(19) United States
(12) Patent Application Publication
(10) Pub. No.: US 2016/0025900 A1
(43) Pub. Date: Jan. 28, 2016

(54) ORGANIC ELECTROLUMINESCENT DISPLAY DEVICE AND METHOD FOR MANUFACTURING SAME

(71) Applicant: KONICA MINOLTA, INC., Tokyo (JP)

(72) Inventor: Shinichiro SUZUKI, Koganei-shi, Tokyo (JP)

(21) Appl. No.: 14/774,006

(22) PCT Filed: Jan. 16, 2014
(86) PCT No.: PCT/JP2014/050636

§ 371 Date: Sep. 9, 2015

(30) Foreign Application Priority Data
Mar. 12, 2013 (JP) 2013-048587

(51) Int. Cl. G02B 1/14; H01L 51/00; H01L 51/52; H01L 51/56; G02B 5/30; G02B 1/04

(52) U.S. Cl. CPC G02B 1/14; G02B 5/3083; G02B 1/04; H01L 51/5281; H01L 51/56; H01L 51/5253; H01L 51/0093; H01L 51/0035; H01L 51/005; H01L 2251/558

(57) ABSTRACT

The objective of the present invention is to provide: an organic electroluminescent display device which is provided with a polarizing plate in the form of a thin film, said polarizing plate having excellent curling resistance and excellent planarity in the cases where the polarizing plate is formed in a low moisture environment or in a high moisture environment, and which has excellent resistance to display unevenness; and a method for manufacturing the organic electroluminescent display device. An organic electroluminescent display device of the present invention comprises a polarizing plate on an organic electroluminescent element unit; and the polarizing plate comprises a retardation film, a polarizer, a protective film and a hard coat layer sequentially in this order from the organic electroluminescent element unit side. The protective film contains a cellulose acetate having a specific average degree of substitution of acetyl groups, and has a water swelling ratio within a specific range and a film thickness within the range of 10-50 μm.

### TECHNICAL FIELD

The present invention relates to an organic electroluminescent display device and a production method of the same. Specifically, the present invention relates to an organic electroluminescent display device having excellent resistance to display unevenness, by being provided with a polarizing plate composed of a thin protective film and a thin layer polarizer and excellent in flatness, and the present invention relates to a production method of the same.

### BACKGROUND

An organic electroluminescent display device (hereafter, it is also called as “an organic EL display device”), being provided with an organic electroluminescent element which emits light from a luminescent layer located between two electrodes by applying voltage to the electrodes, has been intensively studied and developed for various light sources, such as flat-panel illumination devices, light sources for optical fibers, backlights for liquid crystal displays, backlights for liquid crystal projectors, and various light sources for other display devices. This organic electroluminescent element (hereafter, it is also called as “an organic EL element”) is a light emitting element which has been attracted attention in recent years because it exhibits excellent properties of high luminous efficiency, low voltage driving, lightweight, and low costs.

Recently, since it has been requested a display of large size and lightweight, a polarizing plate is demanded to be thinner when a polarizing plate equipped with a A/4 retardation film is used for antireflection. Specifically, a polarizer which composes a polarizing plate, and a protective film which is used for protection of a polarizing plate are required to be thinner. However, when a cellulose film is made thin from the viewpoint of making a thin polarizing plate, there may be produced problems of decreased film strength and decreased film flatness. In particular, when the thin film has a thickness of 50 μm or less, physical properties of the film will be deteriorated. As a result, it will be an obstacle to achieve a thin polarizing plate.

On the other hand, in order to improve the strength of a polarizing plate containing a thin protective film as described above, there have been carried out investigations to improve the adhesiveness of a polarizer with a protective film, or to increase the strength of a protective film for a polarizing plate. For example, it was proposed a cellulose ester film containing a cellulose ester resin and an acrylic resin which is excellent in transparency, size stability and having a low hygroscopic property. The cellulose ester film containing an acrylic resin was suitable for a protective film for a polarizing plate by improving a defect of an acrylic resin as being fragile (for example, refer to Patent document 1). However, it was found that this cellulose ester film containing an acrylic resin had an insufficient close adhesion to a polarizer and it was also insufficient with respect to flatness.

On the other hand, there were disclosed methods in which a polarizer and a cellulose ester film are adhered through a UV (ultraviolet) curable adhesive for the purpose of simplification of the production method of a polarizing plate by omitting a saponification step of a cellulose ester film (for example, refer to Patent documents 2 and 3). It was reported that these methods enabled to achieve a small amount of discoloration of a polarizer (polarizing film) under a severe environment conditions of high temperature and high humidity to result in obtaining a highly durable polarizing plate.

When a cellulose ester film, which is a thin protective film as described above, and a thin polarizer are bonded by adhesion through a UV curable adhesive, a part of the UV curable adhesive will penetrate inside of the cellulose ester film. As a result, it was found that unevenness of curing took place in the UV curable adhesive layer when irradiation with UV rays was done, and there were produced a high humidity resistive region and a low humidity resistive region in the whole cellulose ester film.

Therefore, it was revealed that an organic EL display device containing a polarizing plate having the properties as described above will be deteriorated in humidity resistance, and the polarizer will receive damage in the region of penetrating humidity (water) to result in decreasing the polarizing degree in the whole surface and exhibiting display unevenness. In particular, it was found that the variation phenomenon of humidity resistance caused by an adhesion unevenness of the UV curable adhesive is remarkably exhibited when the polarizer and the cellulose ester film are made thin.

On the other hand, it was observed a problem of giving a whitish image by reflection of outer light on an electrode in an organic EL display device. In order to prevent this problem, it was disclosed a method in which a circularly polarizing plate was provided at an observing side, the circularly polarizing plate being produced by adhering a retardation film having a retardation value of ¼ wavelength of a visible light (hereafter, it is called as a λ/4 retardation film) with a polarizer (for example, refer to JP-A 9-127885).

At present time, in addition to a cellulose ester film, a polycarbonate film and a cycloolefin film are used as a retardation film.

When a cellulose ester film is used as a retardation film, a protective film used for facing a polarizer is mostly a cellulose ester film. When a polarizing plate is composed, the both films have a similar stretching property. Accordingly, there were produced no break of curling balance, and an excellent flatness was maintained. As a result, there occurred no problem in adhesion of a polarizing plate and an organic EL element unit.

On the contrary, when a humidity resistant film such as a polycarbonate film or a cycloolefin film, which is excellent in humidity resistance, is used as a retardation film in order to prevent the effect caused by water to the polarizer, there may be produced break of curling balance and degradation of flatness caused by the difference of hygroscopic property between the cellulose ester film and the retardation film. When a polarizing plate of inferior flatness and an organic EL element unit are bonded to form an electroluminescent display device, it was found that display unevenness was produced in a display screen. This display unevenness was caused by break of curling balance, which was produced by using a polycarbonate film as a retardation film. The surface of the cellulose ester film, which was a curled protective film, was deformed minutely, and a large amount of water was distributed in that region. In particular, when a hard coat layer is provided on the cellulose ester film from the viewpoint of scratch resistance, a minute amount of water penetrated inside of the cellulose ester film from the surface of the hard coat will be trapped into the cellulose ester film, and it is hardly dispersed in the surface. Accordingly, a large amount of water remains in the cellulose ester film to result in producing a distribution (unevenness) of an optical property.

In addition, a polycarbonate film and a cycloolefin film have a problem that they cannot be adhered with an aqueous glue (a polyvinyl alcohol adhesive) after saponification. This is different from a cellulose ester film.

There have been investigated the method for improving the curling produced in a polarizing plate employing a polycarbonate film or a cycloolefin film as described above. For example, it was disclosed a method in which curling of a polarizing plate was reduced by incorporating particles having specific forms on the surface or inside of the cycloolefin film (for example, refer to Patent document 4). Further, it was disclosed an attempt of improving a curling property by adjusting a ratio of a coefficient of elasticity of the films used in a polarizing plate within the specific range (for example, refer to Patent document 5).

However, the above described methods are an improving method addressed to a cycloolefin film which is hardly stretched by water, and they are methods of controlling physical properties such as a coefficient of elasticity. An influence of water in the composition of a polarizing plate is not considered at all in these methods.

Consequently, it is required to develop a polarizing plate which is hardly affected by water and has excellent flatness (curling resistance), producing no display unevenness when it is incorporated in an organic electroluminescent display device.

### PRIOR ART DOCUMENTS

### Patent Documents

Patent document 1: WO 2009/047924

Patent document 2: Japanese patent application publication (JP-A) No. 2010-230806

Patent document 3: JP-A No. 2012-208187

Patent document 4: JP-A No. 2009-210850

Patent document 5: JP-A No. 2008-003126

### SUMMARY OF THE INVENTION

### Problems to be Solved by the Invention

The present invention has been made in view of the above-described problems. An object of the present invention is to provide an organic electroluminescent display device which has excellent resistance to display unevenness, by being provided with a thin layer polarizing plate excellent in curling resistance and flatness when produced under a low humidity environment or a high humidity environment, and to provide a method of producing the same.

### Means to Solve the Problems

In order to solve the above-described problems, the present inventors have investigated the way and have found to achieve an organic electroluminescent display device having excellent flatness and excellent resistance to display unevenness characterized in the following properties.

The realized organic electroluminescent display device comprises an organic electroluminescent element unit having thereon a polarizing plate. The aforesaid polarizing plate has a structure of: a retardation film, a polarizer, a protective film and a hard coat layer, which are laminated in that order from the surface side of the organic electroluminescent element unit. The aforesaid protective film (hereafter, it is also called as a cellulose ester film) has the following properties: (1) containing cellulose acetate having an average degree of acetyl group substitution in the range of 2.60 to 2.95 as a main component; (2) having a water swelling ratio in the range of 0.2 to 1.0% obtained by immersing in water at 23° C. for one hour; and (3) having a thickness in the range of 10 to 50 μm. Thus, the present invention has been achieved.

Namely, the above-described problems of the present invention have been solved by the following embodiments.

1. An organic electroluminescent display device comprising an organic electroluminescent element unit having thereon a polarizing plate,

wherein the polarizing plate has a structure of: a retardation film, a polarizer, a protective film and a hard coat layer, which are laminated in that order from a surface side of the organic electroluminescent element unit; and

the protective film has properties of:

(1) containing cellulose acetate which has an average degree of acetyl group substitution in the range of 2.60 to 2.95 as a main component;

(2) having a water swelling ratio in the range of 0.2 to 1.0% after immersing in pure water at 23° C. for one hour; and

(3) having a thickness in the range of 10 to 50 μm.

2. The organic electroluminescent display device described in the aforesaid item 1,

wherein the retardation film is a film containing polycarbonate or cycloolefin as a main component.

3. The organic electroluminescent display device described in the aforesaid items 1 or 2,

wherein the thickness of the protective film is in the range of 15 to 35 μm.

4. The organic electroluminescent display device described in any one of the aforesaid items 1 to 3,

wherein a thickness of the polarizer is in the range of 2 to 15 μm.

5. The organic electroluminescent display device described in any one of the aforesaid items 1 to 4,

wherein a variation coefficient of the water swelling ratio of the protective film is 0.5% or less when the water swelling ratio is measured at ten different points of a width direction of the protective film.

6. The organic electroluminescent display device described in any one of the aforesaid items 1 to 5,

wherein at least one surface of the protective film and the polarizer is bonded with a UV curable adhesive.

7. The organic electroluminescent display device described in any one of the aforesaid items 1 to 6,

wherein at least one surface of the retardation film and the polarizer is bonded with a UV curable adhesive.

8. The organic electroluminescent display device described in any one of the aforesaid items 1 to 7,

wherein the protective film contains a sugar ester.

9. The organic electroluminescent display device described in the aforesaid item 8,

wherein an average degree of esterification of the sugar ester is in the range of 5.0 to 7.5.

10. The organic electroluminescent display device described in any one of the aforesaid items 1 to 9,

wherein the protective film contains a polyhydric alcohol ester represented by Formula (1) described below.

B₁-G-B₂ Formula (1)

Wherein, B₁ and B₂ each independently represent an aliphatic or aromatic mono carboxylic acid residue. G represents an alkylene glycol residue having a straight or branched structure of 2 to 12 carbon atoms.

11. The organic electroluminescent display device described in the aforesaid item 10,

wherein B₁ and B₂ in the polyhydric alcohol ester represented by Formula (1) each represent an aliphatic mono carboxylic acid residue having 1 to 10 carbon atoms.

12. A method for producing an organic electroluminescent display device comprising an organic electroluminescent element unit having thereon a polarizing plate,

the method comprising a step of:

producing the polarizing plate by sequentially laminating a retardation film, a polarizer, a protective film and a hard coat layer, in that order, from a surface side of the organic electroluminescent element unit,

wherein the protective film has properties of:

(1) containing cellulose acetate as a main component having an average degree of acetyl group substitution in the range of 2.60 to 2.95;

(2) having a water swelling ratio adjusted in the range of 0.2 to 1.0% after immersing in pure water at 23° C. for one hour; and

(3) having a thickness adjusted in the range of 10 to 50 μm.

13. The method for producing an organic electroluminescent display device described in the aforesaid item 12,

wherein the retardation film is a film containing polycarbonate or cycloolefin as a main component.

14. The method for producing an organic electroluminescent display device described in the aforesaid items 12 or 13,

wherein the protective film is prepared by subjecting the protective film to a stretching treatment at first in a longitudinal direction (MD direction), then, in a transversal direction (TD direction) so as to achieve a stretching of 1.3 to 1.7 times in an area ratio compared to an area of the protective film before stretching.

15. The method for producing an organic electroluminescent display device described in any one of the aforesaid items 12 to 14,

wherein, after making the protective film, a laminated roll body is prepared by laminating in a roll state;

a surface of the laminated roll body is subjected to an aging treatment by covering with a moisture-proof sheet and keeping at 50° C. or more for 3 days or more; then,

a hard coat layer is formed thereon.

16. The method for producing an organic electroluminescent display device described in the aforesaid item 15,

wherein a surface treatment is carried out to the hard coat layer after forming the hard coat layer.

17. The method for producing an organic electroluminescent display device described in any one of the aforesaid items 12 to 16,

wherein the polarizing plate is prepared by bonding at least one surface of the protective film and the polarizer with a UV curable adhesive.

18. The method for producing an organic electroluminescent display device described in any one of the aforesaid items 12 to 17,

wherein the polarizing plate is prepared by bonding at least one surface of the retardation film and the polarizer with a UV curable adhesive.

### Effects of the Invention

By the above-described embodiments of the present invention, it can provide an organic electroluminescent display device which has excellent resistance to display unevenness, by being provided with a thin layer polarizing plate excellent in curling resistance and flatness when produced under a low humidity environment or a high humidity environment, and it can provide a method of producing the same.

### BRIEF DESCRIPTION OF DRAWINGS

FIG. 1 is a schematic cross-sectional view illustrating an example of a configuration of an organic electroluminescent display device of the present invention.

FIG. 2 is a schematic diagram illustrating an example of a solution cast film forming method containing a dope preparation step, a casting step and a drying step, and suitably used for production of a cellulose ester film according to the present invention.

FIG. 3 is a schematic diagram illustrating an example of an oblique stretching tenter used for the present invention.

FIG. 4 is a schematic diagram illustrating an example of a rail track (rail pattern) of a tenter used for a production method of the present invention.

FIG. 5A is a schematic diagram illustrating an example of a stretching apparatus (an example of feeding an original long film from a feeding device and obliquely stretching the film) applicable to the present invention.

FIG. 5B is a schematic diagram illustrating another example of a stretching apparatus (another example of feeding an original long film from a feeding device and obliquely stretching the film) applicable to the present invention.

FIG. 5C is a schematic diagram illustrating another example of a stretching apparatus (another example of feeding an original long film from a feeding device and obliquely stretching the film) applicable to the present invention.

FIG. 6A is a schematic diagram illustrating an example of a stretching apparatus (an example of obliquely stretching the film continuously which is prepared in a film forming apparatus) applicable to the present invention.

FIG. 6B is a schematic diagram illustrating another example of a stretching apparatus (another example of obliquely stretching the film continuously which is prepared in a film forming apparatus) applicable to the present invention.

FIG. 7 is a schematic diagram illustrating an example of a package embodiment of a roll laminate body of a cellulose ester film according to the present invention.

### EMBODIMENTS TO CARRY OUT THE INVENTION

An organic electroluminescent display device of the present invention is an organic electroluminescent display device comprising an organic electroluminescent element unit having thereon a polarizing plate, wherein the aforesaid polarizing plate has a structure of: a retardation film, a polarizer, a protective film and a hard coat layer, which are laminated in that order from a surface side of the organic electroluminescent element unit; and the aforesaid protective film has properties of:

(1) containing cellulose acetate as a main component having an average degree of acetyl group substitution in the range of 2.60 to 2.95; (2) having a water swelling ratio in the range of 0.2 to 1.0% after immersing in pure water at 23° C. for one hour; and (3) having a thickness in the range of 10 to 50 μm. These technical properties are common to the inventions according to claims (1) to (18).

A more preferable embodiment of the present invention is that the aforesaid retardation film is a film containing polycarbonate or cycloolefin as a main component, from the viewpoint of achieving a high moisture-proof property and to control an influence of humidity to the polarizer.

It is preferable to make a thickness of the protective film to be in the range of 15 to 35 μm, or to make a thickness of the polarizer to be in the range of 2 to 15 μm from the viewpoint of obtaining a thinner polarizing plate.

It is preferable to make a variation coefficient of the water swelling ratio of the protective film to be 0.5% or less when the water swelling ratio is measured at ten different points of a width direction of the protective film.

Further, it is preferable that: (a) the protective film is bonded to one surface of the polarizer with a UV curable adhesive; (b) the retardation film is bonded to one surface of the polarizer with a UV curable adhesive; (c) the protective film contains a sugar ester; (d) an average degree of esterification of the sugar ester is in the range of 5.0 to 7.5; (e) the protective film contains a polyhydric alcohol ester represented by the aforesaid Formula (1); and (f) B₁ and B₂ in a polyhydric alcohol ester represented by the aforesaid Formula (1) each represent an aliphatic mono carboxylic acid residue having 1 to 10 carbon atoms. From the viewpoint of obtaining a protective film having a water swelling ratio in the range of 0.2 to 1.0% after immersing in pure water at 23° C. for one hour, it is preferable to suitably select any one of the above described embodiments or a combination of these embodiments.

A method for producing an organic electroluminescent display device of the present invention is a method for producing an organic electroluminescent display device comprising an organic electroluminescent element unit having thereon a polarizing plate, the method comprising a step of: producing the polarizing plate by sequentially laminating a retardation film, a polarizer, a protective film and a hard coat layer, in that order, from a surface side of the organic electroluminescent element unit, wherein the protective film has properties of: (1) containing cellulose acetate as a main component having an average degree of acetyl group substitution in the range of 2.60 to 2.95; (2) having a water swelling ratio adjusted in the range of 0.2 to 1.0%; and (3) having a thickness adjusted in the range of 10 to 50 μm.

Further, it is preferable that the retardation film is a film containing polycarbonate or cycloolefin as a main component.

Further, it is preferable that: (1) the protective film is prepared by subjecting a non-stretched film to a stretching treatment at first in a longitudinal direction (MD direction), then, in a transversal direction (TD direction) so as to achieve a stretching of 1.3 to 1.7 times in an area ratio compared to an area of the film before stretching; (2) after making the protective film, a laminated roll body is prepared by laminating in a roll state; a surface of the laminated roll body is subjected to an aging treatment by covering with a moisture-proof sheet and keeping at 50° C. or more for 3 days or more; then, a hard coat layer is formed thereon; (3) surface treatment is carried out to the hard coat layer after forming the hard coat layer; (4) the polarizing plate is prepared by bonding the protective film to one surface of the polarizer with a UV curable adhesive; and (5) the polarizing plate is prepared by bonding the retardation film to one surface of the polarizer with a UV curable adhesive. It can obtain a protective film having a water swelling ratio in the range of 0.2 to 1.0% after immersing in pure water at 23° C. for one hour, by suitably selecting any one of the above described embodiments or a combination of these embodiments.

Although it is not clearly understood the technical reasons to obtain the aimed effects of the present invention by the compositions defined in the present invention and described above, the reasons are presumed to be as follows.

In recent years, it has begun to use the following film for a polarizing plate in order to improve stability of a polarizing plate or by considering durability under a variety of environments. As a constitution of a polarizing plate, a cellulose ester film is mainly used as a protective film on a surface side; and a low hygroscopic resin such as a polycarbonate resin, a cycloolefin resin or an acrylic resin is used as a retardation film on a side of an organic electroluminescent element.

However, as described above, when a polarizer is held between a cellulose ester film used as a protective film for a surface and a polycarbonate resin or a cycloolefin resin used as a retardation film, there will appear a difference of a stretching property between the cellulose ester film having a large stretching property depending on humidity and the retardation film composed of polycarbonate resin or a cycloolefin resin having a very small stretching property depending on humidity. This difference will cause break of curling balance to result in deterioration of flatness.

When a polarizing plate of inferior flatness and an organic EL element unit are bonded to form an electroluminescent display device, as described above, it was found that display unevenness was produced in a display screen. This display unevenness was caused by break of curling balance, which was produced by using a polycarbonate film as a retardation film. Due to the produced curling, the surface of the cellulose ester film, was deformed minutely, and a large amount of water was distributed in that region. In particular, when a hard coat layer is provided on the cellulose ester film from the viewpoint of scratch resistance, dissipation of water will be prevented and water will be remained on the surface of the cellulose ester film. It was supposed that this will be a reason to produce a distribution (unevenness) of an optical property.

As a result of investigating the reason which induces the aforesaid phenomenon, the present inventors focused on the water swelling ratio of a cellulose ester film which has not been investigated in the past. It was found that the above-described problem can be resolved by controlling the water swelling ratio to be in the condition of having a specific range of 0.2 to 1.0%.

By giving a cellulose ester film a property of hardly swelling with water, the cellulose ester film will be less affected by the humidity environment of the polarizing plate production step or by the water remained in the polarizing plate after composing the polarizing plate production. Consequently, there will be hardly produced curling, and it can obtain a polarizing plate excellent in flatness. An organic electroluminescent display device provided with this polarizing plate has achieved distinguished improvement in display unevenness which is caused by degradation of flatness.

The present inventors have investigated in detail the method of giving a cellulose ester film according to the present invention a property of slightly swelling with water. As a result, it was found that the water swelling ratio in the layer can be controlled by adding a specific additive in the film as a constitution member of a cellulose ester film. In particular, it was found that a sugar ester is preferably used as a plasticizer. A further investigation revealed that the use of a sugar ester having an average degree of esterification in the range of 5.0 to 7.5 will exhibit the effect more significantly.

Further, it was found that incorporation of a polyhydric alcohol ester represented by the above-described Formula (1) is efficient as another additive.

On the other hand, the present inventors have investigated in detail the method of producing a protective film according to the present invention. As a result, it was found the following first way was effective. After forming a cellulose ester film, the film is subjected to a stretching treatment by stretching in a longitudinal direction (MD direction), subsequently or at the same time, by stretching in a transversal direction (TD direction) so as to achieve a stretching of 1.3 to 1.7 times in an area ratio compared to an area of the film before stretching.

Further, after making a long cellulose film, and after this cellulose film is laminated to prepare a roll body; a surface of the laminated roll body is subjected to an aging treatment by covering with a moisture-proof sheet and keeping at 50° C. or more for 3 days or more. By this aging treatment, the plasticizer in the film will be orientated in the surface side of the film. Consequently, penetration of a water ingredient from the surface will be prevented. In addition, by subjecting to the aforesaid aging treatment, it can control spreading of a distribution (a variation coefficient) of water swelling ratio in a width direction of the film.

When a polarizing plate is formed, a cellulose ester film and a polarizer, or a retardation film and a polarizer may be bonded through a UV curable adhesive. By this bonding, a stress produced by the change of the outer environment in a composed polarizing plate will be relaxed, and it is believed that generation of curling will be controlled by this. Further, when a polycarbonate film or a cycloolefin film is used as a retardation film, a polarizing plate excellent in close contact will be obtained by bonding the retardation film to the polarizer through a UV curable adhesive.

The present invention and the constitution elements thereof, as well as configurations and embodiments, will be detailed in the following. In the present description, when two figures are used to indicate a range of value before and after “to”, these figures are included in the range as a lowest limit value and an upper limit value.

### <<Schematic Configuration of Organic Electroluminescent Display Device>>

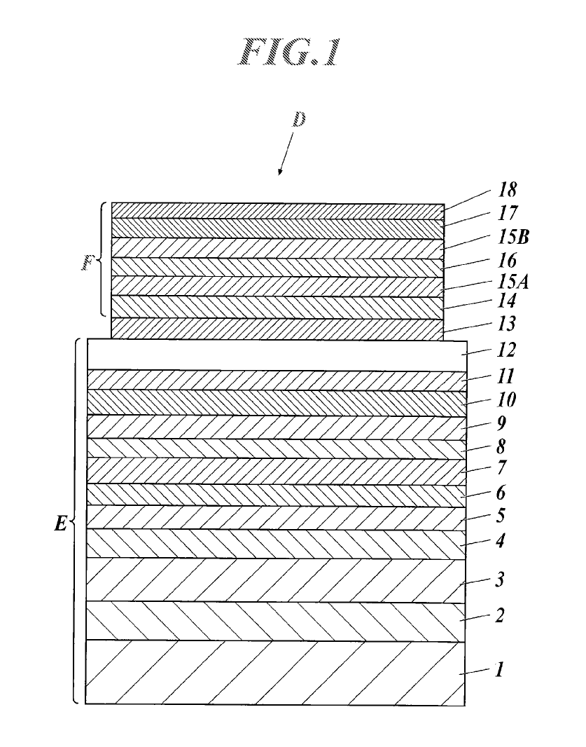

FIG. 1 is a schematic cross-sectional view illustrating an example of a configuration of an organic electroluminescent display device according to the invention.

An organic electroluminescent display device according to the invention contains an organic electroluminescent element unit having thereon a polarizing plate. The polarizing plate contains: a retardation film, a polarizer, a protective film and a hard coat layer, which are laminated in that order from a surface side of the organic electroluminescent element unit

In FIG. 1, a representative organic EL element unit E composing an organic EL display device D of the present invention is composed of by laminating: a substrate 1 composed of glass or polyimide having thereon, TFT 2, a metal electrode 3, ITO 4, a hole transport layer 5, a light emitting layer 6, a buffer layer 7, a cathode 8, ITO 9, an insulating layer 10, an adhesive layer C 11, a sealing glass 12 (it may called as a surface layer), in that order.

A polarizing plate F is disposed on the organic EL element unit E as described above.

As illustrated in FIG. 1, the polarizing plate F has a configuration of: an adhesive layer 13 facing to the organic EL element unit, a retardation film 14, a UV curable adhesive layer 15A, a polarizer 16, a UV curable adhesive layer 15B, a protective film 17 provided with a specific property defined in the present invention, and a hard coat layer 18, which are laminated in that order as shown for example. In addition, an anti-reflection layer or an anti-glare layer may be provided on the hard coat layer 18 when required.

### <<Polarizing Plate>>

First, it will be described in detail each of the constitution elements of a polarizing plate F which composes an organic EL display device D of the present invention.

Main constitution elements of a polarizing plate F according to the present invention are: a retardation film 14, a polarizer 16, a protective film 17, and a hard coat layer 18.

### [Protective Film]

### [Cellulose Acetate]

A protective film according to the present invention has a feature of being composed of cellulose acetate having an average degree of acetyl group substitution in the range of 2.60 to 2.95 as a main component. “A main component” used in the present invention indicates the case in which among the cellulose esters which constitutes the cellulose ester film, an amount of the cellulose ester having an average degree of acetyl group substitution in the range of 2.60 to 2.95 is 60 mass % or more, preferably 80 mass % or more, more preferably 95 mass % or more.

Cellulose acetate used in the protective film is triacetyl cellulose having an average degree of acetyl group substitution in the range of 2.60 to 2.95. More preferably, an average degree of acetyl group substitution is in the range of 2.80 to 2.94. A degree of acetyl group substitution in cellulose ester can be determined by measurement in accordance with ASTM-D817-96.

In the present invention, when an average degree of acetyl group substitution of the cellulose acetate applied is 2.60 or more, it can achieve the properties of high casting aptitude during film formation and excellent handling.

### [Water Swelling Ratio]

In the protective film according to the present invention, one of the characteristics is to have a water swelling ratio in the range of 0.2 to 1.0% after immersing in pure water at 23° C. for one hour.

In the protective film according to the present invention, when the water swelling ratio is in the range of 0.2 to 1.0%, the protective film may exhibit a similar elasticity to that of polycarbonate film or cycloolefin film. Therefore, there will be produced no break of curling balance, and it can achieve excellent flatness.

The water swelling ratio of the protective film according to the present invention is a measured value obtained with the method as described below.

(1) The protective film is cut to a size of 5 cm×5 cm.
(2) After leaving the cut film piece under the environment of 23° C. and 55% RH for 24 hours, thickness values at 10 different points are measured using a thickness measuring apparatus as described below to obtain an arithmetic average value. This value is called as “a thickness A”.
(3) Then, the film piece is immersed in pure water of 23° C. and left in this condition for 1 hour.
(4) After 1 hour, the film piece is taken out from the pure water, and the water attached on the surface of the film piece is wiped off with Kimtowel™ (made by Nippon Paper Crecia, Co. Ltd.). Then the film piece is left still under the environment of 23° C. and 55% RH for 5 minutes.
(5) After a lapse of 5 minutes from the moment of taking the film out of the water, it is started a thickness measurement with the same way. During 5 minutes, until 10 minutes after taking the film out of the water, thickness values of the film piece at 10 different points are measured.
(6) An arithmetic average value from the measured thickness values at 10 points is calculated. This value is called as “a thickness B”.
(7) By using the thickness A and the thickness B, a water swelling ratio of a protective film is obtained with the following equation (1).

Water swelling ratio of a protective film (%)=[(Thickness B−Thickness A)/Thickness A]×100 Equation (1):

Thickness measuring apparatuses are “DIGIMICRO MH-15M” and “COUNTER TC-101” (made by Nikon, Co. Ltd.). The measurement is done by setting the minimum reading value to be 0.01 μm.

It is preferable that the protective film (cellulose acetate film) according to the present invention has a variation coefficient of 0.5% or less obtained from the water swelling ratios measured at 10 different points in the width direction of the film.

It can be obtained a variation coefficient of water swelling ratios according to the present invention with the following equation (2)

Variation coefficient of water swelling ratios (%)=(Standard deviation of water swelling ratios/Average value of water swelling ratios)×100 Equation (2):

Specifically, the water swelling ratios are measured at 10 different points in the width direction (TD direction) of the protective film. By calculating an average value of water swelling ratios obtained as an arithmetic average value and a standard deviation of water swelling ratios, a variation coefficient of water swelling ratios can be calculated.

In the present invention, there is no specific limitation concerning a way to control a water swelling ratio of the protective film (cellulose acetate film) according to the present invention, and its variation coefficient within the range defined in the present invention. However, as described above, the control can be achieved by suitably selecting or combing the methods as described below. The methods applicable to the present invention will be described below, however, the present invention is not limited only to them.

As embodiments of a protective film according to the present invention, the following can be cited.

As a first method, it was found that a sugar ester is preferably used as a plasticizer. Further investigation revealed that preferable is to use a sugar ester having an average degree of esterification adjusted in the range of 5.0 to 7.5 among sugar esters.

As a second method, a polyhydric alcohol ester represented by the aforesaid Formula (1) is used as a plasticizer. More preferably, B₁ and B₂ in Formula (1) is made to be an alkyl group with 1 to 10 carbon atoms.

As a third method, when forming a polarizing plate, a protective film and a polarizer, or a retardation film and a polarizer is bonded through a UV curable adhesive.

As a method of producing a protective film, a fourth method is a method in which the protective film is prepared by subjecting a film to a stretching treatment at first in a longitudinal direction (MD direction), then or simultaneously, in a transversal direction (TD direction) so as to achieve a stretching of 1.3 to 1.7 times in an area ratio compared to an area of the film before stretching.

As a fourth method, preferable is a method in which, after making a long cellulose film, and after this cellulose film is laminated to prepare a roll body; a surface of the laminated roll body is subjected to an aging treatment by covering with a moisture-proof sheet and keeping at 50° C. or more for 3 days or more. By this aging treatment, the plasticizer in the film will be orientated in the surface side of the film. By applying this method, penetration of a water ingredient from the surface will be prevented. In addition, it can control spreading of a distribution (a variation coefficient) of water swelling ratio in a width direction of the film.

The detail of the above-described technologies will be described later.

### [Layer Thickness}

A thickness of a protective film according to the present invention is characterized in being in the range of 15 to 50 μm. Moe preferably, it is in the range of 15 to 35 μm. When the thickness of a protective film is 15 μm or more, it can be acquired properties of a sufficient rigidity and excellent handling. On the other hand, when it is 50 μm or less, it can easily produce a thin type polarization plate.

### [Molecular Weight]

A number average molecular weight (Mn) of the above cellulose triacetate is preferably in the range of 125,000 to 155,000, more preferably, it is in the range of 129,000 to 152,000. A weight average molecular weight (Mw) thereof is preferably in the range of 265,000 to 310,000. A ratio (Mw/Mn) of a weight average molecular weight (Mw) to a number average molecular weight (Mn) thereof is preferably 1.9 to 2.1.

The above described average molecular weights (Mn and Mw)) are determined by gel permeation chromatography (GPC). The measuring conditions are listed below.

Solvent: methylene chloride

Columns: Shodex K806, K805, and K803G (available from Showa Denko K.K., the three columns are connected)

Column temperature: 25° C.

Concentration of sample: 0.1 mass %

Detector: RI Model 504 (available from GL Sciences Inc.)

Pump: L6000 (available from Hitachi, Ltd.)

Flow rate: 1.0 ml/min

Calibration curves: calibration curves derived from thirteen samples of standard polystyrenes STK (available from Tosoh Corporation, Mw: 500 to 2,800,000) are used. The thirteen samples are preferably eluted at substantially equal intervals.

The cellulose acetate according to the present invention can be prepared by a known method such as a sulfuric acid catalyst method, an acetic acid method, or a methylene chloride method. Examples of a raw material for cellulose acetate include: cotton linter, wood pulp (derived from softwood and hardwood), and kenaf, however, it is not limited to them. The cellulose acetates derived from these raw materials may be mixed in any proportion for use. Further, the cellulose acetate according to the present invention can be prepared with reference to the method described in JP-A 10-45804 and JP-A 2005-281645.

A detail of a specific production method of a cellulose acetate film will be described later.

### [Additive]

### (Sugar Ester)

A protective film (cellulose acetate film) according to the present invention preferably contains a sugar ester apart from a cellulose ester.

As a sugar ester according to the present invention, a preferable compound is a sugar ester which contains at least one of pyranose ring and furanose ring in an amount of 1 to 12 rings, and all or a partial OH groups in the ring are esterified.

A sugar ester according to the present invention is a compound which contains at least one of pyranose ring and furanose ring. It may be a monosaccharide, or it may be a polysaccharide containing 2 to 12 saccharide structures bonded with each other. A sugar ester is preferably a compound in which at least one OH group contained in the saccharide structure is esterified. In a sugar ester according to the present invention, an average degree of esterification is preferably in the range of 5.0 to 7.5.

Sugar esters which are applicable to the present invention are not specifically limited. It can be cited sugar esters represented by Formula (A):

(HO)ₘ-G-(O—C(═O)—R²)ₙ Formula (A):

In Formula (A), G represents a monosaccharide or disaccharide residue; R² represents an aliphatic group or an aromatic group; m is a total number of hydroxy groups directly bonded to a mono saccharide or a disaccharide residue, and n is a total number of —(O—C(═O)—R²) groups directly bonded to a mono saccharide or a disaccharide residue; and 3≦m+n≦8, n≠0.

The sugar ester having a structure represented by Formula (A) cannot be readily isolated as a single compound having the predetermined total number m of hydroxy groups and the predetermined total number n of —(O—C(═O)—R²) groups, and thus it is known that the sugar ester is prepared as a mixture of compounds containing components having different values m and n. Thus essential are properties of the mixture of compounds having different numbers of hydroxy groups (m) and different numbers of —(O—C(═O)—R²) groups (n). For a protective film of the present invention, it is preferable to use a sugar ester having an average degree of esterification in the range of 5.0 to 7.5.

Specific examples of a monosaccharide residue represented by G in Formula (A) include: allose, altrose, glucose, mannose, gulose, idose, galactose, talose, ribose, arabinose, xylose, and lyxose.

Examples of a compound containing a monosaccharide residue in a sugar ester represented by Formula (A) will be listed below, however, the present invention is not limited to them.

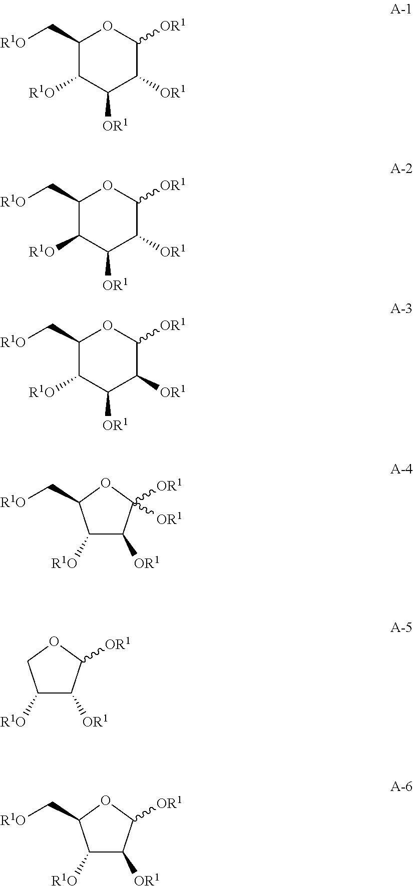

Specific examples of a disaccharide residue represented by G include: trehalose, sucrose, maltose, cellobiose, gentiobiose, lactose, and isotrehalose.

Examples of a compound containing a disaccharide residue in a sugar ester represented by Formula (A) will be listed below, however, the present invention is not limited to them.

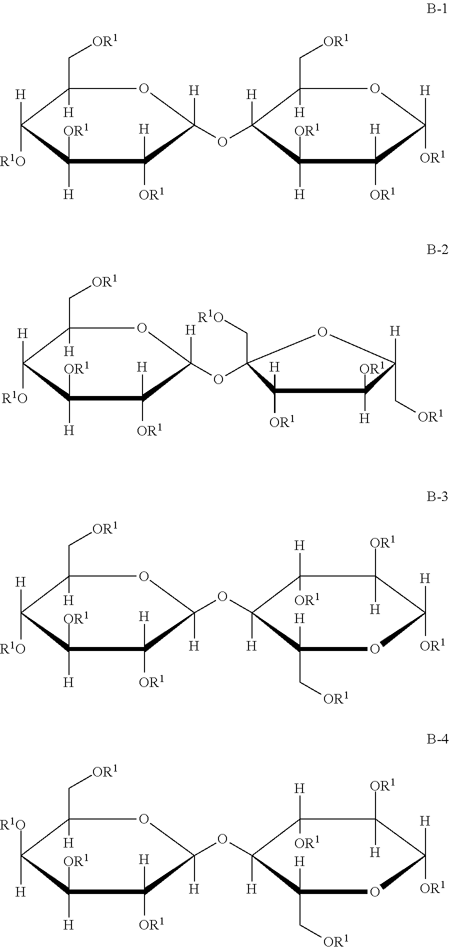

In Formula (A), R² represents an aliphatic group or an aromatic group. Here, an aliphatic group or an aromatic group each independently may have a substituent.

In Formula (A), m is a total number of hydroxy groups directly bonded to a mono saccharide or a disaccharide residue, and n is a total number of —(O—C(═O)—R²) groups directly bonded to a mono saccharide or a disaccharide residue. In addition, it is required to satisfy the condition of 3≦m+n≦8, more preferably, to satisfy the condition of 4≦m+n≦8. Here, n≠0. When n is 2 or more, plural —(O—C(═O)—R²) groups may be the same or different with each other.

In the definition of R², an aliphatic group may be linear, branched, or cyclic. An aliphatic group has preferably 1 to 25 carbon atoms, more preferably 1 to 20 carbon atoms, still more preferably 2 to 15 carbon atoms. Specific examples of an aliphatic group include: a methyl, ethyl, n-propyl, iso-propyl, cyclopropyl, n-butyl, iso-butyl, tert-butyl, amyl, iso-amyl, tert-amyl, n-hexyl, cyclohexyl, n-heptyl, n-octyl, bicyclooctyl, adamantyl, n-decyl, tert-octyl, dodecyl, hexadecyl, octadecyl, and didecyl group.

In the definition of R², an aromatic group may be an aromatic hydrocarbon group or an aromatic heterocyclic group, more preferably an aromatic hydrocarbon group. An aromatic hydrocarbon group has preferably 6 to 24 carbon atoms, more preferably 6 to 12 carbon atoms. Specific examples of an aromatic hydrocarbon group include: benzene, naphthalene, anthracene, biphenyl, and terphenyl. Particularly preferred aromatic hydrocarbon groups are benzene, naphthalene, and biphenyl. An aromatic heterocyclic group preferably has at least one atom of oxygen, nitrogen, and sulfur atoms. Specific examples of a heterocyclic group include: furan, pyrrole, thiophene, imidazole, pyrazole, pyridine, pyrazine, pyridazin, triazole, triazine, indole, indazole, purine, thiazoline, thiadiazole, oxazoline, oxazole, oxadiazole, quinoline, isoquinoline, phthalazine, naphthyridine, quinoxaline, quinazoline, cinnoline, pteridin, acridine, phenanthroline, phenazine, tetrazole, benzimidazole, benzoxazole, benzothiazole, benzotriazole, and tetrazaindene. Particularly preferred aromatic heterocyclic groups are pyridine, triazine, and quinoline rings.

Preferable examples of a sugar ester represented by Formula (A) will be listed below, however, the present invention is not limited to these exemplified compounds.

The sugar ester may contain two or more kinds of substituents in the molecule. It may contain in the molecule: an aromatic substituent and an aliphatic substituent; two or more different aromatic substituents; or two or more different aliphatic substituents.

In addition, it is also preferable to use a mixture of two or more kinds of sugar esters. It is also preferable to use a mixture containing a sugar ester having an aromatic substituent and a sugar ester having an aliphatic substituent at the same time.

| | | Substituent 1 (R¹ group) | | Substituent 2 (R¹ group) | |
|---|---|---|---|---|---|
| Compound | Sugar | | Substitution | | Substitution |
| Name | Residue | Structure | Degree (n) | Structure | Degree (m) |
| a1 a2 a3 a4 | B-2 | 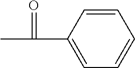 | 8 7 6 5 | —H | 0 1 2 3 |
| b1 b2 b3 | A-1 | 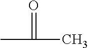 | 5 4 3 | —H | 0 1 2 |
| b4 | | | 2 | | 3 |
| c1 c2 c3 c4 | B-1 | 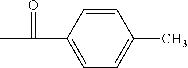 | 8 7 6 5 | —H | 0 1 2 3 |
| d1 d2 d3 | A-5 | 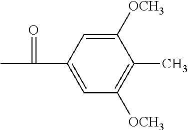 | 3 2 1 | —H | 0 1 2 |
| e1 e2 e3 e4 | A-1 | 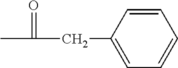 | 5 4 3 2 | —H | 0 1 2 3 |
| f1 f2 f3 | B-2 | 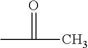 | 8 7 6 | —H | 0 1 2 |
| f4 | | | 5 | | 3 |
| g1 g2 g3 | B-2 | 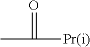 | 8 7 6 | 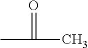 | 0 1 2 |
| g4 | | | 5 | | 3 |

### Synthetic Example

### Synthetic Example of Sugar Ester Represented by Formula (A)

In the following, a synthetic example of a sugar ester suitably used in the present invention will be described.

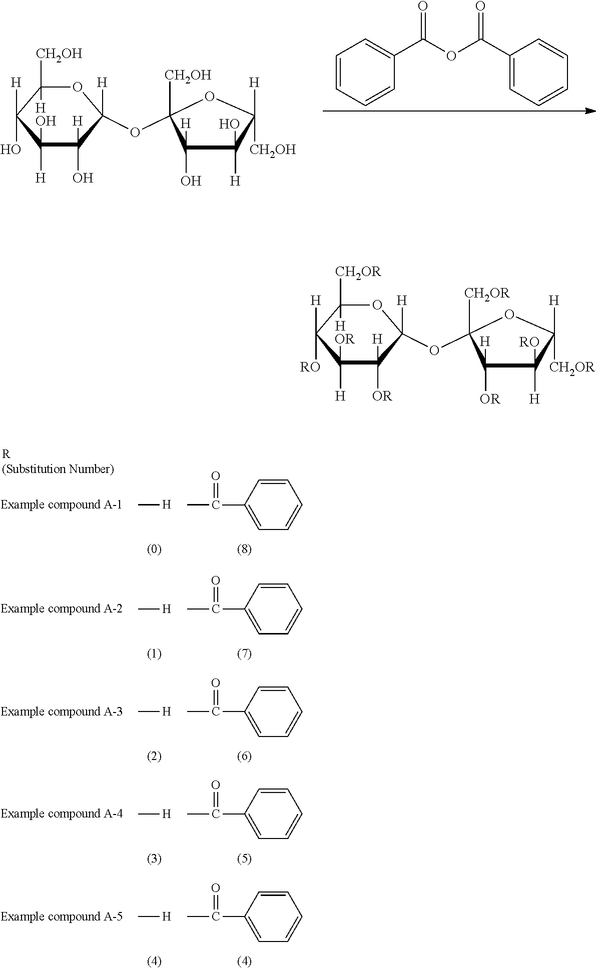

Sucrose (34.2 g, 0.1 mole), benzoic anhydride (180.8 g, 0.8 mole), and pyridine (379.7 g, 4.8 mole) were placed in a four-necked flask equipped with a stirrer, a reflux condenser, a thermometer, and a nitrogen inlet tube. While bubbling a nitrogen gas from the nitrogen inlet tube, these materials were heated under stirring for an esterification reaction at 70° C. for 5 hours. The pressure in the flask was reduced to 4×10² Pa or less to distill off excess pyridine at 60° C. The pressure in the flask was then reduced to 1.3×10 Pa or less, and the mixture was heated to 120° C. to distill off most of benzoic anhydride and generated benzoic acid. Subsequently, toluene (1 L) and a 0.5 mass % aqueous sodium carbonate solution (300 g) were added, and were stirred at 50° C. for 30 minutes. The reaction solution was left to stand until the toluene layer was separated. Finally, water (100 g) was added to the separated toluene layer to wash the toluene layer at normal temperature for 30 minutes. The toluene layer was then separated. Toluene was distilled off under reduced pressure (4×10² Pa or less) at 60° C. to prepare a mixture of Compounds A-1, A-2, A-3, A-4 and A-5. The analyses of the mixture by HPLC and LC-MASS show that the content of Compound A-1 was 7 mass %, Compound A-2 was 58 mass %, Compound A-3 was 23 mass %, Compound A-4 was 9 mass %, and Compound A-5 was 3 mass %. An average degree of esterification of the sugar esters was 6.57. A part of the mixture produced was purified by silica gel column chromatography to obtain Compounds A-1, A-2, A-3, A-4 and A-5 each having a purity of 100%.

### [Polyhydric Alcohol Ester]

It is preferable that a protective film according to the present invention contains a polyhydric alcohol ester represented by the following Formula (1).

B₁-G-B₂ Formula (1):

In the above Formula (1), B₁ and B₂ each independently represent an aliphatic or aromatic mono carboxylic acid residue. G represents an alkylene glycol residue having a straight or branched structure of 2 to 12 carbon atoms.

In Formula (1), G represents a divalent group derived from an alkylene glycol having a straight or branched structure of 2 to 12 carbon atoms.

Examples of a divalent group represented by G and derived from alkylene glycol having 2 to 12 carbon atoms are a divalent group derived from: ethylene glycol, 1,2-propylene glycol, 1,3-propylene glycol, 1,2-butanediol, 1,3-butanediol, 1,2-propanediol, 2-methyl-1,3-propanediol, 1,4-butanediol, 1,5-pentanediol, 2,2-dimethyl-1,3-propanediol (neopentyl glycol), 2,2-diethyl-1,3-propanediol (3,3-dimethylol pentane), 2-n-butyl-2-ethyl-1,3-propanediol (3,3-dimethylol heptane), 3-methyl-1,5-pentanediol, 1,6-hexanediol, 2,2,4-trimethyl-1,3-pentanediol, 2-ethyl-1,3-hexanediol, 2-methyl-1,8-octanediol, 1,9-nonanediol, 1,10-decanediol, and 1,12-octadecanediol. A combined use of a mixture of two or more alkylene glycols is also a preferable embodiment.

In Formula (1), B₁ and B₂ each independently represent a monovalent group derived from an aromatic ring containing monocarboxylic acid or an aliphatic monocarboxylic acid.

In a monovalent group derived from an aromatic ring containing monocarboxylic acid, the aromatic ring containing monocarboxylic acid is a carboxylic acid containing an aromatic ring in the molecule. It includes not only a compound having an aromatic ring directly bonded to a carboxylic group, but a compound having an aromatic ring bonded to a carboxylic group via a joint such as an alkylene group. Examples of a monovalent group derived from an aromatic ring containing monocarboxylic acid include a monovalent group derived from: benzoic acid, para-tertiary-butylbenzoic acid, ortho-toluic acid, meta-toluic acid, par-toluic acid, dimethylbenzoic acid, ethylbenzoic acid, n-propylbenzoic acid, aminobenzoic acid, acetoxybenzoic acid, phenylacetic acid, and 3-phenylpropionic acid. Among these compounds, preferred are benzoic acid, para-toluic acid, and para-toluic acid.

Examples of a monovalent group derived from an aliphatic monocarboxylic acid include a monovalent group derived from: acetic acid, propionic acid, butanoic acid, caprylic acid, caproic acid, decanoic acid, dodecanoic acid, stearic acid, and oleic acid. Among them, preferable is a monovalent group derived from an alkyl monocarboxylic acid having an alkyl portion of 1 to 10 carbon atoms. More preferable is an acetyl group (a monovalent group derived from an acetic acid).

Specific examples of a polyhydric alcohol ester applicable to the present invention are shown below, however, the present invention is not limited to these example compounds.

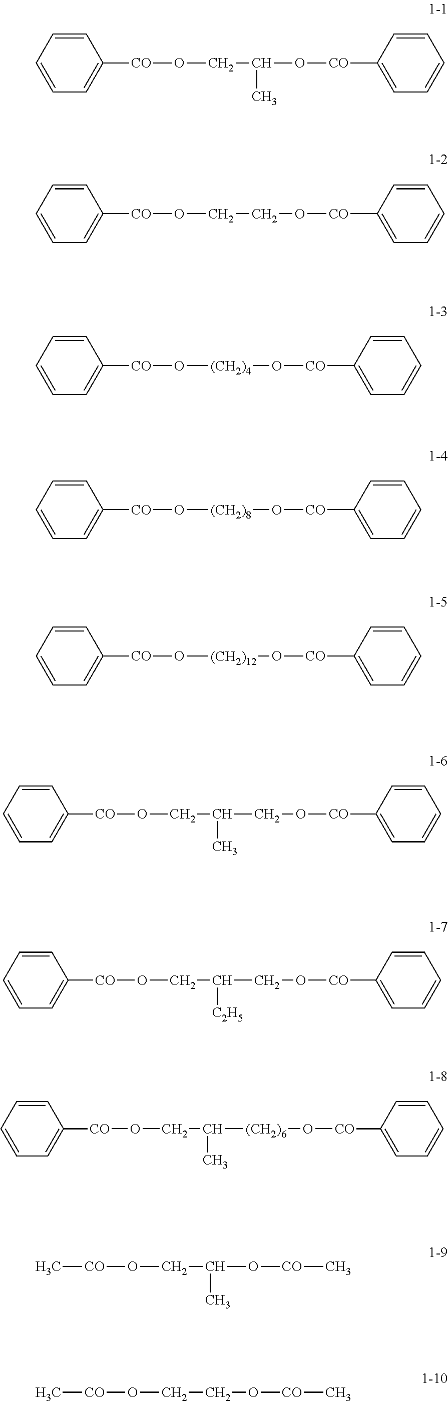

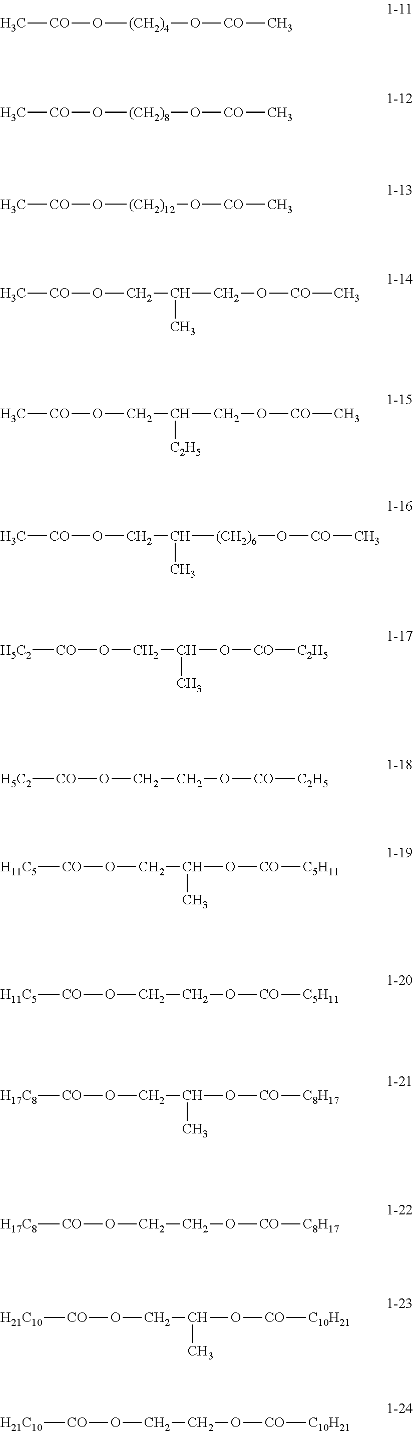

A polyhydric alcohol ester represented by Formula (1) according to the present invention is preferably contained in the range of 0.5 to 5 mass % in a protective film. More preferably, it is in the range of 1 to 3 mass %, and still more preferably, it is in the range of 1 to 2 mass %.

A polyhydric alcohol ester represented by Formula (1) according to the present invention can be synthesized according to a conventionally known general synthetic method.

### [Other Additive]

In a protective film according to the present invention, previously known additives may be used within the range of not deteriorating the targeted effects of the present invention.

Most representative other additives will be described below.

### (Polyester)

A polyester other than a sugar ester may be used in the present invention as a plasticizer.

As a polyester other than a sugar ester applicable to the present invention, it may be used a polyester compound represented by Formula (2) as described below, although it is not specifically limited.

In view of the plasticizing property of the aforesaid polyester, a preferable amount of this compound incorporated in the protective film according to the present invention is in the range of 1 to 20 mass %, more preferably, it is incorporated in the range of 2 to 10 mass %.

B₃-(G₂-A)ₙ-G₂-B₄ Formula (2):

In the above Formula (2), B₃ and B₄ each independently represent an aliphatic or aromatic mono carboxylic acid residue. G₂ represents an alkylene glycol residue of 2 to 12 carbon atoms, an aryl glycol residue of 6 to 12 carbon atoms, or an oxyalkylene glycol residue of 4 to 12 carbon atoms. “A” represents an alkylene dicarboxylic acid residue of 4 to 12 carbon atoms, or an aryl dicarboxylic acid residue of 6 to 12 carbon atoms. “n” is an integer of 1 or more.

In the present invention, when the polyester is a compound containing a repeating unit produce by reacting a dicarboxylic acid and a diol, “A” represents a carboxylic acid residue and G₂ represents an alcohol residue.

A dicarboxylic acid composing a polyester is an aromatic dicarboxylic acid, an aliphatic dicarboxylic acid, or a alicyclic dicarboxylic acid. Preferably, it is an aromatic dicarboxylic acid. The dicarboxylic acid may be one kind, or may be a mixture of two or more kinds. In particular, a mixture of an aromatic dicarboxylic acid and an aliphatic dicarboxylic acid is preferably used.

A diol which composes a polyester is an aromatic diol, an aliphatic diol, or a alicyclic diol. Preferably, it is an aliphatic diol. More preferably, it is an aliphatic diol of 1 to 4 carbon atoms. The diol may be one kind, or a mixture of two or more kinds.

In particular, it is preferable a compound containing a repeating unit obtained by the reaction of a dicarboxylic acid containing at least one aromatic dicarboxylic acid with a diol of 1 to 8 carbon atoms. More preferable is a compound containing a repeating unit obtained by the reaction of dicarboxylic acids containing an aromatic dicarboxylic acid and an aliphatic dicarboxylic acid with a diol of 1 to 8 carbon atoms.

Both ends of the polyester may be or may not be capped. From the viewpoint of reducing a variation of retardation of the protective film, it is preferable to be capped.

In Formula (2), specific examples of an alkylene dicarboxylic acid which composes “A” are divalent groups derived form: 1,2-ethane dicarboxylic acid (succinic acid), 1,3-propanediol dicarboxylic acid (glutaric acid), 1,4-butane dicarboxylic acid (adipic acid), 1,5-dicarboxylic acid (pimelic acid), and 1,8-octane dicarboxylic acid (sebacic acid). Specific examples of an alkenylene dicarboxylic acid which composed “A” are maleic acid and fumaric acid. Specific examples of an aryl dicarboxylic acid which composed “A” are: 1,2-benzenedicarboxylic acid (phthalic acid), 1,3-benzene dicarboxylic acid, 1,4-benzenedicarboxylic acid, and 1,5-naphthalenedicarboxylic acid.

“A” may be one kind, or may be combined with two or more kinds. In particular, preferably, “A” is a combination of an alkylene dicarboxylic acid of 4 to 12 carbon atoms with an aryl dicarboxylic acid of 8 to 12 carbon atoms.

G₂ in Formula (2) represents: a divalent group derived from an alkylene glycol of 2 to 12 carbon atoms; a divalent group derived from an aryl glycol of 6 to 12 carbon atoms; or a divalent group derived from an oxyalkylene glycol of 4 to 12 carbon atoms.

Examples of a divalent group represented by G₂ and derived from alkylene glycol having 2 to 12 carbon atoms are a divalent group derived from: ethylene glycol, 1,2-propylene glycol, 1,3-propylene glycol, 1,2-butanediol, 1,3-butanediol, 1,2-propanediol, 2-methyl-1,3-propanediol, 1,4-butanediol, 1,5-pentanediol, 2,2-dimethyl-1,3-propanediol (neopentyl glycol), 2,2-diethyl-1,3-propanediol (3,3-dimethylol pentane), 2-n-butyl-2-ethyl-1,3-propanediol (3,3-dimethylol heptane), 3-methyl-1,5-pentanediol, 1,6-hexanediol, 2,2,4-trimethyl-1,3-pentanediol, 2-ethyl-1,3-hexanediol, 2-methyl-1,8-octanediol, 1,9-nonanediol, 1,10-decanediol, and 1,12-octadecanediol.

Examples of a divalent group derived from an aryl glycol of 6 to 12 for G₂ are a divalent group derived from: 1,2-dihydroxybenzene (catechol), 1,3-dihydroxybenzene (resorcinol), and 1,4-dihydroxybenzene (hydroquinone). Examples of a divalent group derived from an oxyalkylene glycol of 4 to 12 carbon atoms for G₂ are a divalent group derived from: diethylene glycol, triethylene glycol, tetraethylene glycol, dipropylene glycol, and tripropylene glycol.

G₂ may be one kind, or may be combined with two or more kinds. In particular, G₂ is preferably an alkylene glycol of 2 to 12 carbon atoms.

In Formula (2), B₃ and B₄ each represent a monovalent group derived from an aromatic ring containing monocarboxylic acid or an aliphatic monocarboxylic acid.

In a monovalent group derived from an aromatic ring containing monocarboxylic acid, the aromatic ring containing monocarboxylic acid is a carboxylic acid containing an aromatic ring in the molecule. It includes not only a compound having an aromatic ring directly bonded to a carboxylic group, but a compound having an aromatic ring bonded to a carboxylic group via a joint such as an alkylene group. Examples of a monovalent group derived from an aromatic ring containing monocarboxylic acid include a monovalent group derived from: benzoic acid, para-tertiary-butylbenzoic acid, ortho-toluic acid, meta-toluic acid, par-toluic acid, dimethylbenzoic acid, ethylbenzoic acid, n-propylbenzoic acid, aminobenzoic acid, acetoxybenzoic acid, phenylacetic acid, and 3-phenylpropionic acid. Among these compounds, preferred are benzoic acid and para-toluic acid.

Examples of a monovalent group derived from an aliphatic monocarboxylic acid include a monovalent group derived from: acetic acid, propionic acid, butanoic acid, caprylic acid, caproic acid, decanoic acid, dodecanoic acid, stearic acid, and oleic acid. Among them, preferable is a monovalent group derived from an alkyl monocarboxylic acid having an alkyl portion of 1 to 3 carbon atoms. More preferable is an acetyl group (a monovalent group derived from an acetic acid).

A weight average molecular weight (Mw) of a polyester according to the present invention is preferably in the range of 500 to 3,000. Preferably, it is in the range of 600 to 2,000. The weight average molecular weight can be measured by the aforesaid gel permeation chromatography (GPC).

Examples of a polyester having a structure represented by Formula (2) will be shown below, however, it is not limited to them.

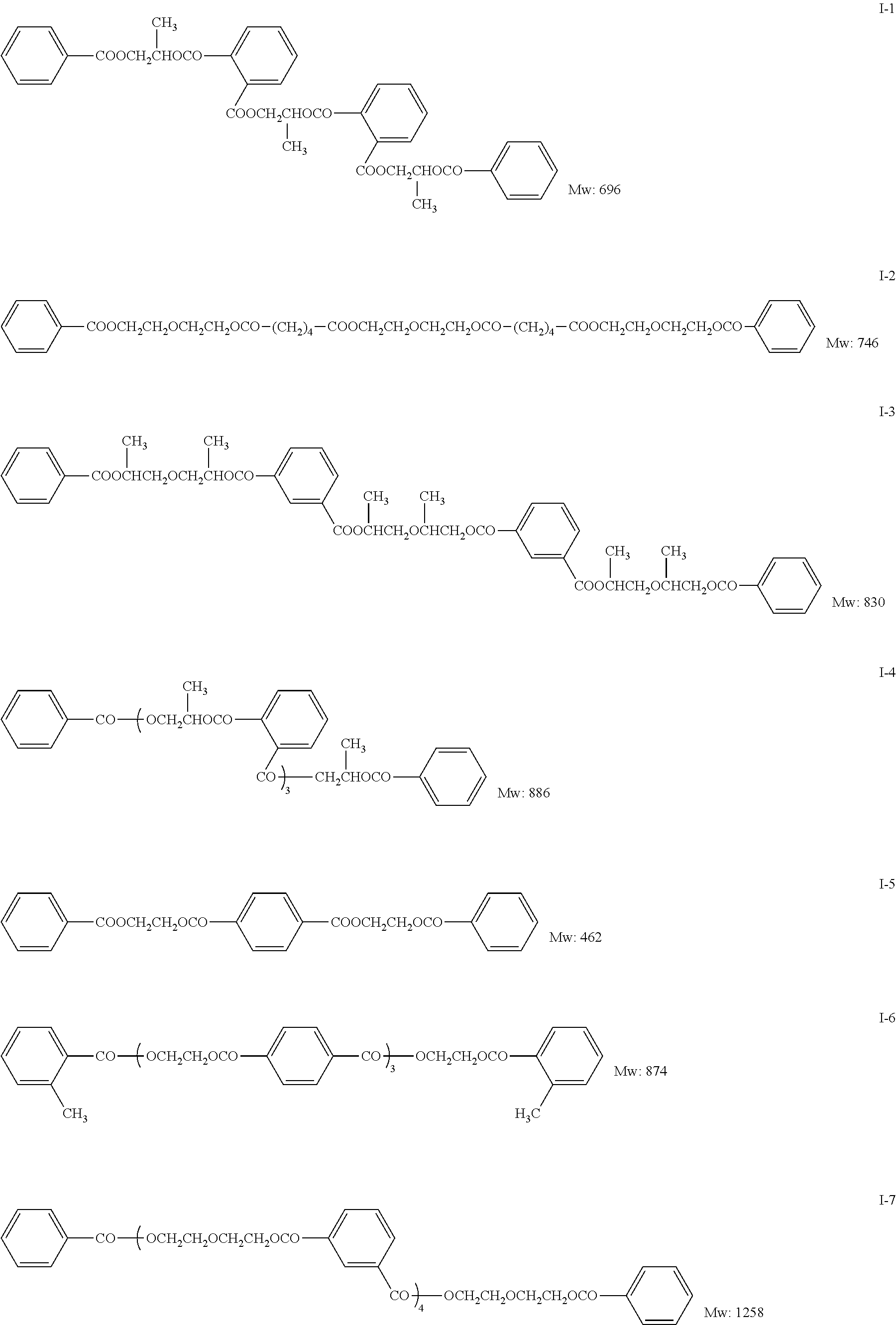

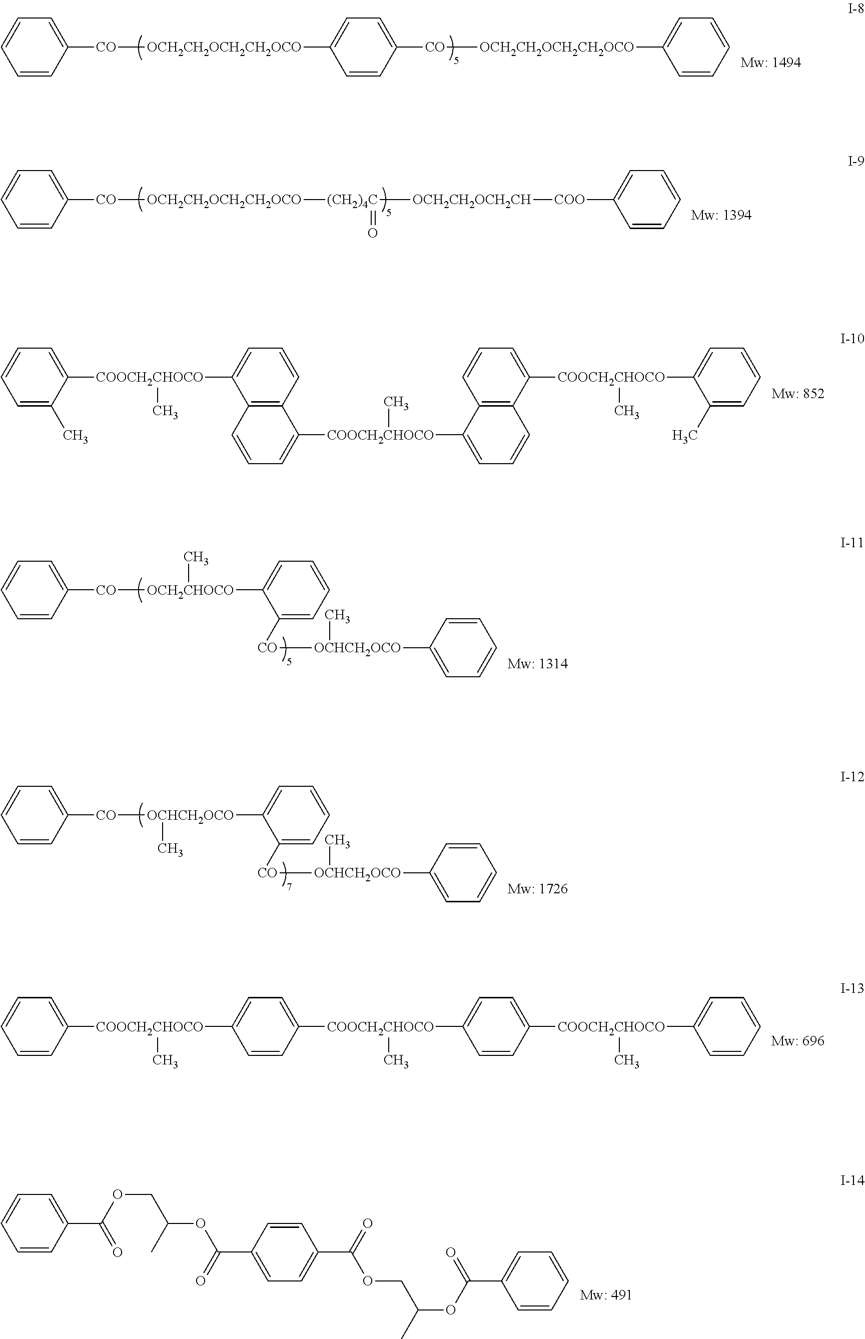

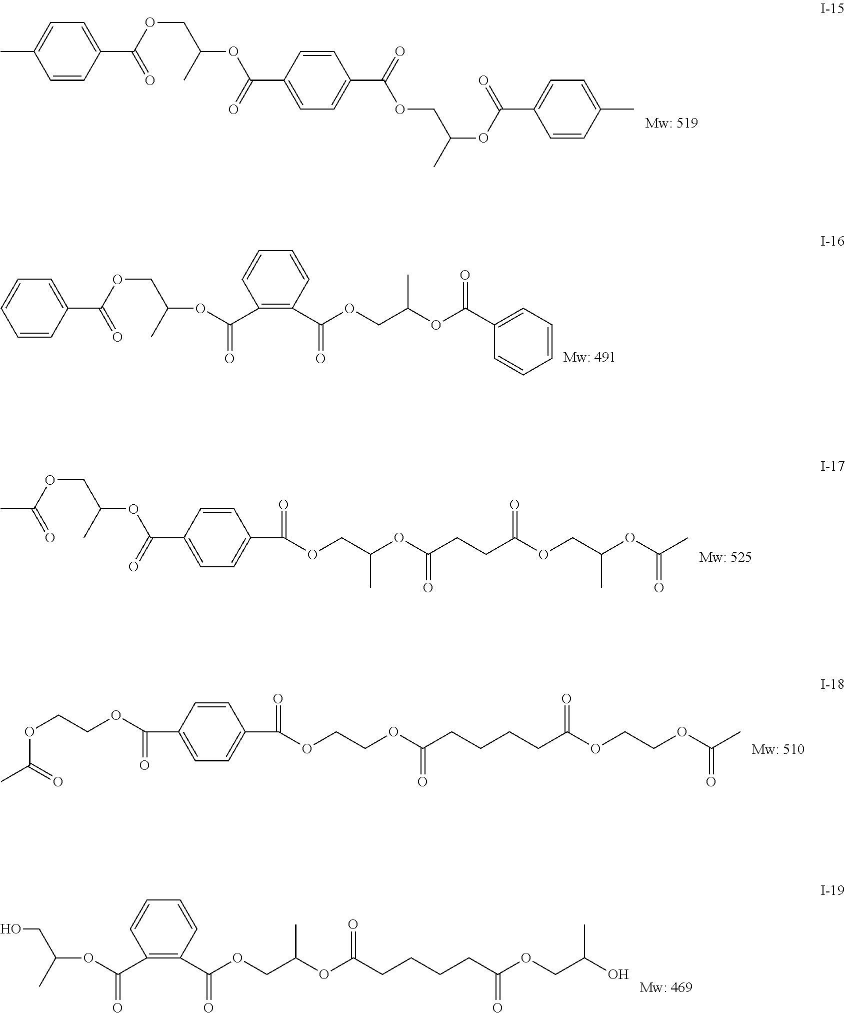

Specific synthetic examples of the above-described polyesters will be described below.

### <Polyester P1>

180 g of ethylene glycol, 278 g of phthalic anhydride, 91 g of adipic acid, 610 g of benzoic acid and 0.191 g of tetraisopropyl titanate as an esterification catalyst were placed into a 2 liter four-necked flask equipped with a thermometer, a stirrer and an Allihn condenser. The temperature was gradually raised to 230° C. in a nitrogen stream while the mixture was stirred. A condensation dehydration reaction was completed while observing polymerization degree. After completion of the reaction, unreacted ethylene glycol was distilled off under reduced pressure at 200° C. to obtain a polyester P1. The polyester P1 had an acid value of 0.20 (KOH mg/g), and a number

average molecular weight of 450.

### <Polyester P2>

251 g of 1,2-propylene glycol, 244 g of phthalic anhydride, 103 g of adipic acid, 610 g of benzoic acid and 0.191 g of tetraisopropyl titanate as an esterification catalyst were placed into a 2 liter four-necked flask equipped with a thermometer, a stirrer and an Allihn condenser. The temperature was gradually raised to 230° C. in a nitrogen stream while the mixture was stirred. A condensation dehydration reaction was completed while observing polymerization degree. After completion of the reaction, unreacted 1,2-propylene glycol was distilled off under reduced pressure at 200° C. to obtain a polyester P2. The polyester P2 had an acid value of 0.10 (KOH mg/g), and a number average molecular weight of 450.

### <Polyester P3>

330 g of 1,4-butane diol, 244 g of phthalic anhydride, 103 g of adipic acid, 610 g of benzoic acid and 0.191 g of tetraisopropyl titanate as an esterification catalyst were placed into a 2 liter four-necked flask equipped with a thermometer, a stirrer and an Allihn condenser. The temperature was gradually raised to 230° C. in a nitrogen stream while the mixture was stirred. A condensation dehydration reaction was completed while observing polymerization degree. After completion of the reaction, unreacted 1,4-butane diol was distilled off under reduced pressure at 200° C. to obtain a polyester P3. The polyester P3 had an acid value of 0.50 (KOH mg/g), and a number average molecular weight of 2,000.

### <Polyester P4>

251 g of 1,2-propylene glycol, 354 g of terephthalic acid, 610 g of benzoic acid and 0.191 g of tetraisopropyl titanate as an esterification catalyst were placed into a 2 liter four-necked flask equipped with a thermometer, a stirrer and an Allihn condenser. The temperature was gradually raised to 230° C. in a nitrogen stream while the mixture was stirred. A condensation dehydration reaction was completed while observing polymerization degree. After completion of the reaction, unreacted 1,2-propylene glycol was distilled off under reduced pressure at 200° C. to obtain a polyester P4. The polyester P4 had an acid value of 0.10 (KOH mg/g), and a number average molecular weight of 400.

### <Polyester P5>

251 g of 1,2-propylene glycol, 354 g of terephthalic acid, 680 g of p-toluic acid and 0.191 g of tetraisopropyl titanate as an esterification catalyst were placed into a 2 liter four-necked flask equipped with a thermometer, a stirrer and an Allihn condenser. The temperature was gradually raised to 230° C. in a nitrogen stream while the mixture was stirred. A condensation dehydration reaction was completed while observing polymerization degree. After completion of the reaction, unreacted 1,2-propylene glycol was distilled off under reduced pressure at 200° C. to obtain a polyester P5. The polyester P5 had an acid value of 0.30 (KOH mg/g), and a number average molecular weight of 400.

### <Polyester P6>

180 g of 1,2-propylene glycol, 292 g of adipic acid, and 0.191 g of tetraisopropyl titanate as an esterification catalyst were placed into a 2 liter four-necked flask equipped with a thermometer, a stirrer and an Allihn condenser. The temperature was gradually raised to 200° C. in a nitrogen stream while the mixture was stirred. A condensation dehydration reaction was completed while observing polymerization degree. After completion of the reaction, unreacted ethylene glycol was distilled off under reduced pressure at 200° C. to obtain a polyester P6. The polyester P6 had an acid value of 0.10 (KOH mg/g), and a number average molecular weight of 400.

### <Polyester P7>

160 g of ethylene glycol, 292 g of adipic acid, and 0.191 g of tetraisopropyl titanate as an esterification catalyst were placed into a 2 liter four-necked flask equipped with a thermometer, a stirrer and an Allihn condenser. The temperature was gradually raised to 200° C. in a nitrogen stream while the mixture was stirred. A condensation dehydration reaction was completed while observing polymerization degree. After completion of the reaction, unreacted ethylene glycol was distilled off under reduced pressure at 200° C. to obtain a polyester P7. The polyester P7 had an acid value of 0.10 (KOH mg/g), and a number average molecular weight of 1,000.

### <Polyester P8>

251 g of ethylene glycol, 244 g of phthalic anhydride, 200 g of sebacic acid, 610 g of benzoic acid and 0.191 g of tetraisopropyl titanate as an esterification catalyst were placed into a 2 liter four-necked flask equipped with a thermometer, a stirrer and an Allihn condenser. The temperature was gradually raised to 230° C. in a nitrogen stream while the mixture was stirred. A condensation dehydration reaction was completed while observing polymerization degree. After completion of the reaction, unreacted ethylene glycol was distilled off under reduced pressure at 200° C. to obtain a polyester P8. The polyester P8 had an acid value of 0.50 (KOH mg/g), and a number average molecular weight of 2,000.

An content of the above-described polyesters in the protective film is preferably in the range of 1 to 20 mass %, more preferably, it is in the range of 1.5 to 15 mass %.

### (Phosphoric Acid Ester Compound)

In the protective film according to the present invention, it may use a phosphoric acid ester compound. Examples of a phosphoric acid ester compound are: triaryl phosphoric acid ester, diaryl phosphoric acid ester, monoaryl phosphoric acid ester, aryl phosphonic acid ester compound, aryl phosphine oxide compound, condensed aryl phosphoric acid ester, halogenated alkyl phosphoric acid ester, halogen-containing condensed phosphoric acid ester, halogen-containing condensed phosphoric acid ester, and halogen-containing phosphorous acid ester.

Specific phosphate ester compounds are: triphenyl phosphate, 9,10-dihydro-9-oxa-10-phosphaphenanthrene-10-oxide, phenyl phosphonate, tris(β-chloroethyl)phosphate, tris(dichloropropyl)phosphate, and tris(tribromoneo pentyl)phosphate.

### (Glycol Acid Ester)

In the protective film according to the present invention, it may use a glycol acid ester (glycolate compound) as a kind of polyhydric alcohol ester compound.

Although a glycolate compound applicable to the present invention is not specifically limited, preferably used is an alkyl phthalyl alkyl glycolate.

Examples of an alkyl phthalyl alkyl glycolate are: methyl phthalyl methyl glycolate, ethyl phthalyl ethyl glycolate, propyl phthalyl propyl glycolate, butyl phthalyl butyl glycolate, octyl phthalyl octyl glycolate, methyl phthalyl ethyl glycolate, ethyl phthalyl methyl glycolate, ethyl phthalyl propyl glycolate, methyl phthalyl butyl glycolate, ethyl phthalyl butyl glycolate, butyl phthalyl methyl glycolate, butyl phthalyl ethyl glycolate, propyl phthalyl butyl glycolate, butyl phthaly propyl glycolate, methyl phthalyl octyl glycolate, ethyl phthalyl octyl glycolate, octyl phthalyl methyl glycolate, and octyl phthalyl ethyl glycolate. Preferable is ethyl phthalyl ethyl glycolate.

### (UV Absorber)

A protective film according to the present invention is used as a protective film disposed at a surface side (viewing side) of an organic EL display device. It is preferable that it contains a UV absorber from the viewpoint of improving light resistance. UV absorbers absorb ultraviolet light of 400 nm or less to enhance the durability. It is preferable that it has a transmittance at a wavelength of 370 nm of 10% or less, more preferably 5% or less, still more preferably 2% or less.

Examples of a UV absorber preferably used in the present invention include: benzotriazole UV absorber, benzophenone UV absorber, and triazine UV absorber. Specifically preferable compound are benzotriazole UV absorber and benzophenone UV absorber.

Specific examples of a UV absorber applicable to the present invention include: 5-chloro-2-(3,5-di-sec-butyl-2-hydroxylphenyl)-2H-benzotriazole, (2-2H-benzotriazol-2-yl)-6-(linear and branched dodecyl)-4-methylphenol, 2-hydroxy-4-benzyloxybenzophenone, and 2,4-benzyloxybenzophenone. The following are commercially available products: TINUVIN 109, TINUVIN 171, TINUVIN 234, TINUVIN 326, TINUVIN 327, TINUVIN 328, and TINUVIN 928 which are available from BASF SE Japan Ltd and they are preferably used. Among these, a compound without a halogen atom is more preferable.

In addition, a discotic compound having a 1,3,5-triazine ring is also preferably used as a preferable UV absorber.

Preferably, the protective film according to the present invention contains two or more kinds of UV absorber.

A polymer UV absorber may be also used. In particular, a polymer UV absorber described in JP-A 6-148430 is preferably used. Further, it is preferable that a UV absorber does not contain a halogen group.

The UV absorber can be added to the dope by the following methods: the UV absorber is dissolved in alcohol, for example, methanol, ethanol, or butanol; an organic solvent, for example, methylene chloride, methyl acetate, acetone, or dioxolane, or a mixture thereof, and then the mixture is added to the dope. Alternatively, the UV absorber is directly added to a dope composition.

UV absorbers insoluble in an organic solvent, such as inorganic powder, are added to the dope in the form of dispersion in a mixture of an organic solvent and cellulose ester (cellulose acetate) prepared with a dissolver or a sand mill.

An amount of a UV absorber to be added depends on the types of UV absorbers and conditions in use. When a protective film has a dry thickness of 15 to 50 μm, an amount is preferably 0.5 to 10 mass %, more preferably 0.6 to 4 mass % with respect to the total mass of the protective film.

### (Antioxidant)

An antioxidant is also referred to as anti-degradation agent. It may occur degradation of a protective film when an organic EL display device is placed under high humidity and high temperature conditions.

An antioxidant delays or prevents decomposition of a protective film caused by halogen in the residual solvent or phosphoric acid in the phosphoric acid plasticizer contained in the protective film. It is preferably contained in the protective film according to the present invention.

Examples an antioxidizing agent which can be used in the present invention are: 2,6-di-t-butyl-p-cresol, pentaerythrityl-tetrakis[3-(3,5-di-t-butyl-4-hydroxyphenyl)propionate], triethylene glycol-bis[3-(3-t-butyl-5-methyl-4-hydroxyphenyl)propionate], 1,6-hexandiol-bis[3-(3,5-di-t-butyl-4-hydroxyphenyl)propionate], 2,4-bis-(n-octylthio)-6-(4-hydroxy-3,5-di-t-butylanilino)-1,3,5-triazine, 2,2-thio-diethylene bis[3-(3,5-di-t-butyl-4-hydroxyphenyl)propionate], octadecyl-3-(3,5-di-t-butyl-4-hydroxyphenyl)propionate, N,N′-hexamethylene bis(3,5-di-t-butyl-4-hydroxy-hydrocinnamide), 1,3,5-trimethyl-2,4,6-tris(3,5-di-t-butyl-4-hydroxybenzyl)benzene, tris-(3,5-di-t-butyl-4-hydroxy-benzyl)-isocyanurate.

Particularly preferred are 2,6-di-t-butyl-p-cresol, pentaerythrityl-tetrakis[3-(3,5-di-t-butyl-4-hydroxyphenyl) propionate], and triethylene glycol-bis[3-(3-t-butyl-5-methyl-4-hydroxyphenyl) propionate]. A hydrazine metal deactivator, such as N,N′-bis[3-(3,5-di-t-butyl-4-hydroxyphenyl)propionyl]hydrazine, or a phosphorus process stabilizer, such as tris(2,4-di-t-butylphenyl)phosphate, can be used in combination.

These compounds are added to the cellulose ester (cellulose acetate) in a mass proportion of preferably 1 ppm to 1.0%, more preferably 10 to 1,000 ppm.

### (Fine Particles: Matting Agent)

To improve a slipping property of the surface of the protective film of the present invention, the film may contains fine particles (a matt agent) according to necessity.

The fine particles may be inorganic fine particles or organic fine particles. Examples of an inorganic fine particle are: silicon dioxide (silica), titanium dioxide, aluminum oxide, zirconium oxide, calcium carbonate, calcium carbonate, talc, clay, calcinated kaolin, calcinated calcium silicate, hydrated calcium silicate, aluminum silicate, magnesium silicate and calcium phosphate. Among them, silicon dioxide and zirconium oxide are preferable. Silicon dioxide is more preferable because it decrease haze in the obtained film.

Silicon dioxide particles are available on the market. Examples thereof are: Aerosil™ R972, R972V, R974, R812, 200, 200V, 300, R202, OX50, TT600, and NAX50 (made by Nippon Aerosil Co. Ltd.); and SEAHOSTAR™ KE-P10, KE-P30, KE-P50, and KE-P100 (made by Nippon Shokubai Co. Ltd.). Among them, Aerosil™ R972V, NAX 50 and SEAHOSTAR™ KE-P30 are particularly preferable because they enable to achieve a film of low turbidity and low friction coefficient.

A primary particle size of the fine particles is preferably in the range of 5 to 50 nm, and more preferably in the range of 7 to 20 nm. The larger the primary particles size, the lager the effect of improving the slipping property of the obtained film. However, the transparency tends to be decreased. Therefore, the fine particles may be incorporated as a secondary aggregated body (secondary particles) having a particles size in the range of 0.05 to 0.3 μm. A primary particle size or a secondary aggregated body of the fine particles can be measured as an average value obtained from 100 particles of the primary particles or the secondary aggregated bodies can be determined, by observing the primary particles and the secondary aggregated bodies by a transmission electron microscope with a magnifying power of 500,000 to 2,000,000.

A content of the fine particles is preferably in the range of 0.05 to 1.0 mass %, more preferably in the range of 0.1 to 0.8 mass % with respect to cellulose ester (cellulose triacetate).

### [Production Method of Protective Film]

A production method of a cellulose acetate protective film relating to the present invention may be applied any of the methods of: conventional inflation molding method, T-die method, calendaring method, cutting method, casting method, emulsion method, and hot pressing method. From the viewpoint of reducing tinting, contamination defects of foreign matter, and optical defects such as die lines, preferable methods are a solution casting film forming method and a melt casting film forming method. In particular, a solution casting method is preferable because it can produce a protective film having a required water swelling ratio.

### [Solution Casting Film Forming Method]

An example of a solution casting method for producing a protective film according to the present invention will be described in the following.

When a protective film according to the present invention is produced with a solution casting method, any organic solvent can be used without limitation for preparing a dope as long as it can dissolve both cellulose ester (cellulose acetate) and other compounds at the same time.

For example, methylene chloride is used as a chlorinated organic solvent. Examples of a non-chlorinated organic solvent are: methyl acetate, ethyl acetate, amyl acetate, acetone, tetrahydrofuran, 1,3-dioxolane, 1,4-dioxane, cyclohexanone, ethyl formate, 2,2,2-trifluoroethanol, 2,2,3,3-hexafluoro-1-propanol, 1,3-difluoro-2-propanol, 1,1,1,3,3,3-hexafluoro-2-methyl-2-propanol, 1,1,1,3,3,3-hexafluoro-2-propanol, 2,2,3,3,3-pentafluoro-1-propanol, nitroethane. Among them, methylene chloride, methyl acetate, ethyl acetate, and acetone are preferably used.

A dope preferably contains 1 to 40 mass % of straight-chain or branched-chain aliphatic alcohol with a carbon number of 1 to 4, in addition to the organic solvent described above. A dope with a high content of the aliphatic alcohol causes the web to gel and it is readily detachable from the metal support. A dope with a low content of the aliphatic alcohol has a role to promote dissolution of cellulose ester (cellulose acylate) and other compounds in a non-chlorinated organic solvent. In film formation of a protective film according to the present invention, it can apply a method of using a dope with an alcohol content in the range of 0.5 to 4.0 mass % by the reason that this dope will improve uniformity of a water swelling ratio in the obtained protective film and to achieve a variation coefficient of the water swelling ratio in a width direction to be 0.5% or less.

In particular, a preferable is a dope composition of cellulose ester (cellulose acylate) and other compounds in a total amount of 15 to 45 mass % dissolved in a solvent containing a methylene chloride and a straight-chain or branched-chain aliphatic alcohol with a carbon number of 1 to 4.

Examples of a straight-chain or branched-chain aliphatic alcohol with a carbon number of 1 to 4 include: methanol, ethanol, n-propanol, iso-propanol, n-butanol, sec-butanol, and tert-butanol. Among them, methanol and ethanol are preferred because they stabilize the dope and has a low boiling point and high volatility.

In the following, a preferable film formation method of a protective film according to the present invention will be described.

### (1) Dissolving Step

This step is a dope preparation step. A cellulose ester (cellulose acetate), and occasionally, other additives suitably used for the present invention (a sugar ester, a polymer (polyester), a polyhydric alcohol ester, or other additive) are placed with an organic solvent mainly composed of good solvent in a dissolution tank, and they are dissolved with stirring. Otherwise, a sugar ester, a polyester, a polyhydric alcohol ester, and other additive are mixed in a solution of the aforesaid cellulose ester (cellulose acetate) to prepare a dope used as a mail dissolved liquid.

A cellulose ester (cellulose acetate), and other additives suitably used for the present invention (a sugar ester, a polyester, a polyhydric alcohol ester, or other additive) may be dissolved by applying a variety of dissolving methods such as: a method carried out at normal pressure, a method carried out at the temperature under the boiling point of the main solvent, a method carried out under high pressure at the temperature over the boiling point of the main solvent, a cooled dissolving method described in JP-A 9-95544, JP-A 9-95557, and JP-A 9-95538, and a method carried out under high pressure described in JP-A 11-21379. In particular, it is preferable a method carried out under high pressure at the temperature over the boiling point of the main solvent.

A concentration of a cellulose ester (cellulose acetate) in a dope is not specifically limited. However, it is preferable that the concentration is in the range of 10 to 40 mass %. Other compound is added during dissolving the dope or after dissolving the dope, then, the mixture is dissolved and dispersed. Subsequently, it is filtered with a filtering medium and defoamed. Then, it is transferred to the next step with a liquid transfer pump.

A preferable filtering condition is to use a filtering medium having a catching particle size in the range of 0.5 to 5 μm and having a filter time in the range of 10 to 25 sec/100 ml.

In this method, an aggregated matter remained during dispersion of particles of matting agent, or an aggregated matter generated at the time of adding the main dope will be eliminated by using a filtering medium having a catching particle size in the range of 0.5 to 5 μm and having a filter time in the range of 10 to 25 sec/100 ml. The main dope has a sufficiently thin concentration of particles compared with an added liquid. Therefore, a rapid increase of filtering pressure will not be produced by mutual coagulation of aggregated matters.

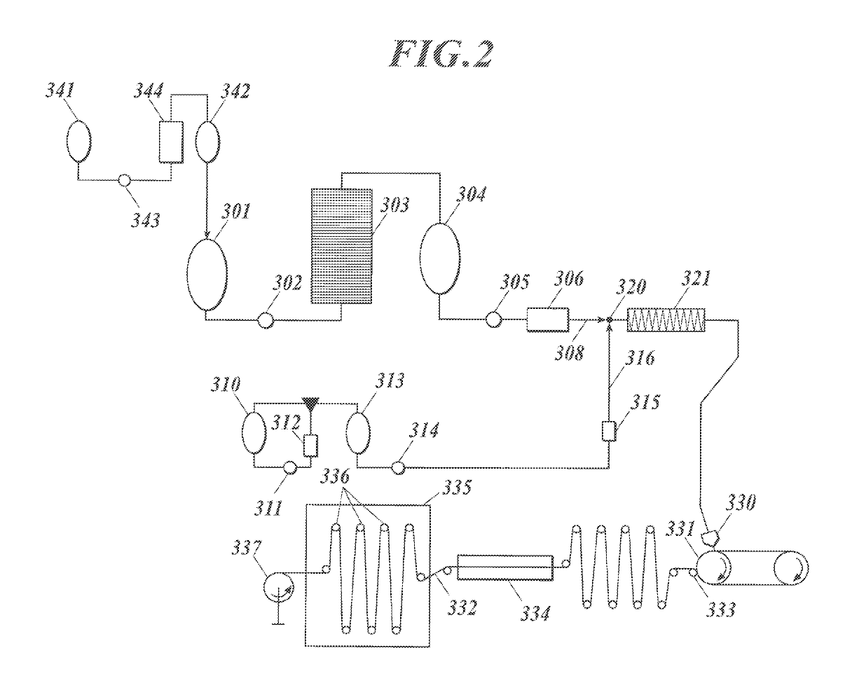

FIG. 2 is a figure which schematically illustrates an example of a dope preparation method, a cast step and a drying step of a solution cast film forming method preferable to the present invention.

Various kinds of additives are adjusted or prepared in a preparation tank 341, subsequently liquid transferred to a filtering apparatus 344 from the preparation tank 341 by means of a pump 343. After removing large sized aggregates with the filtering apparatus 344, it is liquid transferred to a stock tank 342. Thereafter, the various kinds of additives are added to a dissolving tank 301 for a main dope from the stock tank 342.

Thereafter, the main dope is liquid transferred to a main filtering apparatus 303 with a pump 302. To this is added in-line a UV absorber addition liquid through a conducting pipe 316. Here, a preparation step of a UV absorber addition liquid is omitted.

In many cases, the main dope may contain a recovered material in an amount of 10 to 50 mass %.

Here, a recovered material is composed of pulverized film pieces of a protective film. It is used film edge portions produced by cutting both sides of the film or the original product of cellulose ester film exceeding the prescribed values when the protective film is formed.

As a raw resin material which may be used for preparation of dope, it may be preferably used a pellet which is previously made with cellulose ester (cellulose acetate) and other compounds.

### (2) Casting Step

A dope is transferred in liquid to a pressure die 330 through a liquid transfer pump (for example, a pressure type fixed quantity gear pump). The dope is cast through a pressure die on a casting position of a metal support 331 having an endless metal belt endlessly transferring (for example, a stainless steel belt or a rotating metal drum).

It is preferable to use a die which can be adjusted a slit shape of a cap of the die for easily making a uniform layer thickness. Examples of a pressure die are: a coat hunger die and a T die. They may be preferably used. A surface of the metal support 331 is a specular surface. In order to increase the film forming speed, two or more pressure dies may be provided on the metal support 331 for laminate coating by dividing a dope amount. Otherwise, it is also preferable to obtain a film having a laminate structure with a co-doping method in which plural kinds of dopes are simultaneously cast.

### (3) Solvent Evaporation Step

This is a step of evaporating a solvent by heating a web (hereafter, a dope film formed by casting a dope on a casting support is called as a web) on a casting support 331.

Known methods for evaporating a solvent are: a method of blowing wing from a web side, a method of transferring heat with a liquid from the rear side of the support, a method of transferring heat on a front side and a back side with radiant heat. Among them, preferable is a method of transferring heat with a liquid from the rear side in view of high drying efficiency. In addition a combined method of the aforesaid methods is also preferably used. It is preferable that the cast web on the metal support 331 is dried on the support at the environment of 40 to 100° C. In order to maintain the environment of 40 to 100° C., it is preferable that a warm wind of this temperature range is blown on the upper surface of the web, or heating is done by means of infrared rays, for example.

From the viewpoint of surface quality, moisture permeability and peeling property, it is preferable to peel the web from the metal support 331 within 30 to 120 seconds.

### (4) Peeling Step

This is a step of peeling the web from the metal support 331 after evaporating the solvent at a peeling off position 333. The peeled web is transferred to the next step.

The temperature at the peeling off position 333 on the metal support 331 is preferably in the range of 10 to 40° C., and more preferably, in the range of 11 to 30° C.

An amount of residual solvent at the moment of peeling off the web on the metal support 331 is preferably in the range of 50 to 120 mass % depending on the degree of drying conditions or a length of the metal support 331. When the web is peeled off at the moment of having a large amount of residual solvent, and if the web is too soft, the flatness at peeling off moment will be damaged. It will easily generate uneven stretch or a vertical line caused by a peeling off tension. Therefore, an amount of residual solvent is decided by balancing a cost-effective speed and quality.

An amount of residual solvent is defined by the following equation (4).

Amount of residual solvent (%)=(Mass of the web before heat treatment−Mass of the web after heat treatment)/(Mass of the web after heat treatment)×100 Equation (4):

Here, the heat treatment at the time of measuring an amount of residual solvent designates a heat treatment at 115° C. for one hour.

The peeling tension for peeling the film from the metal support is usually in the range of 196 to 245 N/m, however, when it tends to produce wrinkles at the moment of peeling, it is preferable to peel off with the tension of 190 N/m or less.

In the present invention, it is preferable to set the temperature of the peeling off position 333 on the metal support 331 in the range of −50 to 40° C., more preferably in the range of 10 to 40° C., and most preferably in the range of 15 to 30° C.

### (5) Drying and Stretching Step

The web peeled off from the metal support 331 is dried. Drying of web may be done while transporting the web with many rollers situated above and under the web, or it may be done while transporting the web with fixing the edges of the web using clips.

The drying methods of web may be any drying method using: a heated air, a heated roller or a microwave. The drying method using a heated air is preferably used since it is a simple method. The drying temperature of web is in the range of about 40 to 250° C., and more preferably in the range of 40 to 160° C.

A preferable embodiment of the protective film according to the present invention is prepared by subjecting the film to a stretching treatment at first in a longitudinal direction (MD direction), subsequently or simultaneously, in a transversal direction (TD direction) so as to achieve a stretching of 1.3 to 1.7 times in an area ratio compared to an area of the film before stretching.

The stretching method of the web is a biaxially-stretching method in which the web is stretched at first in a longitudinal direction (MD direction), subsequently, it is stretched in a transversal direction (TD direction). The biaxially-stretching method includes an embodiment in which the web is stretched in one direction, then, the web is contracted by relieving tension in other direction.

### (6) Embossing Treatment Step

The protective film according to the present invention is a thin film having a thickness in the range of 15 to 40 μm. Therefore, it may be produced a rolling disorder or a deteriorated optical property (film surface uniformity) when it is stored in the condition of a laminated roll. These defects can be effectively prevented by subjecting to an embossing treatment to the film.

In order to avoid close contact of the front surface and the rear surface of the winded film, an embossed portion is provided on the edge portions of the film before winding the long film. It is made to have a fixed width pattern containing continuous fine unevenness. When one surface of the film (for example, upper face) is projected in a convex form, the other surface of the film (for example, rear face) is made to have a concave form corresponding to the aforesaid convex form.

### (7) Winding Step

This is a step of winding the web by a winding apparatus 337 as a protective film after making the amount of residual solvent to be 2 mass % or less. By making the amount of residual solvent to be 0.4 mass % or less, it can obtain a film having an excellent size stability. In particular, it is preferable to wind the film after making the amount of residual solvent in the range of 0.00 to 0.10 mass %.

Generally used winding methods may be used. Known winding methods are: a constant torque method, a constant tension method, a tapered tension method and a programed tension control method in which an inner stress is constant. These methods may be used by suitably selecting.

The protective film according to the present invention is preferably a long film. Specifically, it has a length of about 100 m to 10,000 m. Particularly preferable is a protective film in a roll laminate body having a length of 5,000 m or more. A preferable film width is 1 to 4 m, and a more preferable film width is 1.4 to 3 m.

### (8) Aging Treatment of Roll Laminate Body

A roll laminate body of a protective film prepared as described above is performed with a package treatment on the periphery thereof. Subsequently, it is subjected to an aging treatment under the condition of 50° C. or more for 3 days or more. By this treatment, it can obtain a protective film achieving a required water swelling ratio and a required variation coefficient of the water swelling ratio in the width direction. This is one of preferable embodiments.

A roll laminate body of a protective film according to the present invention is packed with a resin film for package. In particular, it is preferable that the periphery is packed with a moisture-proof film composed of a resin film for package evaporated with aluminum thereon, then, a winding shaft portion is fixed with a string or a rubber band to form a storing form.

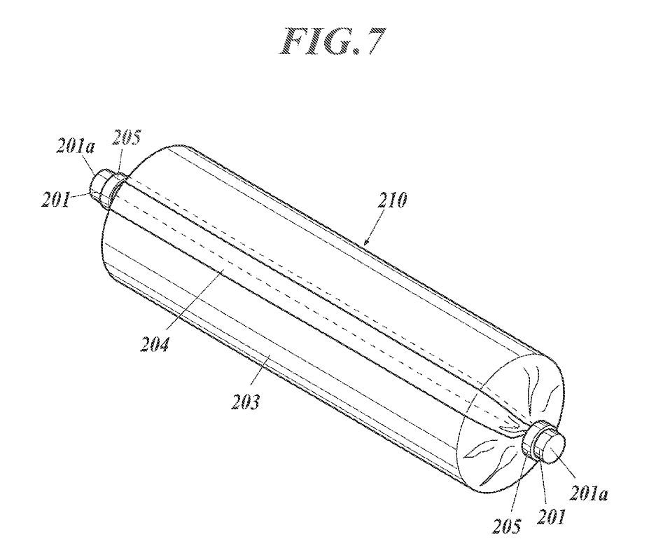

FIG. 7 shows a schematic diagram illustrating an example of a package embodiment of a roll laminate body of a protective film according to the present invention.

As shown in FIG. 7, an example of a package embodiment of a roll laminate body 210 of a protective film (cellulose ester film) according to the present invention has the following structure. The protective film is winded to a pipe shaped winding core 201. The peripheral surface and the right and left sides of the protective film are covered with a packaging material 203 in a sheet form. The both edges in the roll periphery direction are laminated with each other, and a packing tape is 204 is adhered on the bonding portion of the edges of the packaging material 203. As a result, there is generated no space at the contact portions of the edges of the packaging material 203. This can avoid penetration of a foreign matter to the interior of the roll. At the same time, the peripheral surface of the both edges of winding core 201a of the winding core 201, which are projected outside from the right and left sides of the roll film, and the bonding portion of the right and left edges of the packaging material 203 are fixed with a rubber band 205. There is a substantially small space between the peripheral surface of the both edges of winding core 201a and the right and left edges of the packaging material 203. Thus, it is preferable that the package is in a weakly hermetic sealed condition. Compared with a previously known package condition in which the right and left sides of the roll film are fixed with a rubber tape laminated many times, the embodiment in which the winding core portion is fixed with a string or a rubber band is preferable, because this structure enables to suitably absorb or release humidity of the roll body during storage or transporting the roll body to result in increasing uniformity of optical properties and physical properties of the optical film.

Examples of the aforesaid packaging material 203 are: polyolefin resin film such as polyethylene and polypropylene film; and polyester resin film such as polyethylene terephthalate and polyethylene naphthalate. A thickness of the packaging material 203 is preferably 10 μm or more from the viewpoint of maintaining a moisture-proof property. In addition, from the viewpoint of handling property such as rigidity, the thickness is preferably 100 μm or less. The moisture-proof property of the packaging material 203 varies depending on the thickness of the synthetic resin film constituting the packaging material 203. Therefore, the moisture-proof property of the packaging material 203 may be suitably adjusted by changing the thickness of the synthetic resin film.

Here, a preferable moisture-proof property of the packaging material 203 is a moisture permeability of 10 g/m² or less per day defined by JIS 20208. With this value, it can achieve a required water swelling ratio and a required variation coefficient of the water swelling ratio in the width direction. In addition, it can avoid degradation of winding shape and a foreign matter failure. It is preferable that a scratch failure due to the foreign matter failure will be reduced.

In a package embodiment 200 of a roll laminate body of a protective film according to the present invention, it is preferable to pack the roll laminate body of a protective film with a packaging material 203 having a moisture permeability of 5 g/m² or less per day defined by JIS 20208. It is more preferable to pack the roll laminate body with a packaging material 203 having a moisture permeability of 1 g/m² or less. The reason is that it can largely reduce the degradation in physical distribution during storage or transporting the film (degradation of winding shape, mutual adhesion of the films, generation of failure and foreign matter failure)

Examples of a packaging material 203 having a moisture permeability of 5 g/m² or less per day or 1 g/m² or less per day defined by JIS 20208 are: composite materials made of polyolefin resin film such as polyethylene and polypropylene film and polyester resin film such as polyethylene terephthalate and polyethylene naphthalate; composite materials made of these films on which metal such as aluminum is vapor deposited; or composite materials made of these films on which a metal thin film is laminated by being pasted. A thickness of the packaging material 203 composed of the aforesaid composite materials is preferably 1 μm or more from the viewpoint of maintaining the moisture-proof property, and it is preferably 50 μm or less from the viewpoint of handling property such as rigidity. The moisture-proof property of the packaging material 203 varies depending on the thickness of the composite materials. Therefore, the moisture-proof property of the packaging material 203 may be suitably adjusted by changing the thickness.

In particular, the following composite materials are preferably used because a high moisture-proof property can be obtained, and further, they are light for handling: composite materials made of polyolefin resin film such as polyethylene and polypropylene film and polyester resin film such as polyethylene terephthalate and polyethylene naphthalate; composite materials made of these films on which metal such as aluminum is vapor deposited; or composite materials made of these films on which a metal thin film is laminated by being pasted.

The aforesaid packaging material 203 will exhibit the effects as described above by wrapping at least singly the roll body of the protective film of the present invention. A preferable embodiment is a packaging embodiment wrapped doubly or more. It is preferable to perform an aging treatment in this embodiment at 50° C. or more for 3 days or more from the viewpoint of achieving a required water swelling ratio and a required variation coefficient of the water swelling ratio in the width direction.

The roll body of the protective film of the present invention wrapped in the packaging embodiment as described above can avoid degradation of winding shape in the long-term storage in a warehouse, or during transportation by a truck or a ship. It can provide a protective film having a uniform Martense hardness.

### [Polarizer]

A polarizer, which is a main component of a polarizing plate according to the present invention, transmits only a light component having a polarization plane in a predetermined direction. Typical known polarizers include polyvinyl alcohol polarizing films. The polyvinyl alcohol polarizing films are classified into polyvinyl alcohol films dyed with iodine and those dyed with dichroic dyes.

A polarizer can be prepared by the following procedure: A polyvinyl alcohol aqueous solution is formed into a film. The film is monoaxially stretched, then, it is dyed, or the film is dyed, then, it is monoaxially stretched. The resulting film is preferably treated with a boron compound to give durability. The polarizer has a thickness of in the range of about 2 to 30 μm. In the present invention, a preferable thickness is in the range of 2 to 15 μm.

Also preferred is an ethylene modified polyvinyl alcohol described in JP-A Nos. 2003-248123 and 2003-342322, which contains an ethylene unit in an average amount of 1 to 4 mol %, and has a degree of polymerization of 2,000 to 4,000, and a degree of saponification of 99.0 to 99.99 mol %. Among these films, preferred are ethylene modified polyvinyl alcohol films having a temperature for hot water cutting of 66 to 73° C. A polarizer composed of such an ethylene modified polyvinyl alcohol film has high polarization and high durability, and reduced color unevenness. Such a polarizer is particularly preferred in large-sized liquid crystal display devices.

Further, it is also preferable to produce a polarizing plate by bonding a protective film according to the present invention with a coating type polarizer prepared with a method described in JP-A 2011-100161, Japanese Patent No. 4691205, Japanese Patent No. 4751481 and Japanese Patent No. 4804589.

### [UV Curable Adhesive]

A polarizing plate according to the present invention is characterized that the cellulose ester film (the aforesaid protective film) is adhered to one surface of the polarizer by a UV curable adhesive.

A preferable embodiment is the case in which a retardation film that will be described later and a polarizer are also bonded through a UV curable adhesive.

In the present invention, it can obtain an excellent property of flatness with high productivity by applying a UV curable adhesive for bonding a protective film and a polarizer, or for bonding a retardation film and a polarizer.

### [Composition of UV Curable Adhesive]

As a composition of UV curable adhesive applicable to the production of a polarizing plate according to the present invention, there are known: a photo radical polymerization composition utilizing a photo radical polymerization; a photo cationic polymerization composition utilizing a photo cationic polymerization; and a hybrid composition utilizing a photo radical polymerization and a photo cationic polymerization jointly.

As a photo radical polymerization, it is known a composition which contains a radical polymerization compound having a polar group such as a hydroxy group or a carboxy group and a radical polymerization compound without containing a polar group with a specific ratio as described in JP-A 2008-009329. In particular, a preferable radical polymerization compound is a compound containing an ethylenically unsaturated bond which is possible to do a radical polymerization. An example of a compound containing an ethylenically unsaturated bond which is possible to do a radical polymerization is a compound contains a (metha)acryloyl group. Examples of a compound contains a (metha)acryloyl group includes: N-substituted (metha)acrylamide compounds, and (metha)acrylate compounds. Here, (metha)acrylamide indicates acrylamide or methacrylamide.

As a photo cationic polymerization, it is known a UV curable adhesive composition containing: (α) a cationic polymerization compound; (β) a photo cationic polymerization initiator; (γ) a photo sensitizer having an absorption maximum at a wavelength of longer than 380 nm; and (δ) a naphthalene sensitizer auxiliary agent, which is described in JP-A 2011-028234. However, it may be used other UV curable adhesive composition than this.

### (Pre-Treatment Step)

A pre-treatment step is a step to carry out an easy adhesion treatment on the bonding surfaces of a protective film and a polarizer. When a protective film A and a protective B are respectively adhered on each of the both surfaces of the polarizer, the surface of each protective film to be adhered with the polarizer is subjected to an easy adhesion treatment. Examples of an easy adhesion treatment are: a corona discharge treatment and a plasma treatment.

### (UV Curable Adhesive Applying Step)

In the UV curable adhesive applying step, the aforesaid UV curable adhesive is applied onto at least one of bonding surfaces of the polarizer and the protective film. When the UV curable adhesive is directly applied onto the surfaces of the polarizer or the protective film, there is no specific limitation to the application methods. It can utilize a variety of wet application methods such as: doctor blading, wire bar coating, die coating, comma coating, and gravure coating. The UV curable adhesive may also be applied by casting the UV curable adhesive between the polarizer and the protective film, subsequently applying pressure onto them with rolls to uniformly spread the adhesive.

### (Bonding Step)

After the UV curable adhesive is applied with the method described above, it is treated in the bonding step. In the bonding step, for example, when the UV curable adhesive is applied onto the surface of the polarizer in the previous applying step, the protective film is laminated thereon. When the UV curable adhesive is applied onto the surface of the protective film in the applying step, the polarizer is laminated thereon. When the UV curable adhesive is cast between the polarizer and the protective film, the polarizer and the protective film are laminated in this state. When the protective film and the retardation film (which will be described later) are bonded to both surfaces of the polarizer, and the UV curable adhesive are used on both surfaces, the protective film and the retardation film are laminated on the surfaces of the polarizer through the UV curable adhesive. In this state, pressure is usually applied through the pressure roller from both surfaces (from the polarizer and the protective film when the protective film is laminated on one surface of the polarizer, or from the protective film and the retardation film when the protective film and the retardation film are laminated on both surfaces of the polarizer). Metal or rubber may be used for the material of the pressure roller. The pressure rollers disposed on both surfaces may be composed of the same material or different materials.

### (Curing Step)

In the curing step, the uncured UV curable adhesive is irradiated with UV rays to cure the UV curable adhesive layer containing a cationic polymerization compound (for example, an epoxy compound and an oxetane compound) or a radical polymerization compound (for example, an acrylate compound and an acrylamide compound). Thus, the polarizer and the protective film, or the polarizer and the retardation film are bonded with the UV curable adhesive. When the protective film is bonded to one surface of the polarizer, any side of the polarizer or the protective film may be irradiated with the active energy rays. When the protective film and the retardation film are bonded to both surfaces of the polarizer, it is advantageous to irradiate with UV rays to cure simultaneously in the state of laminating the protective film and the retardation film on both surfaces of the polarizer through the UV curable adhesive.

Regarding to conditions of UV ray irradiation, any suitable conditions may be adopted as long as the UV curable adhesive is cured. An accumulated amount of irradiation of UV rays is preferably 50 to 1,500 mJ/cm², more preferably, it is 100 to 500 mJ/cm².

When the production process of the polarizing plate is done with a continuous on-line method, although the line speed depends on the curing time of the adhesive, it is preferably in the range of 1 to 500 m/min. More preferably, it is in the range of 5 to 300 m/min, and still more preferably, it is in the range of 10 to 100 m/min. When the line speed is 1 m/min or more, a high productivity can be secured, and the damage to the protective film may be controlled. When the line speed is 500 m/min or less, curing of the UV curable adhesive will be sufficient and it can form a UV curable adhesive layer having a targeted hardness and excellent adhesiveness.

### [Retardation Film]

A polarizing plate according to the present invention is characterized in having a retardation film along with a protective film and a polarizer.

Usually, as resin materials used for producing a retardation film are: cellulose resins (for example, cellulose ester films), acrylic resins, polycarbonate resins, and cycloolefin resins. In the present invention, it is preferable to use a film mainly composed of polycarbonate or cycloolefin. In particular, a film mainly composed of polycarbonate is preferable.

In the present invention, “a main component” indicates that among resin components constituting the retardation film, a ratio of polycarbonate or cycloolefin is 60 mass % or more, preferably 80 mass % or more, and more preferably 95 mass % or more.

### <Polycarbonate Resin>

A preferred polycarbonate resin used for a retardation film according to the invention is an aromatic polycarbonate prepared by the reaction of an aromatic dihydric phenol and a carbonate precursor.

The present invention may use any aromatic polycarbonate that allows the film to have desired characteristics. Usually, polymeric materials named as polycarbonates are collective term to the compounds prepared by polycondensation reaction and have main chains linked by a carbonate bond. In particular, polycarbonates are especially refer to those prepared by a polycondensation of a phenol derivative, phosgene, and diphenyl carbonate. An aromatic polycarbonate having repeating units and containing a bisphenol component of 2,2-bis(4-hydroxyphenyl)propane, generally called bisphenol A is preferably used. An aromatic polycarbonate copolymer may be prepared with any suitably selected bisphenol derivative.

Examples of a co-monomer component for composing a polycarbonate resin other than bisphenol A include: bis(4-hydroxyphenyl)methane, 1,1-bis(4-hydroxyphenyl)cyclohexane, 9,9-bis(4-hydroxyphenyl)fluorene, 1,1-bis(4-hydroxyphenyl)-3,3,5-trimethylcyclohexane, 2,2-bis(4-hydroxy-3-methylphenyl)propane, 2,2-bis(4-hydroxyphenyl)-2-phenylethane, 2,2-bis(4-hydroxyphenyl)-1,1,1,3,3,3-hexafluoropropane, bis(4-hydroxyphenyl)diphenylmethane, bis(4-hydroxyphenyl)sulfide, bis(4-hydroxyphenyl)sulfone, and 1,1-bis(4-hydroxyphenyl)-3,3,5-trimethylcyclohexane.

An aromatic polyester carbonate containing terephthalic acid or isophthalic acid component may be partly used. By using an aromatic polycarbonate of bisphenol A partially containing such a unit, it may improve the properties of aromatic polycarbonate, for example, high heat-resistance and solubility. These copolymers may be used in the present invention.

Alternatively, it may suitable use any of the polycarbonate resins disclosed in the following documents: JP-A 2006-131660, JP-A 2006-143832, JP-A 2006-232897, JP-A 2008-163107, JP-A 2008-222965, JP-A 2008-285638, JP-A 2010-134232, JP-A 2010-241883, JP-A 2010-261008, JP-A 2011-148942, and JP-A 2011-168742.

### <Cycloolefin Polymer>

As a retardation film according to the present invention, it is preferable to use a film containing cycloolefin composed of cycloolefin polymer.

A cycloolefin polymer usable in the present invention is made of a polymer resin having alicyclic structures. Examples of a preferred cycloolefin polymer include a resin made of a polymer or copolymer of a cyclic olefin. Examples of a cyclic olefin include: polycyclic unsaturated hydrocarbons and their derivatives, such as norbornene, dicyclopentadiene, tetracyclododecene, ethyltetracyclododecene, ethylidene tetracyclododecene, and tetracyclo[7.4.0.110,13.02,7]trideca-2,4,6,11-tetraen; and monocyclic unsaturated hydrocarbons and their derivatives, such as cyclobutene, cyclopentene, cyclohexene, 3,4-dimethylcyclopentene, 3-methylcyclohexene, 2-(2-methylbutyl)-1-cyclohexene, cyclooctene, 3a,5,6,7a-tetrahydro-4,7-methano-1H-indene, cycloheptene, cyclopentadiene, and cyclohexadiene. These cyclic olefins may have a polar group as a substituent. Examples of a polar group include: a hydroxy group, a carboxy group, an alkoxyl group, an epoxy group, a glycidyl group, a oxycarbonyl group, a carbonyl group, an amino group, an ester group, and a carboxylic anhydride group. Among them, preferred are an ester group, a carboxy group, and a carboxylic anhydride group.

A preferred cycloolefin polymer may be an addition copolymer with a monomer other than a cyclic olefin. Examples of a copolymerizable monomer include: ethylenes or α-olefins such as ethylene, propylene, 1-butene, and 1-pentene; and dienes such as 1,4-hexadiene, 4-methyl-1,4-hexadiene, 5-methyl-1,4-hexadiene, and 1,7-octadiene.

A cyclic olefin can be prepared by addition polymerization or metathesis ring-opening polymerization. The polymerization is usually carried out in the presence of a catalyst.

An example catalyst for addition polymerization is a polymerization catalyst composed of a vanadium compound and an organic aluminum compound.

Examples of a catalyst for ring-opening polymerization include polymerization catalysts composed of halides of metals, such as ruthenium, rhodium, palladium, osmium, iridium, and platinum, reducing agents, and nitrates or acetylacetone compounds; and polymerization catalysts composed of acetylacetone compounds or halides of metals, such as titanium, vanadium, zirconium, tungsten, and molybdenum, and organic aluminum compounds.

The polymerization may be carried out at any temperature and pressure, usually at a polymerization temperature in a range of −50 to 100° C. and a polymerization pressure in a range of 0 to 490 N/cm².

A cycloolefin polymer is preferably prepared by polymerization or copolymerization of a cyclic olefin, and then, by hydrogenation reaction to convert unsaturated bonds in the molecules into saturation bonds. The hydrogenation reaction is carried out with bubbling hydrogen in the presence of a known hydrogenation catalyst.

Examples of a hydrogenation catalyst include homogeneous catalysts composed of combinations of transition metal compounds and alkyl metal compounds, such as cobalt acetate and triethylaluminum, nickel acetylacetonate and triisobutylaluminum, titanocene dichloride and n-butyllithium, zirconocene dichloride and sec-butyllithium, and tetrabutoxytitanate and dimethyl magnesium; heterogeneous metal catalysts, such as nickel, palladium, and platinum; and heterogeneous solid catalysts composed of metals-on-carriers, such as nickel on silica, nickel on diatom earth, nickel on alumina, palladium on carbon, palladium on silica, palladium on diatomite, and palladium alumina.

Other examples of a cycloolefin polymer include the following norbornene resins. The norbornene resins should preferably have repeating units of a norbornene skeleton. Examples of such resins include those described in: JP-A S62-252406, JP-A S62-252407, JP-A H2-133413, JP-A 563-145324, JP-A S63-264626, JP-A H1-240517, Japanese Examined Patent Publication No. S57-8815, JP-A H5-2108, JP-A H5-39403, JP-A H5-43663, JP-A H5-43834, JP-A H5-70655, JP-A H5-279554, JP-A H6-206985, JP-A H7-62028, JP-A H8-176411, JP-A H9-241484, JP-A 2001-277430, JP-A 2003-139950, JP-A 2003-14901, JP-A 2003-161832, JP-A 2003-195268, JP-A 2003-211588, JP-A 2003-211589, JP-A 2003-268187, JP-A 2004-133209, JP-A 2004-309979, JP-A 2005-121813, JP-A 2005-164632, JP-A 2006-72309, JP-A 2006-178191, JP-A 2006-215333, JP-A 2006-268065, and JP-A 2006-299199. It is not limited to them. These compounds may be used alone or in combination. Cycloolefin polymers are available as commercial products. Specific examples include: Zeonex™ and Zeonor™ available from Zeon Corporation, Arton™ available from JSR Corporation, and Apel™ (APL8008T, APL6509T, APL6013T, APL5014DP, and APL6015T) available from Mitsui Chemicals, Inc.

A cycloolefin polymer may have any molecular weight depending on the intended use, and usually, it has a polyisoprene- or polystyrene-equivalent weight average molecular weight in the range of 5,000 to 500,000, preferably 8,000 to 200,000, more preferably 10,000 to 100,000 to achieve excellent balance between the mechanical strength and molding processability.

When a cycloolefin polymer is used for a retardation film, it is effective to apply a method of bonding a polarizer to the retardation film using a UV curable adhesive, since it cannot bond with an aqueous glue (a polyvinyl alcohol adhesive) after saponification of the surface as conventionally done.

### (Stretching Treatment of Retardation Film)

A preferable retardation film according to the present invention is a film obliquely stretched with respect to a longitudinal direction of the film.

In order to obliquely stretch a non-stretched film, it is preferable to use an apparatus which can obliquely stretch a film (oblique stretching tenter). The oblique stretching tenter applicable to the present invention is preferably as follows. It can appropriately determine the orientation angle of the film with a widely variable rail patterns, can provide an accurate and even orientation axis to the film across the width direction, and can accurately control the thickness and retardation of the film. Here, the orientation angle is an orientation direction caused by stretching of resin molecules in the film.

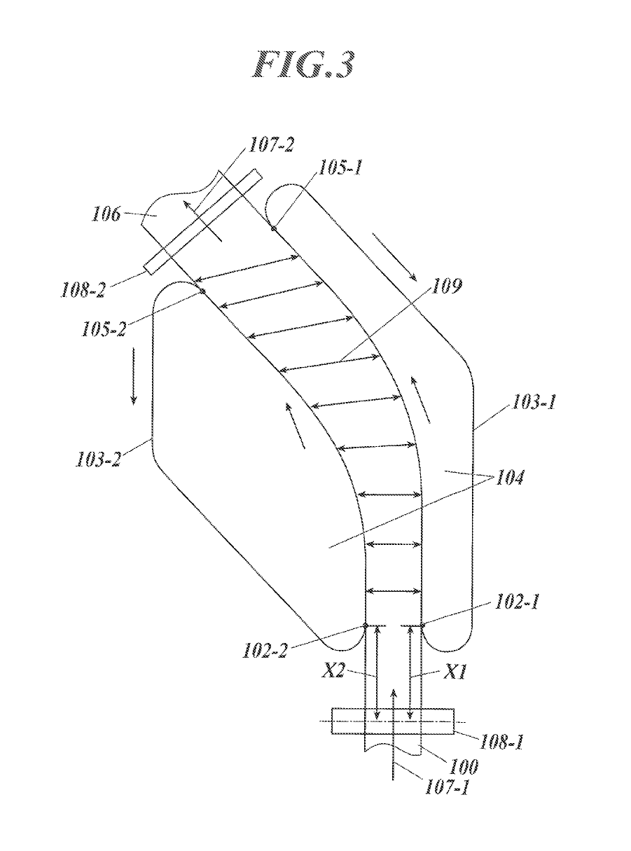

FIG. 3A is a schematic diagram illustrating an example oblique stretching tenter applicable to fabricating of an oblique stretching film according to the present invention. The example is for illustrative purpose, and the present invention is not limited to that.

The original non-stretched film 100 is directed toward a certain direction by a guide roller 108-1 located in the entrance of the tenter. The film 100 is caught with holders (called as clip holding portions) at a right side film catching position 102-1 and a left side film catching position 102-2, and it is conveyed and stretched by the oblique stretching tenter 104 in diagonal directions illustrated as a path 103-1 of the right side film holder and a path 103-2 of the left side film holder, it is released at a right side film releasing position 105-1 and a left side film releasing position 105-2, and it is conveyed under the control of an exit guide roller 108-2. This process yields an obliquely stretched film 106. In FIG. 3, the original non-stretched film is obliquely stretched in an angle of a stretching direction 109 of the film (called as an orientation angle θ) with respect to a film conveying direction 107-1, and it is rolled in the film winding direction 107-2 of the film.

In the present invention, distances X₁ and X₂ between the position of the main axis of the guide roller 108-1 located in the nearest portion of the entrance of the oblique stretching tenter and the holders located in the entrance of the oblique stretching tenter are preferably in the range of 20 to 10 cm. By retaining the aforesaid distance, it can maintain the flatness of the film when the film is caught, and it can stabilize optical properties such as an orientation angle θ in the longitudinal direction and retardation. The distances X₁ and X₂ are preferably in the range of 20 to 60 cm, and more preferably, in the range of 20 to 40 cm. Here, X₁ is a distance between the position of the main axis of the guide roller 108-1 and the holder (the clip holding portion) at a right side film catching position 102-1, and X₂ is a distance between the position of the main axis of the guide roller 108-1 and the holder (the clip holding portion) at a left side film catching position 102-2,

X₁ and X₂ may be: X₁═X₂ or X₁≠X₂. Preferably, X₁═X₂. In the present invention, X₁ and X₂ are preferably in the range of 20 to 100 cm.

When the distance between the position of the main axis of the guide roller 108-1 located in the nearest portion of the entrance of the oblique stretching tenter and the holders located in the entrance of the oblique stretching tenter is less than 100 cm, it can maintain the uniformity of the orientation angle θ of the obliquely stretched film, and this is preferable. An orientation angle θ designates an angle when a longitudinal angle is set to be 0°.

In order to make the distance of between the position of the main axis of the guide roller 108-1 located in the nearest portion of the entrance of the oblique stretching tenter and the holders of the oblique stretching tenter in the above-described range, the following ways may be adopted: to make the guide roller and the clip holding portions to have a mechanism enabling to adjust the positions; to make the length of the holder in the transporting direction to be 1 to 5 inches (1 inch=2.54 cm); to make the diameter of the guide roller 108-1 located in the nearest portion of the entrance of the oblique stretching tenter to be in the range of 1 to 20 cm; and to have a mechanism enabling to locate another roller at the neighborhood of the entrance of the oblique stretching tenter.

The fabrication of an obliquely stretched optical film according to the present invention is preferably done with a tenter capable of obliquely stretching a film as described above. The tenter increases the width of the original long film in a direction diagonal to the moving direction (traveling direction of the widthwise center of the film) while heating the film with an oven. The tenter includes an oven, a pair of right and left rails each defining the traveling path of holders to convey the film, and a large number of holders traveling along the rails. The film unrolled from a roll and sequentially fed to the entrance of the tenter, is held with the holders at the side edges of the film, is conveyed through the oven, and is released from the holders at the exit of the tenter. The film released from the holders is wound around a core. The pair of rails each are provided with an endless continuous track. The holders that release the film at the exit of the tenter will travel along the outer part of the rail and sequentially return to the entrance.

The right and left rails of the tenter have mutually different shapes that can be manually or automatically fine-adjusted depending on the desired orientation angle θ and stretching ratio of the long stretched film. In the present invention, the long optical film is stretched and it may have any orientation angle θ preferably between 10° to 80° from the winding direction of the stretched film. In the present invention, the holders in the tenter are made to move at a constant speed with having a fixed distance with each other.

The holders may travel at any speed, and typically at a speed between 1 to 100 m/min. The percentage of the difference in traveling speed between the right and left holders to the traveling speed is typically 1% or lower, preferably 0.5% or lower, and more preferably 0.1% or lower. The difference in moving speed between the right and left edges of the film would cause wrinkles and puckering of the film at the end of the stretching process; hence, the difference in traveling speed between the right and left holders should be substantially zero. The speed difference does not refer to irregularities in speed of less than one second (which often corresponds to several percent) caused by the teeth intervals of a sprocket driving a chain and the frequency of the drive motor in a general tenter.

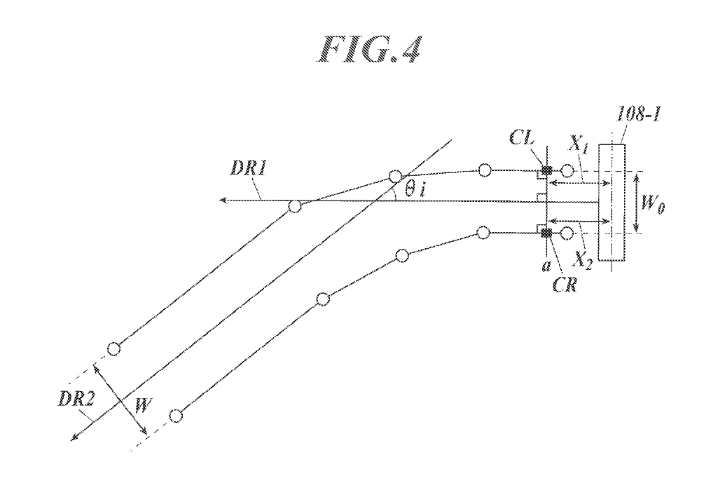

It is preferable in the oblique stretching tenter according to the present invention that the rail components and the joints therefor be disposed at any position. The oblique stretching tenter having a predetermined entrance width and exit width can achieve a stretching ratio corresponding to the widths (the symbols “0” in FIG. 4 represent the joints).

In the oblique stretching tenter according to the invention, the rails defining the paths of holders should often be greatly bent. It is desirable that a bend in the paths of the holders form an arc, to avoid interference between the holders or local concentration of stress due to a steep bend.

FIG. 4 illustrates an example of tracks of the rails (rail patterns) of the tenter used for producing an obliquely stretched optical film. A moving direction DR1 (film-feeding direction 107-1 in FGI. 3) of the non-stretched film at a tenter entrance is different from a moving direction DR2 (film winding direction 107-2 in FIG. 3) at a tenter exit after the stretching. By this configuration, homogeneous optical properties can be obtained in a wide range even in a stretched film having relatively large orientation angle θ. The feeding angle θi is an angle between the film moving direction DR1 at the entrance of the tenter before the stretching and the film moving direction DR2 at the exit of the tenter after the stretching.

In the present invention, the feeding angle θi of the optical film roll body is within 30°<θi<60° in order to fabricate the above-described preferable film having an orientation angle θ between 30° to 60°. More preferably, the feeding angle θi is 35°<θi<55°. The feeding angle θi within the preferable range can achieve a desired small variation in the optical characteristics of the resulting film in the width direction (i.e., variation in optical properties in its width direction can be reduced).

The optical film is successively held with the clips at a tenter entrance (the position represented by the letter “a”) at both edges (both sides) of the film, and then conveyed with the travelling clips. The right and left clips CR and CL face to each other in the direction almost perpendicular to the direction in which the film is conveyed (the feeding direction DR1) at the tenter entrance (the position represented by the letter “a”). The right and left clips CR and CL travel on the asymmetric rails as illustrated in FIG. 3 and pass through the oven in which a pre-heating zone, a stretching zone, and a cooling zone, are arranged. Here, the definition of “almost perpendicular to the feeding direction DR1” means that the angle between the line connecting the clip CR with the clip CL that face to each other and the film-feeding direction DR1 is 90±1°.

A temperature of each zone (pre-heating zone, a stretching zone, a holding zone, and a cooling zone) is preferably adjusted to be between Tg to (Tg+30° C.). Tg indicates the glass transition temperature of the thermoplastic resin of the optical film.

As a method of giving a density gradient of the residual solvent in the width direction of the film, it will be achieved by adjusting the drying conditions. For example, it will be done with methods of: adjusting the degree of opening of the nozzle which delivers the aforesaid warm current of air into the constant temperature room; or adjusting the heating conditions by arranging a heater at a width direction.

A length of a pre-heating zone, a stretching zone, a holding zone or a cooling zone may be suitably selected. Generally, the length of a pre-heating zone is in the range of 1.0 to 1.5 times of the total length of the stretching zone, and the holding zone is in the range of 0.5 to 1.0 times of the total length of the stretching zone.

In order to prevent appearance of wrinkles and puckering of the long stretched film, the following is preferable: to stretch the film while steadily supporting the film and maintaining its volatile component to at least 5 volume %, and then, to reduce the volatile component during the shrinkage of the film. The steady support of the film in the present invention refers to the holding of the side edges of the film while maintaining its characteristics. The volatile component may be maintained to be at least 5 volume % during the entire stretching process or during only a part of the stretching process. In the latter case, it is preferred that the volatile component be at least 12 volume % in at least 50% of the entire zones starting from the entrance. In both cases, the volatile component before the stretching process should preferably be at least 12 volume %. The volatile component (unit: volume %) refers to the volume of the volatile constituents of the film for unit volume, and is determined by dividing the volume of the volatile constituents by that of the film.

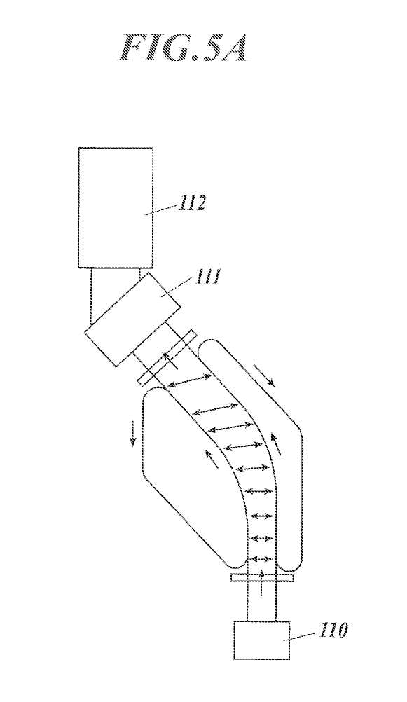

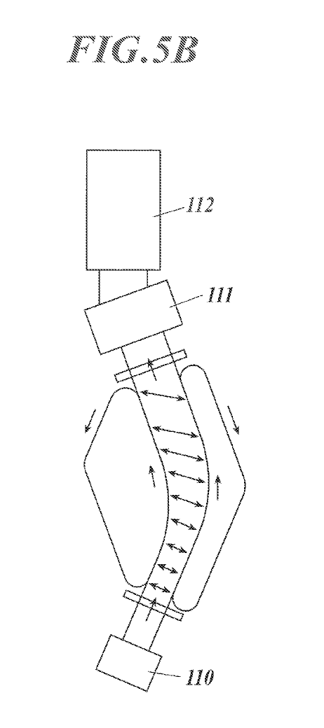

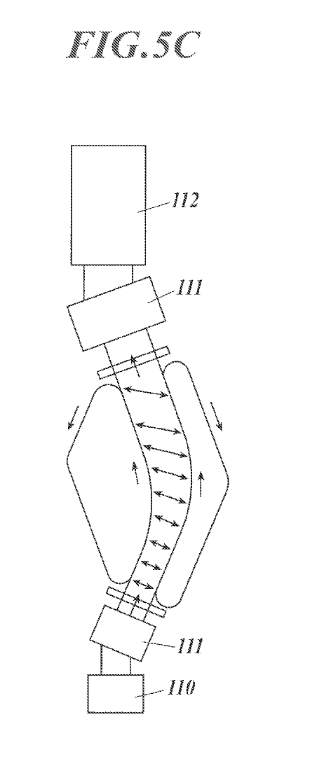

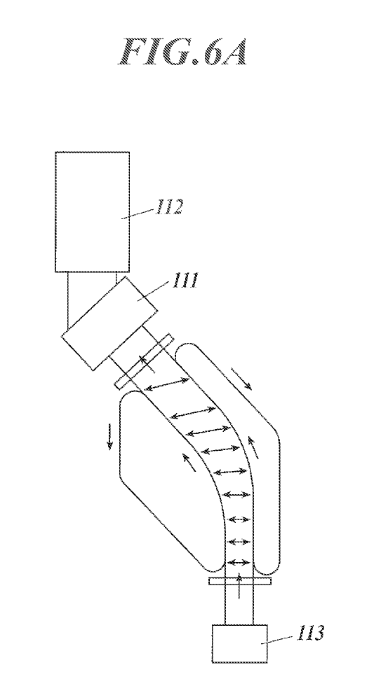

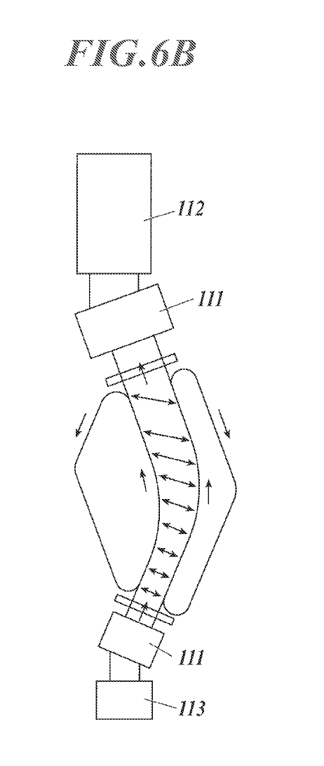

Regarding to the above-described various production patterns of an oblique stretching according to the present invention, FIGS. 5A to 5C illustrate an example of step of obliquely stretching a long film by feeding from a feeding apparatus. FIGS. 6A and 6B illustrate an example of step of obliquely stretching a long film continuously with online after forming a film with a film forming apparatus.

In each figures, there are shown a film feeding apparatus 110, a transport direction changing apparatus 111, winding apparatus 112 and a film forming apparatus 113.

It is preferable that the film feeding apparatus 110 is made: to be able to slide or rotate so as to feed the aforesaid film with a predetermined angle with respect to the entrance of the oblique stretching tenter; or to be able to slide so as to feed the aforesaid film to the entrance of the oblique stretching tenter through the transport direction changing apparatus 111.

### [Hard Coat Layer]

One of the features of a polarizing plate according to the present invention is to locate a hard coat layer on a protective film.

By locating a hard coat layer having a high surface hardness on a thin film protective film, it can increase durability of the polarizing plate against an outer pressure.

A preferable hard coat layer applicable to the present invention contains an actinic ray curable resin. Namely, the preferable hard coat layer according to the present invention is a layer mainly composed of a resin which is cured by irradiation with actinic rays such as UV rays or electron beams through a cross-linking reaction.

A preferred actinic ray curable resin contains a monomer component having an ethylenically unsaturated double bond. The resin is cured by irradiation with actinic rays such as UV rays or electron beams to form an actinic ray curable resin layer. Typical examples of an actinic ray curable resin include UV curable resins and electron beam curable resins, but UV ray curable resins are preferable in view of superior mechanical strength (abrasion resistivity and pencil hardness).

Examples of UV curable resins are: UV curable acrylate resins, UV curable urethane acrylate resins, UV ray curable polyester acrylate resins, UV curable epoxy acrylate resins, UV curable polyol acrylate resins, and UV curable epoxy resins. Among these resins, most preferred are UV curable acrylate resins.

Preferable UV ray curable acrylate resins are polyfunctional acrylates. Examples of a polyfunctional acrylate are preferably selected from the group consisting of pentaerythritol polyacrylates, dipentaerythritol polyacrylates, pentaerythritol polymethacrylates, and dipentaerythritol polymethacrylates. Here, a polyfunctional acrylate is a compound having two or more acryloyloxy or methacryloyloxy groups in the molecule.

Preferable examples of a monomer of the polyacrylate compound include: ethylene glycol diacrylate, diethylene glycol diacrylate, 1,6-hexanediol diacrylate, neopentylglycol diacrylate, trimethylolpropane triacrylate, trimethylolethane triacrylate, tetramethylolmethane triacrylate, tetramethylolmethane tetraacrylate, pentaglycerol triacrylate, pentaerythritol diacrylate, pentaerythritol triacrylate, pentaerythritol tetraacrylate, glycerol triacrylate, dipentaerythritol triacrylate, dipentaerythritol tetraacrylate, dipentaerythritol pentaacrylate, dipentaerythritol hexaacrylate, tris(acryloyl oxyethyl)isocyanurate, ethylene glycol dimethacrylate, diethylene glycol dimethacrylate, 1,6-hexanediol dimethacrylate, neopentylglycol dimethacrylate, trimethylolpropane trimethacrylate, trimethylolethane trimethacrylate, tetramethylolmethane trimethacrylate, tetramethylolmethane tetramethacrylate, pentaglycerol trimethacrylate, pentaerythritol dimethacrylate, pentaerythritol trimethacrylate, pentaerythritol tetramethacrylate, glycerol trimethacrylate, dipentaerythritol trimethacrylate, dipentaerythritol tetramethacrylate, dipentaerythritol pentamethacrylate, dipentaerythritol hexamethacrylate, isobornyl acrylate, and an active energy ray curable isocyanurate derivative.

These compounds are available on the market. Examples of commercially available compounds include: Adeka Optomer N Series (ADEKA Corporation); SUNRADs H-601, RC-750, RC-700, RC-600, RC-500, RC-611, and RC-612 (Sanyo Chemical Industries, Ltd.); SP-1509, SP-1507, Aronix M-6100, Aronix M-8030, Aronix M-8060, Aronix M-215, Aronix M-315, Aronix M-313, and Aronix M-327 (Toagosei Co., Ltd.); NK Ester A-TMM-3L, NK Ester AD-TMP, NK ESTER ATM-35E, NK Ester ATM-4E, NK Ester A-DOG, NK Ester A-IBD-2E, A-9300, and A-9300-1CL (Shin-Nakamura Chemical Co., Ltd.), and Light acrylate TMP-A and Light acrylate PE-3A (Kyoeisha Chemical Industry Co., Ltd.).

Monofunctional acrylates may be used for UV ray curable acrylate resins. Examples of a monofunctional acrylate include: isoboronyl acrylate, 2-hydroxy-3-phenoxypropyl acrylate, isostearyl acrylate, benzyl acrylate, ethylcarbitol acrylate, phenoxyethyl acrylate, lauryl acrylate, isooctyl acrylate, tetrahydrofurfuryl acrylate, behenyl acrylate, 4-hydroxybutyl acrylate, 2-hydroxyethyl acrylate, 2-hydroxypropyl acrylate, and cyclohexyl acrylate. Such monofunctional acrylates are available from Nippon Kasei Chemical Co., Ltd., Shin-Nakamura Chemical Co., Ltd. or Osaka Organic Chemical Industry Ltd.

The hard coat layer preferably contains a photopolymerization initiator in order to accelerate the curing of the actinic ray curable resin. The photopolymerization initiator may be contained preferably in a mass ratio of the photopolymerization initiator to the actinic ray curable resin being 20:100 to 0.01:100. Specific examples of the photopolymerization initiator include: alkylphenone, acetophenone, benzophenone, hydroxybenzophenone, Michler's ketone, α-amyloxim ester, thioxanthone, and derivatives thereof, however, it is not particularly limited to them.

Examples of a usable photopolymerization initiator may include commercially available products. Preferable examples are: Irgacure 184, Irgacure 907, and Irgacure 651 available from BASF Japan Ltd.

The hard coat layer can be formed as follows: preparing a hard coat layer composition, which contains the components for the hard coat layer diluted with solvent (hereinafter referred to as a hard coat layer coating composition); this hard coat layer coating composition is coated on a protective film which composes a polarizer; then it is dried, and cured to result in forming a hard coat layer.

A thickness of a hard coat layer is in the range of 0.05 to 20 μm as an average. Preferably, it is in the range of 1 to 10 μm. The hard coat layer coating composition can be applied by any well-known wet coating process with, for example, a gravure coater, a dip coater, a reverse coater, a wire bar coater, a die coater, or an ink-jet printer. The hard coat layer can be formed by applying the hard coat layer coating composition with the above-described process, and then the resultant coating layer is dried and subjected to a UV ray irradiation process, followed by heat treatment after the UV ray irradiation process, if necessary.

Any light source that emits ultraviolet rays can be used for UV irradiation treatment without limitation. Examples of a light source include: low-pressure mercury lamp, middle-pressure mercury lamp, high-pressure mercury lamp, ultra-high-pressure mercury lamp, carbon arc lam, metal halide lamp, and xenon lamp.

Irradiation conditions depend on the type of the lamp to be used. For example, the irradiation dose of actinic rays is in the range of 50 to 1,000 mJ/cm², preferably from 50 to 500 mJ/cm².

### [Surface Treatment Layer: Functional Layer]

A polarizing plate according to the present invention may be provided with a hard coat layer laminated on the protective film. In addition, it may be further provided with a functional layer thereon when needed.

For example, it may be cited the following constitutions.

Protective film/hard coat layer/low refractive index layer;

Protective film/hard coat layer/high refractive index layer/low refractive index layer; and

Protective film/hard coat layer/high refractive index layer/low refractive index layer/high refractive index layer/low refractive index layer.

As a constitution of the aforesaid high refractive index layer and low refractive index layer, it can be applied known high refractive index layers and low refractive index layers used for previously known antireflection films.

### <<Organic Electroluminescent Display Device>>

A polarizing plate according to the present invention is characterized in constituting an organic electroluminescent display device (organic EL display device) together with an organic electroluminescent element unit.

An organic EL display device D of the present invention has the following constitution as exemplified in FIG. 1. An organic EL display device D is formed with: an organic electroluminescent element unit E which contains on a substrate 1, a TFT 2, a metal electrode 3, ITO 4, a hole transport layer 5, a light emitting layer 6, a buffer layer 7, a cathode 8, ITO 9, an insulating layer 10, an adhesive layer A and a sealing glass; and a polarizing plate F of the present invention which are placed on the organic electroluminescent element unit E through an adhesive layer B (13). It is required to place a protective film 17 and a retardation film 14 sandwiching the polarizer, the protective film 17 being on a surface side (a viewing side) and the retardation film 14 being on a side of the organic electroluminescent element unit E.

In general, in an organic EL display device, a metal electrode, an organic layer and a transparent electrode are laminated in this order on or over a transparent substrate to form an element that emits light (organic EL element). The organic layer is composed of laminated various thin organic layers. Examples include laminates with various known layer compositions: a laminate a hole-injecting layer formed of a triphenyl amine derivative or the like and a light-emitting layer formed of a fluorescent organic solid material such as anthracene and/or a phosphorescent substance, a laminate composed of such a light-emitting layer and an electron-injecting layer formed of a perylene derivative or the like, and a laminate composed of such a hole-injecting layer, such a light-emitting layer and such an electron-injecting layer, for example.

Light emission in the organic EL display device occurs on the following mechanism: holes and electrons are injected into a light-emitting layer upon voltage application to a transparent electrode and a metal electrode, energy is generated upon recombination of the holes and the electrons, the energy excites a fluorescent substance or a phosphorescent substance, and the excited fluorescent substance or the excited phosphorescent substance returns to the ground state and then emits light. Mechanisms of the recombination is similar to those of a conventional diode, and thus, current and luminance intensity show strong nonlinearity with rectification properties to the applied voltage as it can be anticipated from that similarity.

In the organic EL display device, at least one of the electrodes is required to be transparent to extract light from the light-emitting layer. Normally, a transparent electrode formed of a transparent electroconductive material such as indium tin oxide (ITO) is used as an anode. On the other hand, to increase efficiency of light emission by enhancing electron injection, it is important to use a material having small work function in a cathode. Normally, a metal electrode formed of Mg—Ag, Al—Li or the like is used.

In the organic EL display device of such a configuration, the light-emitting layer is a very thin layer with a thickness of about 10 nm. Thus, the light emitting layer almost completely transmits light, like the transparent electrode. As a result, when light incident from outside of the transparent electrode passes through the transparent electrode and the light emitting layer and then reflected by the metal electrode, this light travels to outside the transparent electrode again. Thus, a displaying surface of the organic EL display device is seen as a specular surface when viewed from the outside.

In an organic EL display device which contains an organic EL element including a transparent electrode in the viewing side of the light emitting layer which emits light by voltage application and a metal electrode in the reverse side of the light emitting layer, it can achieve the following by locating a circularly polarizing plate on a surface of the transparent electrode (viewing side). The light passing through the circularly polarizing plate will pass through the transparent substrate, the transparent electrode, and the transparent thin film. This light is reflected on the metal electrode and again passes through the transparent thin film, the transparent electrode and the transparent substrate. This light becomes again linearly polarized light by the circularly polarizing plate. This linearly polarized light is perpendicular to the polarizing direction of the polarizing plate and thus cannot pass through the polarizing plate. As a result, the specular surface of the metal electrode can be made completely invisible.

A polarizing plate according to the present invention may use a obliquely stretched A/4 retardation film together with a protective film of the present invention. This polarizing plate is preferably used as a polarizing plate for an organic electroluminescent element applied to an organic electroluminescent display device.

### EXAMPLES

Hereafter, the present invention will be described specifically by referring to Examples, however, the present invention is not limited to them. In Examples, the term “%” is used. Unless particularly mentioned, it represents “mass %”.

### Example 1

### Protective Film

### Preparation of Cellulose Ester Film

### [Preparation of Cellulose Ester Film 1]

### (Preparation of Fine Particle Dispersion Diluted Liquid)

A mixed liquid of 10 mass parts of Aerosil 972V (an average primary particle size of 16 nm; an apparent specific gravity of 90 g/L) with 90 mass parts of ethanol was stirred in a dissolver for 30 minutes. Then, it was dispersed in a Manton Gaulin type homogenizer to prepare a fine particle dispersion liquid.

To the prepared fine particle dispersion liquid was added 88 mass parts of dichloromethane with stirring. Then, it was stirred in a dissolver for 30 minutes for diluting. The obtained solution was filtered with a polypropylene wind cartridge filter (product number: TCW-1N-PPS (filter precision: 1 μm), made by Advantec Toyobo Co. Ltd.) to obtain a fine particle dispersion diluted liquid.

### (Preparation of Inline Additive Liquid)

15 mass parts of a UV absorber TINUVIN 928 (2-(2H-benzotriazole-2-yl)-6-(1-methyl-1-phyenylethyl)-4-(1,1,3,3-tetramethylbutyl)phenol, made by BASF Japan Ltd.) and 100 mass parts of dichloromethane were placed in an airtight container and they were heated with stirring to dissolve completely. Then the solution was filtered. To the obtained UV absorber solution was added 36 mass parts of the aforesaid fine particle dispersion diluted liquid with stirring. After further stirring for 30 minutes, 6 mass parts of cellulose ester 1 (average degree of acetyl group substitution=2.90, Mn=90,0000, Mw=152,000, Mw/Mn=1.7) was added with stirring, then it was further stirred for 60 minutes. The obtained solution was filtered with FINEMET NF (made by Nippon Seisen Co. Ltd.) to prepare an inline additive liquid. The filtering medium of nominal filtering precision of 20 μm was used.

### (Preparation of Dope 1)

The following components were placed in an airtight container and they were heated with agitation to dissolve completely. The obtained solution was filtered through Azumi filter paper No. 24 made by Azumi Filter Paper Co. Ltd. to prepare a main dope 1.

### <Composition of Main Dope 1>

| | |
|---|---|
| Cellulose acetate 1 (average degree of acetyl group | 83.5 mass parts |
| substitution = 2.90, Mn = 90,000, Mw = 152,000, | |
| Mw/Mn = 1.7) | |

Polyhydric alcohol ester (Compound of Formula (1));

| | | |
|---|---|---|
| Example compound 1-10 | 1.5 | mass parts |
| Sugar ester; BzSc (Benzyl saccharose) (average ester | 10.0 | mass parts |
| substitution = 6.0) | | |
| Polyester; Polyester P1 | 5.0 | mass parts |
| Dichloromethane | 430 | mass parts |
| Ethanol | 11 | mass parts |

100 mass parts of the abovementioned main dope 1 and 2.5 mass parts of the inline additive solution were sufficiently mixed with an inline mixer (Static type inner tube mixer Hi-Mixer, SWJ, made by TORAY Co. Ltd.) to obtain a dope 1. The concentration of alcohol (ethanol) in the prepared dope 1 was 2.0 mass %.

### (Film Forming Step)

The obtained dope 1 was uniformly cast on a stainless-steel belt support using a belt type cast apparatus shown in FIG. 2. The liquid temperature of the dope 1 was 35° C., the width of the cast dope was 1.95 m and the final thickness was 20 μm. The organic solvent in the obtained dope film was evaporated on the stainless-steel belt support to an extent that the remaining organic solvent became 100 mass % to result in forming a web. The obtained web was peeled from the stainless-steel belt support. The obtained web was further dried at 35° C., then it was slit to have the width of 1.90 m. Afterward, the web is successively stretched under the condition of 160° C. Specifically, at first, the web was stretched to 1.1 times in the longitudinal direction (MD direction) using a nip roller. Subsequently, the web was stretched to 1.3 times in the transversal direction (TD direction) using a tenter. The stretching ratio in an area ratio was 1.43 times. The amount of the residual solvent in the web at the initial time of the stretching was 2.0 mass %. Then, the obtained film was dried at 120° C. for 15 minutes while transporting in the drying apparatus with many rollers. Subsequently, the film was slit in a sheet having a width 2.4 m, and a long cellulose ester film 1 having a length of 4,000 m with a thickness of 20 μm was wound in a roll in a longitudinal direction to prepare a roll laminate body 1.

### (Aging Treatment of Laminate Roll Body)

According to a method described in FIG. 7, a package form 210 of a laminate roll body 1A was prepared.

An outer circumference of a laminate roll body 1 was doubly packed using a moisture-proof film packaging material 203, which was composed of a polyethylene resin film of a thickness of 50 μm with vapor deposited aluminum thereon. The edged of the winding core 201a was fixed with a rubber band 205 to prepare a laminate roll body 1A.

Subsequently, the prepared laminate roll body 1A was subjected to an aging treatment of 3 days under a constant temperature of 50° C. to obtain a cellulose ester film 1.

### [Preparation of Cellulose Ester Films 2 to 38]

Cellulose ester films 2 to 38 were prepared in the same manner as preparation of the above-described cellulose ester film 1 except that there were changed: the kind of cellulose ester film, the kind of polyhydric alcohol ester, the kind of sugar ester (change in average degree of ester substitution), the kind of polyester, and presence or absence of other additive at the time of a dope preparation; presence or absence of aging treatment, stretching conditions, and layer thickness as indicated in Table 1 and Table 2.

TABLE 1

| | Dope composition | | | | | | | | | | | | | | | |
|---|---|---|---|---|---|---|---|---|---|---|---|---|---|---|---|---|
| | | | Additive | | | | | | | | | | | | | |
| | | | Compound | | | | | | | | | | | | | |
| | | | represented by | | | | | | | | | | | | | |
| | | | Formula (1) | | Sugar ester | | | Polyester | | Other additive | | Stretching conditions | | | | |
| | | | Exam- | Added | | | Added | | Added | | Added | | | Stretch- | Layer | |
| Cellulose | | | ple | amount | | | amount | Exam- | amount | | amount | MD | TD | ing | thick- | |
| ester | *A | | com- | (mass | | | (mass | ple | (mass | | (mass | direction | direction | magni- | ness | |
| film No. | No. | *1 | pound | %) | Kind | *2 | %) | No. | %) | Kind | %) | (times) | (times) | fication | (μm) | *3 |
| 1 | 1 | 2.90 | 1-10 | 1.5 | BzSc | 6.0 | 10.0 | P1 | 5.0 | — | — | 1.1 | 1.3 | 1.43 | 20 | Presence |
| 2 | 1 | 2.90 | 1-10 | 1.5 | BzSc | 6.0 | 10.0 | P1 | 5.0 | — | — | 1.1 | 1.3 | 1.43 | 8 | Presence |
| 3 | 1 | 2.90 | 1-10 | 1.5 | BzSc | 6.0 | 10.0 | P1 | 5.0 | — | — | 1.1 | 1.3 | 1.43 | 10 | Presence |
| 4 | 1 | 2.90 | 1-10 | 1.5 | BzSc | 6.0 | 10.0 | P1 | 5.0 | — | — | 1.1 | 1.3 | 1.43 | 15 | Presence |
| 5 | 1 | 2.90 | 1-10 | 1.5 | BzSc | 6.0 | 10.0 | P1 | 5.0 | — | — | 1.1 | 1.3 | 1.43 | 25 | Presence |
| 6 | 1 | 2.90 | 1-10 | 1.5 | BzSc | 6.0 | 10.0 | P1 | 5.0 | — | — | 1.1 | 1.3 | 1.43 | 30 | Presence |
| 7 | 1 | 2.90 | 1-10 | 1.5 | BzSc | 6.0 | 10.0 | P1 | 5.0 | — | — | 1.1 | 1.3 | 1.43 | 40 | Presence |
| 8 | 1 | 2.90 | 1-10 | 1.5 | BzSc | 6.0 | 10.0 | P1 | 5.0 | — | — | 1.1 | 1.3 | 1.43 | 55 | Presence |
| 9 | 1 | 2.90 | — | — | — | — | — | P1 | 5.0 | — | — | 1.1 | 1.3 | 1.43 | 20 | Presence |
| 10 | 1 | 2.90 | — | — | — | — | — | — | — | EPEG | 5.0 | 1.1 | 1.3 | 1.43 | 20 | Presence |
| 11 | 1 | 2.90 | — | — | — | — | — | — | — | TPP/ | 2.5/ | 1.1 | 1.3 | 1.43 | 20 | Presence |
| | | | | | | | | | | BDP | 2.5 | | | | | |
| 12 | 1 | 2.90 | 1-10 | 1.5 | — | — | — | — | — | — | — | 1.1 | 1.3 | 1.43 | 20 | Presence |
| 13 | 1 | 2.90 | 1-1 | 1.5 | — | — | — | — | — | — | — | 1.1 | 1.3 | 1.43 | 20 | Presence |
| 14 | 1 | 2.90 | — | — | iPrAcSc | 6.0 | — | — | — | — | — | 1.1 | 1.3 | 1.43 | 20 | Presence |
| 15 | 1 | 2.90 | — | — | iPrAcSc | 7.8 | — | — | — | — | — | 1.1 | 1.3 | 1.43 | 20 | Presence |
| 16 | 1 | 2.90 | 1-10 | 1.5 | — | — | — | P1 | 5.0 | — | — | 1.1 | 1.3 | 1.43 | 20 | Presence |
| 17 | 1 | 2.90 | 1-10 | 1.5 | — | — | — | P2 | 5.0 | — | — | 1.1 | 1.3 | 1.43 | 20 | Presence |
| 18 | 1 | 2.90 | 1-10 | 1.5 | — | — | — | P8 | 5.0 | — | — | 1.1 | 1.3 | 1.43 | 20 | Presence |
| 19 | 1 | 2.90 | — | — | BzSc | 4.5 | 10.0 | P1 | 5.0 | — | — | 1.1 | 1.3 | 1.43 | 20 | Presence |

*A: Cellulose acetate
*1: Average degree of acetyl group substitution
*2: Average degree of ester substitution of sugar ester
*3: Presence or absence of aging treatment in laminate roll condition

TABLE 2

| | Dope composition | | | | | | | | | | | | | | | |
|---|---|---|---|---|---|---|---|---|---|---|---|---|---|---|---|---|
| | | | Additive | | | | | | | | | | | | | |
| | | | Compound | | | | | | | | | | | | | |
| | | | represented by | | | | | | | | | | | | | |
| | | | Formula (1) | | Sugar ester | | | Polyester | | Other additive | | Stretching conditions | | | | |
| | | | Exam- | Added | | | Added | | Added | | Added | | | Stretch- | Layer | |
| Cellulose | | | ple | amount | | | amount | Exam- | amount | | amount | MD | TD | ing | thick- | |
| ester | *A | | com- | (mass | | | (mass | ple | (mass | | (mass | direction | direction | magni- | ness | |
| film No. | No. | *1 | pound | %) | Kind | *2 | %) | No. | %) | Kind | %) | (times) | (times) | fication | (μm) | *3 |
| 20 | 1 | 2.90 | — | — | BzSc | 5.0 | 10.0 | P1 | 5.0 | — | — | 1.1 | 1.3 | 1.43 | 20 | Presence |
| 21 | 1 | 2.90 | — | — | BzSc | 6.0 | 10.0 | P1 | 5.0 | — | — | 1.1 | 1.3 | 1.43 | 20 | Presence |
| 22 | 1 | 2.90 | — | — | BzSc | 7.5 | 10.0 | P1 | 5.0 | — | — | 1.1 | 1.3 | 1.43 | 20 | Presence |
| 23 | 1 | 2.90 | — | — | BzSc | 7.7 | 10.0 | P1 | 5.0 | — | — | 1.1 | 1.3 | 1.43 | 20 | Presence |
| 24 | 1 | 2.90 | — | — | AsSc | 7.8 | 10.0 | P1 | 5.0 | — | — | 1.1 | 1.3 | 1.43 | 20 | Presence |
| 25 | 1 | 2.90 | 1-10 | 1.5 | AsSc | 7.8 | 10.0 | P1 | 5.0 | — | — | 1.1 | 1.3 | 1.43 | 20 | Presence |
| 26 | 1 | 2.90 | 1-10 | 1.5 | BzSc | 6.0 | 10.0 | P2 | 5.0 | — | — | 1.1 | 1.3 | 1.43 | 20 | Presence |
| 27 | 1 | 2.90 | 1-1 | 1.5 | — | — | — | P1 | 5.0 | — | — | 1.1 | 1.3 | 1.43 | 20 | Presence |
| 28 | 1 | 2.90 | 1-1 | 1.5 | BzSc | 6.0 | 10.0 | P1 | 5.0 | — | — | 1.1 | 1.3 | 1.43 | 20 | Presence |
| 29 | 1 | 2.90 | 1-1 | 1.5 | BzSc | 6.0 | 10.0 | P2 | 5.0 | — | — | 1.1 | 1.3 | 1.43 | 20 | Presence |
| 30 | 1 | 2.90 | 1-10 | 1.5 | BzSc | 6.0 | 10.0 | P1 | 5.0 | — | — | 1.1 | 1.1 | 1.21 | 20 | Presence |
| 31 | 1 | 2.90 | 1-10 | 1.5 | BzSc | 6.0 | 10.0 | P1 | 5.0 | — | — | 1.1 | 1.2 | 1.32 | 20 | Presence |
| 32 | 1 | 2.90 | 1-10 | 1.5 | BzSc | 6.0 | 10.0 | P1 | 5.0 | — | — | 1.2 | 1.2 | 1.44 | 20 | Presence |
| 33 | 1 | 2.90 | 1-10 | 1.5 | BzSc | 6.0 | 10.0 | P1 | 5.0 | — | — | 1.2 | 1.3 | 1.56 | 20 | Presence |
| 34 | 1 | 2.90 | 1-10 | 1.5 | BzSc | 6.0 | 10.0 | P1 | 5.0 | — | — | 1.4 | 1.1 | 1.54 | 20 | Presence |
| 35 | 1 | 2.90 | 1-10 | 1.5 | BzSc | 6.0 | 10.0 | P1 | 5.0 | — | — | 1.2 | 1.4 | 1.68 | 20 | Presence |
| 36 | 1 | 2.90 | — | — | — | — | — | P1 | 5.0 | — | — | 1.2 | 1.5 | 1.80 | 20 | Presence |
| 37 | 1 | 2.90 | 1-10 | 1.5 | BzSc | 6.0 | 10.0 | P1 | 5.0 | — | — | 1.1 | 1.3 | 1.43 | 20 | Absence |
| 38 | 2 | 2.10 | 1-10 | 1.5 | BzSc | 6.0 | 10.0 | P1 | 5.0 | — | — | 1.1 | 1.3 | 1.43 | 20 | Presence |

*A: Cellulose acetate
*1: Average degree of acetyl group substitution
*2: Average degree of ester substitution of sugar ester
*3: Presence or absence of aging treatment in laminate roll condition

In addition, the details of the abbreviated additives described in Table 1 and Table 2 are shown below.

BzSc: Benzyl saccharose (Mixture of Compounds a-1 to a-4 described in Chem. 3, [0116]).

iPrAcSc: Isopropylacetyl saccharose (Mixture of Compounds g-1 to g-4 described in Chem. 4, [0117]).

EPEG: Glycolate compound (Ethyl phthalyl ethyl glycolate)

TPP: Tripheny phosphate

BDP: Biphenyl diphenyl phosphate

Cellulose acetate 2: Average degree of acetyl group substitution=2.45, weight average molecular weight (Mw)=151,000, number average molecular weight (Mn)=100,0000, Mw/Mn=1.5

### <<Evaluation of Properties of Cellulose Ester Film>>

An evaluation sample (10 cm length and 2.4 m width) was taken at the position of 1,000 m from the outer circumference of a 4,000 m cellulose ester film thus prepared. The following evaluations were carried out to each sample.

### [Measurement of Water Swelling Ratio and its Variation Coefficient]

A water swelling ratio was measured as describe in the following at 10 places randomly selected in the width direction (2.4 m) of each collected sample. The arithmetic average value was obtained.

(1) Test pieces each having a size of 5 cm×5 cm are sampled at 10 different places with a constant space in the width direction of a cellulose ester film having a width of 2.4 m.
(2) Each sampled test piece is left under the environment of 23° C. and 55% RH for 24 hours. Then, the thickness of each test piece is measured with a thickness measuring apparatus described below. The obtained thickness is called as “a thickness A”.
(3) Subsequently, each test piece is immersed in pure water of 23° C. and left in this condition for 1 hour.
(4) After 1 hour, the test piece is taken out from the pure water, and the water attached on the surface of the film piece is wiped off with Kimtowel™ (made by Nippon Paper Crecia, Co. Ltd.). Then, the film piece is left still under the environment of 23° C. and 55% RH for 5 minutes.
(5) After a lapse of 5 minutes from the moment of taking the test piece out of the water, it is started a thickness measurement in the same way. During 5 minutes, until 10 minutes after taking the film out of the water, thickness values of the test piece is measured. This value is called as “a thickness B”.
(6) By using the thickness A and the thickness B as described above, a water swelling ratio of each test piece is obtained with the following equation (1). At the end, an arithmetic average of swelling ratios at 10 different places is obtained. This value is made as a water swelling ratio of a cellulose ester film.

Water swelling ratio of test piece (%)=[(Thickness B−Thickness A)/Thickness A]×100 Equation (1):

Thickness measuring apparatuses are “DIGIMICRO MH-15M” and “COUNTER TC-101” (made by Nikon, Co. Ltd.). The measurement is done by setting the minimum reading value to be 0.01 μm.

Subsequently, a variation coefficient of water swelling ratios at 10 places in the width direction was obtained with the following equation (2)

Variation coefficient of water swelling ratios (%)=(Standard deviation of water swelling ratios/Average value of water swelling ratios)×100 Equation (2):

The measurement results thus obtained are listed in Table 3.

TABLE 3

| Cellulose ester | Water swelling properties | |
|---|---|---|
| film No. | Water swelling ratio (%) | Variation coefficient (%) |
| 1 | 0.4 | 0.5 |
| 2 | 0.5 | 0.4 |
| 3 | 0.3 | 0.2 |
| 4 | 0.4 | 0.5 |
| 5 | 0.3 | 0.3 |
| 6 | 0.4 | 0.3 |
| 7 | 0.4 | 0.4 |
| 8 | 0.6 | 0.7 |
| 9 | 1.3 | 0.6 |
| 10 | 2.0 | 0.8 |
| 11 | 1.4 | 0.8 |
| 12 | 1.0 | 0.6 |
| 13 | 0.9 | 0.7 |
| 14 | 1.0 | 0.6 |
| 15 | 0.9 | 0.8 |
| 16 | 0.8 | 0.5 |
| 17 | 0.8 | 0.5 |
| 18 | 0.8 | 0.5 |
| 19 | 0.7 | 0.6 |
| 20 | 0.4 | 0.5 |
| 21 | 0.3 | 0.4 |
| 22 | 0.6 | 0.6 |
| 23 | 0.7 | 0.6 |
| 24 | 1.0 | 0.6 |
| 25 | 0.8 | 0.4 |
| 26 | 0.2 | 0.2 |
| 27 | 0.9 | 0.8 |
| 28 | 0.7 | 0.6 |
| 29 | 0.5 | 0.6 |
| 30 | 1.6 | 0.9 |
| 31 | 1.0 | 0.6 |
| 32 | 0.5 | 0.4 |
| 33 | 0.7 | 0.4 |
| 34 | 0.6 | 0.5 |
| 35 | 0.9 | 0.5 |
| 36 | 2.2 | 0.7 |
| 37 | 1.0 | 0.9 |
| 38 | 1.3 | 0.8 |

<<Preparation of Cellulose Ester Film Provided with a Hard Coat Layer>>

There is provided a hard coat layer on each of the cellulose ester films 1 to 38 having been subjected to the aging treatment and used for a protective film. Thus, cellulose ester films provided with a hard coat layer were prepared.

A hard coat layer coating liquid containing the following composition was filtered with a polypropylene filter having a pore size of 0.4 μm. This hard coat layer coating liquid is applied with a micro gravure coater on each cellulose ester film. The coated layer was dried at 70° C. Then, while an oxygen concentration was controlled to be 1.0 volume % by nitrogen gas purge, the coated layer was irradiated by a UV lamp with an illuminance of 100 mW/cm² at an irradiated portion. An amount of irradiation was set to be 0.15 J/cm² to cure the coated layer. Thus it was formed a hard coat layer having a dry thickness of 9 μm.

### [Coating Composition of Hard Coat Layer]

### (Preparing Fluorine-Siloxane Graft Polymer 1)

Brand names of the materials used for preparing fluorine-siloxane graft polymer 1 are as follows:

Radical polymerizable fluororesin (A): CEFRAL COAT CF-803 (hydroxy group value: 60, number average molecular weight: 15,000, available from Central Glass Co., Ltd.)

Single end radical polymerizable polysiloxane (B): Silaplane FM-0721 (number average molecular weight: 5,000, available from Chisso Corporation)

Radical polymerization initiator: PERBUTYL O (t-butyl peroxy-2-ethylhexanoate, available from NOF CORPORATION)

Curing agent: SUMIDUR N3200 (biuret prepolymer of hexamethylene diisocyanate, available from Sumika Bayer Urethane Co., Ltd.)

### <Synthesis of Radical Polymerizable Fluororesin (A)>

A glass reactor equipped with a mechanical stirrer, a thermometer, a condenser, and a dry nitrogen gas inlet was charged with CEFRAL COAT CF-803 (1,554 mass parts), xylene (233 mass parts), and 2-isocyanatoethyl methacrylate (6.3 mass parts) and heated to 80° C. in a dry nitrogen atmosphere. The mixture was reacted at 80° C. for 2 hours. After no absorption band assigned to isocyanate was observed in an infrared absorption spectrum of a reaction product sample, it was taken out the reacted mixture. Thus, it was obtained 50 mass % radical polymerizable fluororesin (A) through urethane bonds.

### <Preparation of Graft Polymer>

A glass reactor equipped with a mechanical stirrer, a thermometer, a condenser, and a dry nitrogen gas inlet was charged with the radical polymerizable fluororesin (A) synthesized above (26.1 mass parts), xylene (19.5 mass parts), n-butyl acetate (16.3 mass parts), methyl methacrylate (2.4 mass parts), n-butyl methacrylate (1.8 mass parts), lauryl methacrylate (1.8 mass parts), 2-hydroxyethyl methacrylate (1.8 mass parts), FM-0721 (5.2 mass parts), and PERBUTYL O (0.1 mass parts) and heated to 90° C. in a nitrogen atmosphere. The mixture was then kept at 90° C. for 2 hours. After further added PERBUTYL O (0.1 mass parts), the mixture was kept at 90° C. for 5 hours to obtains a solution of 35 mass % fluorine-siloxane graft polymer 1 having a weight average molecular weight of 171,000.

### (Preparation of Hard Coat Layer Coating Liquid 1)

The following materials were added and mixed with stirring to prepare a hard coat layer coating liquid 1.

| | | |
|---|---|---|
| Pentaerythritol triacrylate | 20.0 | mass parts |
| Pentaerythritol tetraacrylate | 50.0 | mass parts |
| Dipentaerythritol hexaacrylate | 30.0 | mass parts |
| Dipentaerythritol pentaacrylate | 30.0 | mass parts |
| IRGACURE 184 (made by BASF Corp.) | 5.0 | mass parts |
| IRGACURE 907 (made by BASF Corp.) | 10.0 | mass parts |
| Fluorine-siloxane graft polymer I (35 mass %) | 5.0 | mass parts |
| Pentaerythritol tetrakis(3-mercaptobutylate) | 2.5 | mass parts |
| Propylene glycol monomethyl ether | 10 | mass parts |
| Methyl acetate | 20 | mass parts |
| Acetone | 20 | mass parts |
| Methyl ethyl ketone | 60 | mass parts |
| Cyclohexanone | 20 | mass parts |

<<Preparation of Cellulose Ester Film 1 Treated with Anti-Reflection Treatment 1: AL Processing Treatment>>

The above-described Cellulose ester film 1 on which a hard coat layer was formed was used as a sample. An atmospheric pressure plasma treatment was conducted to the surface of the hard coat layer of the sample. The atmospheric pressure plasma treatment was done by using an atmospheric pressure plasma apparatus described in JP-A 2006-299373, with conditions of: a distance of electrode of 0.5 mm; supplying a discharge gas containing 80.0 volume % of nitrogen gas and 20.0 volume % of oxygen gas in the discharge space; and discharging at 100 kHz.

Subsequently, a high refractive index layer and a low refractive index layer were laminated as described below to obtain a cellulose ester film 1A which is an AL processing film. This cellulose ester film 1A treated with AL processing was used in a polarizing plate 44 which will be described later.

### (Formation of High Refractive Index Layer)

In order to provide a high refractive index layer on a hard coat layer of the cellulose ester film 1, a fine particle dispersion liquid A was prepared, and then, a coating liquid for a high refractive index layer was prepared.

A coating liquid for a high refractive index layer described below was die-coated on a hard coat layer treated with atmospheric pressure plasma. The coated layer was dried at 70° C. Then, while an oxygen concentration was controlled to be 1.0 volume % by nitrogen gas purge, the coated layer was irradiated with UV rays of 0.2 J/cm² by a high pressure mercury lamp to obtain a high refractive index layer having a thickness of 120 nm after cured. The refractive index of the produced high refractive index layer was 1.60.

### <Preparation of Fine Particle Dispersion Liquid A>

To 6.0 kg of antimony complex oxide colloid dispersion in methanol (zinc antimonite sol, solid content 60%, product name: CELNAX CX-Z610M-F2, made by Nissan Chemical Industries Ltd.) was gradually added 12.0 kg of isopropyl alcohol with stirring to prepare a fine particle dispersion liquid A.

### <High Refractive Index Layer Coating Liquid>

| | |
|---|---|
| PGME (propylene glycol monomethyl ether) | 40 mass parts |
| Isopropyl alcohol | 25 mass parts |
| Methyl ethyl ketone | 25 mass parts |
| Pentaerythritol triacrylate | 0.9 mass parts |
| Pentaerythritol tetraacrylate | 1.0 mass parts |
| Urethane acrylate (product name: U-4HA, made by Shin | 0.6 mass parts |
| Nakamura Chemical Co. Ltd.) | |
| Fine particle dispersion liquid A | 20 mass parts |
| Irgacure 184 (made by BASF Japan Ltd.) | 0.4 mass parts |
| Irgacure 907 (made by BASF Japan Ltd.) | 0.2 mass parts |
| FZ-2207 (10% propylene glycol monomethyl ether | 0.4 mass parts |
| solution, made by NUC Corporation) | |

### (Formation of Low Refractive Index Layer)

In order to form a low refractive index layer on the produced high refractive index layer as describe above, there were prepared an isopropyl alcohol dispersion of a porous silica fine particle 1, and a tetraethoxysilane hydrolysis product A. Thus a low refractive index layer coating liquid 1 was prepared.

### <Preparation of Isopropyl Alcohol Dispersion Liquid of Porous Silica Particle 1>

Step (a):

A mixture of 100 g of silica sol (average particle size of 5 nm, concentration of SiO₂ of 20 mass %) and 1,900 g of pure water was heated to 80° C. The pH of this reaction mother liquid was 10.5. To this mother liquid were added at the same time, 9,000 g of 0.98 mass % of sodium silicate for SiO₂ and 9,000 g of 1.02 mass % of sodium aluminate for Al₂O₃. During the addition, the temperature of the reaction liquid was kept to be 80° C. The pH of the reaction liquid increased to 12.5 immediately after the addition, and it was almost not changed thereafter. After termination of the addition, the reaction liquid was cooled to room temperature, and it was washed using an ultrafiltration membrane to obtain a SiO₂—Al₂O₃-core particle dispersion liquid having a solid content of 20 mass %.

Step (b):

To 500 g of this core particle dispersion liquid was added 1,700 g of pure water. The mixture was heated to 98° C. With keeping this temperature, 3,000 g of silicic acid liquid (SiO₂-concentration: 3.5 mass %, produced by dealkalization of an aqueous sodium silicate with cationic ion exchange resin) was added to the mixture to obtain a core particle dispersion liquid formed with a first silica covering layer.

Step (c):

Subsequently, 1,125 g of pure water was added to 500 g of the core particle dispersion liquid formed with a first silica covering layer, which was washed using an ultrafiltration membrane to have a solid content of 13 mass %. Further, concentrated hydrochloric acid (35.5%) was dropped to adjust the pH of 1.0. Thus dealuminization treatment was carried out. Subsequently, while adding 10 L of an aqueous hydrochloric acid (pH 3) and 5 L of pure water, a dissolved aluminum salt was separated using an ultrafiltration membrane to prepare a dispersion liquid of SiO₂—Al₂O₃ porous particles in which the constituting component of the core particles formed with a first silica covering layer was partially removed.

Step (d):

A mixes liquid of 1,500 g of the above-described porous particle dispersion liquid, 500 g of pure water, 1,750 g of ethanol, and 626 g of a 28% aqueous ammonia solution was heated to 35° C. Then, 104 g of ethyl silicate (SiO₂: 28 mass %) was added to cover the surface of the porous particles formed with a first silica covering layer with a hydrolysis polycondensation product of ethyl silicate to form a second silica covering layer. Subsequently, the solvent was substituted with isopropyl alcohol using an ultrafiltration membrane. Thus, it was produced a dispersion liquid of porous silica particles 1 with a solid content of 20 mass %.

### <Preparation of Tetraethoxysilane Hydrolysis Product A>

230 g of tetraethoxysilane (product name: KBE04, made by Shin-Etsu Chemical Co. Ltd.) and 440 g of ethanol were mixed. To this was added 120 g of 2% aqueous acetic acid solution and the mixture was stirred at room temperature (25° C.) for 28 hours. Thus, it was prepared a tetraethoxysilane hydrolysis product A.

### <Preparation of Low Refractive Index Layer Coating Liquid 1>

| | |
|---|---|
| Propylene glycol monomethyl ether | 430 mass parts |
| Isopropyl alcohol | 430 mass parts |
| Tetraethoxysilane hydrolysis product A (solid | 120 mass parts |
| content: 21% conversion value) | |
| γ-Methacryloxy propyl trimethoxylsilane (product | 3.0 mass parts |
| name: KBM503, made by Shin-Etsu Chemical Co. Ltd.) | |
| Isopropyl alcohol dispersion liquid of porous silica | 60 mass parts |
| particles 1 (average particle size of 45, particle size | |
| variation coefficient of 30%) | |
| Aluminum ethyl acetoacetate diisopropylate (made by | 3.0 mass parts |
| Kawaken Fine Chemicals Co. Ltd.) | |
| FZ-2207 (10% propylene glycol monomethyl ether | 3.0 mass parts |
| solution, made by NUC Corporation) | |

The prepared low refractive index layer coating liquid 1 as described above was die coated on the high refractive index layer. The coated layer was dried at 80° C. Then, while an oxygen concentration was controlled to be 1.0 volume % by nitrogen gas purge, the coated layer was irradiated with UV rays of 0.15 J/cm² by a high pressure mercury lamp to obtain a low refractive index layer having a thickness of 86 nm. The refractive index of the produced low refractive index layer was 1.38.

<<Preparation of Cellulose Ester Film Treated with Anti-Reflection Treatment 2: LR Processing Treatment>>

A cellulose ester film 1B treated with anti-reflection treatment 2 (LR processing) was prepared in the same manner as preparation of a cellulose ester film treated with anti-reflection treatment 1 (AL processing) except that only the above-described low refractive index layer was provided on the hard coat layer. This cellulose ester film 1B treated with LR processing was used in a polarizing plate 43 which will be described later.

### <<Preparation of Polarizer>>

A 75 μm-thick polyvinyl alcohol film (average polymerization degree of 2,400, and saponification degree of 99.9 mole %) was immersed in water of 30° C. for 60 seconds to swell. Subsequently, the swelled polyvinyl alcohol film was immersed in a 0.3% aqueous solution of iodine/potassium iodide (mass ratio=0.5/8), and it was dyed while stretching the film to a stretching ratio of 3.5 times. Afterward, the dyed polyvinyl alcohol film was stretched in an aqueous boric acid ester solution to have a stretching ratio of 37.5 times. Then, the obtained polyvinyl alcohol film was dried in the oven at 40° C. for 3 minutes to prepare a polarizer having a thickness of 2 μm. Subsequently, each polarizer having a thickness of 5 μm, 10 μm, 15 μm, or 20 μm was prepared in the same manner as described above except that the stretching ratio was suitably changed.

### <<Preparation of UV Curable Adhesive Liquid>>

The following components were mixed and defoamed to prepare a UV curable adhesive liquid 1. Here, triarylsulfonium hexafluorophosphate was added in the form of a 50% propylene carbonate solution, and an amount of the solid content of triarylsulfonium hexafluorophosphate was indicated in the following.

| | |
|---|---|
| 3,4-Epoxycyclohexylmethyl-3,4-epoxycyclohexane | 45 mass parts |
| carboxylate | |
| Epolead GT-301 (alicyclic epoxy resin,made by Daicel | 40 mass parts |
| Co. Ltd.) | |
| 1,4-Butanediol diglycidyl ether | 15 mass parts |
| Triarylsulfonium hexafluorophosphate | 2.3 mass parts |
| 9,10-Dibutoxyanthracene | 0.1 mass parts |
| 1,4-Diethoxynaphthalene | 2.0 mass parts |

### <<Preparation of Retardation Film>>

### (Preparation of Retardation Film 1)

A film composed of 50 μm-thick polycarbonate was prepared using a polycarbonate resin (product name: AD-5503, Tg=145° C., viscosity-average molecular weight M=15,200) in accordance with the method described in Example 1 of WO 2010/053212. Subsequently, the film was obliquely stretched to 2.0 times at 150° C. with an oblique stretching apparatus described in FIG. 3 of the present specification. Thus, it was prepared a retardation film 1 having a thickness of 25 μm.

### (Preparation of Retardation Film 2)

A film was prepared using a blend of a polyester resin and a polycarbonate resin in accordance with the method described in Example 1 of JP-A 2007-108280. Subsequently, the film was obliquely stretched to 2.0 times at 150° C. with an oblique stretching apparatus described in FIG. 3 of the present specification. Thus, it was prepared a retardation film 2 having a thickness of 25 μm composed of polyester and polycarbonate.

### (Preparation of Retardation Film 3)

A laminated film was prepared using a norbornene resin (ZEONOR 1420 made by Zeon Co., Tg=136° C.) and a styrene resin (styrene-maleic anhydride copolymer resin, DYLARK D332, made by NOVA Chemicals Co., Tg=131° C.) in accordance with the method described in Preparation example 1 of JP-A 2004-233666. Subsequently, the film was obliquely stretched to 1.7 times at 150° C. with an oblique stretching apparatus described in FIG. 3 of the present specification. Thus, it was prepared a retardation film 3 having a thickness of 25 μm of co-cast with cycloolefin polymer/styrene polymer.

### (Preparation of Retardation Film 4)

A film was prepared using a norbornene resin (ZEONOR 1420 made by Zeon Co., Tg=136° C.) in accordance with the method described in Preparation example 2 (3) of JP-A 2004-233666. The film was stretched to 1.4 times with having an angle between the width direction of the film and the orientation angle being 30°. Thus, it was prepared a retardation film 4 having a thickness of 25 μm. The retardation of this obliquely stretched retardation film 4 was 137.5 nm measured at the wavelength of 550 nm, and an angle between the retardation axis and the width direction of the film was 30°.

### <<Preparation of Polarizing Plate>>

### [Preparation of Polarizing Plate 1]

A polarizing plate F having a constitution described in FIG. 1 was prepared in accordance with the method described below. The figures in parentheses indicate the number of the constitution element described in FIG. 1.

The above-described retardation film 1 (polycarbonate film) was used as a retardation film (14). On the surface thereof was subjected to a corona discharge treatment. Here, the conditions of the corona discharge treatment were set as follows: corona output intensity of 2.0 kW; and line speed of 18 m/min. Subsequently, the above prepared UV curable adhesive liquid 1 was coated on the corona discharge treated surface of the retardation film (105) with a bar coater to form a UV curable adhesive layer (15A) to have a cured thickness of 3 μm. The above prepared polyvinyl alcohol-iodine polarizer (16, thickness of 2 μm) was pasted to the obtained UV curable adhesive layer (15A).

Subsequently, a cellulose ester film 1 (detailed constitution is described in Table 1) having the above prepared hard coat layer (18) thereon was used as a cellulose ester film (17). A corona discharge treatment was done on a surface of the cellulose ester film on which was not formed a hard coat layer. The conditions of the corona discharge treatment were set as follows: corona output intensity of 2.0 kW; and line speed of 18 m/min.

Then, the above prepared UV curable adhesive liquid 1 was coated on the corona discharge treated surface of the cellulose ester film 1 (17) with a bar coater to form a UV curable adhesive layer (15B) to have a cured thickness of 3 μm.

To this UV curable adhesive layer (15B) was pasted a polarizer (16) which had been adhered to one surface of the retardation film (14). Thus it was obtained a laminate body (a polarizing plate F) laminated with: retardation film (14)/UV curable adhesive layer (15A)/polarizer (16)/UV curable adhesive layer (15B)/cellulose ester film (17)/hard coat layer (18). When the retardation film (14) and the polarizer (16) were pasted, the retardation axis of the retardation film (14) and the absorbing axis of the polarizer (16) were made to be orthogonal.

UV rays were irradiated from both sides of this laminate body using a UV irradiation apparatus equipped with a belt conveyor (using a D valve made by Fusion UV Systems Co.). The accumulated amount of light was made to be 750 mJ/cm², and the UV curable adhesive layer (15A) and UV curable adhesive layer (15B) were cured to obtain a polarizing plate 1 (F) having a total thickness of 62 μm.

### [Preparation of Polarizing Plates 2 to 5]

Polarizing plates 2 to 5 were prepared in the same manner as preparation of Polarizing plate 1 except that the thickness of the polarizer was changed to the condition as described in Table 4.

### [Preparation of Polarizing Plates 6 to 42]

Polarizing plates 6 to 42 were prepared in the same manner as preparation of Polarizing plate 2 except that a protective film provided with a hard coat layer was changed to a protective film provided with a hard coat layer as described in Table 4 and Table 5.

### [Preparation of Polarizing Plates 43 and 44]

Polarizing plates 43 to 44, each using a protective film subjected to a surface treatment, were respectively prepared in the same manner as preparation of Polarizing plate 2 except that a protective film 1 provided with a hard coat layer was replaced with a cellulose ester film 1B treated with anti-reflection treatment 2 (LR processing) and a cellulose ester film 1A treated with anti-reflection treatment 1 (AL processing).

### [Preparation of Polarizing Plates 45 to 47]

Polarizing plates 45 to 47 were prepared in the same manner as preparation of Polarizing plate 2 except that a retardation film 1 is respectively replaced with retardation films 2 to 4.

### [Preparation of Polarizing Plate in a Different Preparation Condition]

The following two kinds of polarizing plates 1 to 47 were prepared. One kind is “A” series polarizing plates (1A to 47A) which were prepared under a low humidity condition of 23° C. and 20% RH in all of the preparation steps. The other kind is “B” series polarizing plates (1B to 47B) which were prepared under a high humidity condition of 23° C. and 80% RH in all of the preparation steps.

### <<Evaluation of Polarizing Plate>>

The above prepared polarizing plates 1A to 47A (“A” series: prepared under a low humidity condition) and polarizing plates 1B to 47B (“B” series: prepared under a high humidity condition) were evaluated for flatness property (curling resistance) as described below.

### [Evaluation of Flatness]

The above prepared polarizing plates each were cut to a piece of 10 cm×10 cm. The sample was left still on a non-water absorptive horizontal board at 23° C. and 55% RH. Uplift at four corners caused by curling of the sample was visually observed and flatness was evaluated in accordance with the following criteria. When the curling property was positive curl, the sample was left as it was. When the curling property was negative curl, the placement face of the sample was inversed. The evaluation was always made to the sample in the concave condition.

\textcircled{o}: Uplift at four corners caused by curling is not observed.

◯): Slight uplift at one corner is observed, however, flatness is substantially kept.

Δ: Slight uplift at four corners is observed with acceptance level for practical use.

X: Severe uplift at four corners is observed, which is problem for practical use.

### [Evaluation of Thin Film Aptitude]

The total thickness of each of the prepared polarizing plates was measured. An evaluation of thin film aptitude was done in accordance with the following criteria. When the rank is Δ or ◯, the sample was judged to be provided with an aptitude for using as a polarizing plate with respect to the requirement of making a thinner organic electroluminescent display device.

◯: The total thickness of polarizing plate is less than 75 μm.

Δ: The total thickness of polarizing plate is 75 μm or more, and less than 90 μm.

X: The total thickness of polarizing plate is 86 μm or more.

The evaluation results obtained are shown in Table 4 and Table 5 described below.

### <<Production of Organic Electroluminescent Display Device>>

### [Production of Organic EL Display Devices 1A and 1B]

### (Production of Organic EL Element)

Subsequently, each organic EL element was produced according to the following procedures.

An organic EL element was prepared as follows: a TFT was formed on a glass substrate; on the glass substrate, a reflection electrode formed of chrome and having a thickness of 80 nm was formed by sputtering; on the reflection electrode, an anode was formed using ITO by sputtering to obtain a thickness of 40 nm; on the anode, a hole transport layer having a thickness of 80 nm was formed using poly(3,4-ethylenedioxythiophene)-polystyrene sulfonate (PEDOT:PSS) by sputtering; on the hole transport layer, light emitting layers each having a thickness of 100 nm and for colors of R, G or B were formed using a shadow mask. The red light emitting layer having a thickness of 100 nm was formed by co-deposition of tris(8-hydroxy quinolinato)aluminum (Alq₃) as a host and a light emitting material[4-(dicyanomethylene)-2-methyl-6(p-dimethylaminostyryl)-4H-pyran] (DCM) (at a ratio of 99:1 by mass). The green light emitting layer having a thickness of 100 nm was formed by co-deposition of Alq₃ as a host and a light emitting compound Coumarin 6 (at a ratio of 99:1 by mass). The blue light emitting layer having a thickness of 100 nm was formed by co-deposition of BAlq as a host and a light emitting compound Perylene (at a ratio of 90:10 by mass).

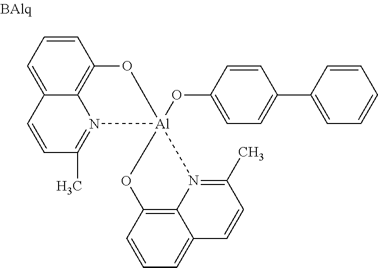

On the light emitting layer, a first cathode having a thickness of 4 nm and low work function that enables effective injection of electrons (also referred to as a buffer layer) was formed using calcium by vacuum deposition; on the first cathode, a second cathode having a thickness of 2 nm was formed using aluminum. Aluminum used in the second cathode can prevent calcium in the first cathode from being chemically changed when a transparent electrode is formed on the second cathode by sputtering. An organic light emitting layer unit was thus obtained.

Thereafter, a transparent electroconductive film having a thickness of 80 nm was formed on the cathode by sputtering. Here, ITO was used for forming the transparent electroconductive film. On the transparent electroconductive film, an insulation film having a thickness of 200 nm was formed using silicon dioxide by a CVD method. Further, a sealing glass (thickness of 1 mm) was bonded over the insulation film using an adhesive sheet, thus an organic EL element was obtained. An average refractive index of the sealing glass was 1.51.

On the retardation film surface side of the above prepared polarizing plate 1A was transferred an adhesive layer A (13 in FIG. 1) using an adhesive sheet A as described below. The surface side of the prepared organic EL element was pasted on the aforesaid adhesive layer A to prepare an organic EL display device 1A. In the same way, an organic EL display device 1B was prepared using a polarizing plate 1B.

### (Preparation of Adhesive Sheet A)

### <1 Preparation of Adhesive Coating Liquid A>

In a reaction container fitted with a condenser tube, a nitrogen gas inlet, a thermometer, a dropping funnel and a mechanical stirrer were added 49 parts of 2-ethylexhyl acrylate (“parts” indicates “mass parts”, hereinafter, it means the same), 50 parts of phenoxyethyl acrylate, 1 part of acrylic acid and 0.2 parts of AIBN with a solvent. A nitrogen gas reflux was done at room temperature for 1 hour. Then, under the nitrogen gas condition, the temperature of the mixture was raised to 60° C. to react for 4 hours. Subsequently, the mixture was raised to 80° C. to ripen for 2 hours, and thus, an acrylic copolymer solution was obtained.

Subsequently, to the aforesaid adhesive composed of acrylic copolymer solution was added 1 part (solid) of trimethylol propane/trilene-diisocyanate (Colonate L, made by Nippon Polyurethane Co.) as a cross-linking agent to prepare an adhesive coating liquid A.

### (Coating and Pasting of Peeling Off Sheet)

The above-described adhesive coating liquid 2 was coated on a silicone treated polyethylene terephthalate film having a thickness of 38 μm (peeling off sheet) with an applicator. It was dried at 130° C. for 3 minutes to form an adhesive layer A having a thickness of 25 μm. On the produced adhesive layer A was pasted a silicone treated polyethylene terephthalate film having a thickness of 38 μm (peeling off sheet) to obtain an adhesive sheet A. An average refractive index of the adhesive layer A of the adhesive sheet A was 1.48.

### [Production of Organic EL Display Devices 2A to 47A and 2B to 47B]

Organic EL display devices 2A to 47A were prepared in the same manner as preparation of the aforesaid Organic EL display device 1A except that the polarizing plates 2A to 47A were used in place of the polarizing plates 1A. In the similar way, organic EL display devices 2B to 47B were prepared in the same manner as preparation of the aforesaid Organic EL display device 1B except that the polarizing plates 2B to 47B were used in place of the polarizing plates 1B.

### <<Evaluation of Organic EL Display Device>>

Resistance to display unevenness for the above prepared organic EL display devices was evaluated in accordance with the following method.

### [Evaluation of Resistance to Display Unevenness]

The above prepared organic EL display devices each were emitted white light from the whole surface with a driving voltage of 10 V. The generation of unevenness was visually observed and resistance to display unevenness was evaluated in accordance with the following criteria.

\textcircled{o}: Display unevenness is not observed at all when the screen is observed from the front, or from an angle of 45° with respect to a normal line.

◯: Display unevenness is almost not observed when the screen is observed from the front, or from an angle of 45° with respect to a normal line.

Δ: Display unevenness is not observed when the screen is observed from the front, however, a slight display unevenness is observed when the screen is observed from an angle of 45° with respect to a normal line.

X: Distinct display unevenness is observed when the screen is observed from any directions.

The evaluation results obtained are shown in Table 4 and Table 5.

TABLE 4

| | | | | | | | | | | Evaluation of | | |
|---|---|---|---|---|---|---|---|---|---|---|---|---|
| | | | | | | | | | | Organic EL | | |
| Organic | | | | | | | Evaluation of | | | display device | | |
| EL | | | Thickness | | | Surface | Polarization | | | Resistance to | | |
| display | | | of | Cellulose | Hard | treatment | plate | | | display | | |
| device | Polarizing | Retardation | Polarizer | ester | coat | functional | Flatness | | Thin film | unevenness | | |
| No. | plate No. | film No. | (μm) | film No. | layer | layer | *4 | *5 | aptitude | *4 | *5 | Remarks |
| 1 | 1 | Retardation 1 | 2 | 1 | Presence | — | ⊚ | ◯ | ◯ | ◯ | Δ | Present Invention |
| 2 | 2 | Retardation 1 | 5 | 1 | Presence | — | ⊚ | ⊚ | ◯ | ◯ | ◯ | Present Invention |
| 3 | 3 | Retardation 1 | 10 | 1 | Presence | — | ⊚ | ⊚ | ◯ | ⊚ | ⊚ | Present Invention |
| 4 | 4 | Retardation 1 | 15 | 1 | Presence | — | ◯ | ◯ | Δ | ◯ | ◯ | Present Invention |
| 5 | 5 | Retardation 1 | 20 | 1 | Presence | — | Δ | Δ | Δ | ◯ | ◯ | Present Invention |
| 6 | 6 | Retardation 1 | 5 | 2 | Presence | — | X | X | ◯ | X | X | Comparative Invention |
| 7 | 7 | Retardation 1 | 5 | 3 | Presence | — | ◯ | ⊚ | ◯ | ◯ | ◯ | Present Invention |
| 8 | 8 | Retardation 1 | 5 | 4 | Presence | — | ⊚ | ⊚ | ◯ | ⊚ | ⊚ | Present Invention |
| 9 | 9 | Retardation 1 | 5 | 5 | Presence | — | ⊚ | ⊚ | ◯ | ⊚ | ⊚ | Present Invention |
| 10 | 10 | Retardation 1 | 5 | 6 | Presence | — | ⊚ | ⊚ | Δ | ◯ | ◯ | Present Invention |
| 11 | 11 | Retardation 1 | 5 | 7 | Presence | — | ⊚ | ◯ | Δ | ◯ | ◯ | Present Invention |
| 12 | 12 | Retardation 1 | 5 | 8 | Presence | — | Δ | X | X | Δ | X | Comparative Invention |
| 13 | 13 | Retardation 1 | 5 | 9 | Presence | — | Δ | X | Δ | Δ | X | Comparative Invention |
| 14 | 14 | Retardation 1 | 5 | 10 | Presence | — | X | X | ◯ | X | X | Comparative Invention |
| 15 | 15 | Retardation 1 | 5 | 11 | Presence | — | Δ | X | ◯ | Δ | X | Comparative Invention |
| 16 | 16 | Retardation 1 | 5 | 12 | Presence | — | Δ | Δ | ◯ | ◯ | ◯ | Present Invention |
| 17 | 17 | Retardation 1 | 5 | 13 | Presence | — | Δ | Δ | ◯ | ◯ | ◯ | Present Invention |
| 18 | 18 | Retardation 1 | 5 | 14 | Presence | — | Δ | Δ | ◯ | ◯ | ◯ | Present Invention |
| 19 | 19 | Retardation 1 | 5 | 15 | Presence | — | Δ | Δ | ◯ | Δ | Δ | Present Invention |
| 20 | 20 | Retardation 1 | 5 | 16 | Presence | — | ◯ | Δ | ◯ | ⊚ | ◯ | Present Invention |
| 21 | 21 | Retardation 1 | 5 | 17 | Presence | — | ◯ | Δ | ◯ | ⊚ | ◯ | Present Invention |
| 22 | 22 | Retardation 1 | 5 | 18 | Presence | — | ◯ | Δ | ◯ | ⊚ | ◯ | Present Invention |
| 23 | 23 | Retardation 1 | 5 | 19 | Presence | — | Δ | Δ | ◯ | ◯ | Δ | Present Invention |
| 24 | 24 | Retardation 1 | 5 | 20 | Presence | — | ◯ | Δ | ◯ | ⊚ | ◯ | Present Invention |

*4: Flatness (curling property) when the polarization plate is prepared under a low humidity environment. A series
*5: Flatness (curling property) when the polarization plate is prepared under a hign humidity environment. B series

TABLE 5

| | | | | | | | | | | Evaluation of | | |
|---|---|---|---|---|---|---|---|---|---|---|---|---|
| | | | | | | | | | | Organic EL | | |
| Organic | | | | | | | Evaluation of | | | display device | | |
| EL | | | Thickness | | | Surface | Polarization | | | Resistance to | | |
| display | | | of | Cellulose | Hard | treatment | plate | | | display | | |
| device | Polarizing | Retardation | Polarizer | ester | coat | functional | Flatness | | Thin film | unevenness | | |
| No. | plate No. | film No. | (μm) | film No. | layer | layer | *4 | *5 | aptitude | *4 | *5 | Remarks |
| 25 | 25 | Retardation 1 | 5 | 21 | Presence | — | ◯ | ◯ | ◯ | ⊚ | ◯ | Present Invention |
| 26 | 26 | Retardation 1 | 5 | 22 | Presence | — | ◯ | Δ | ◯ | ◯ | ◯ | Present Invention |
| 27 | 27 | Retardation 1 | 5 | 23 | Presence | — | Δ | Δ | ◯ | ◯ | ◯ | Present Invention |
| 28 | 28 | Retardation 1 | 5 | 24 | Presence | — | Δ | ◯ | ◯ | ◯ | ⊚ | Present Invention |
| 29 | 29 | Retardation 1 | 5 | 25 | Presence | — | ◯ | ⊚ | ◯ | ⊚ | ⊚ | Present Invention |
| 30 | 30 | Retardation 1 | 5 | 26 | Presence | — | ⊚ | ⊚ | ◯ | ⊚ | ⊚ | Present Invention |
| 31 | 31 | Retardation 1 | 5 | 27 | Presence | — | Δ | Δ | ◯ | ◯ | Δ | Present Invention |
| 32 | 32 | Retardation 1 | 5 | 28 | Presence | — | ◯ | ◯ | ◯ | ◯ | ◯ | Present Invention |
| 33 | 33 | Retardation 1 | 5 | 29 | Presence | — | ◯ | ◯ | ◯ | ◯ | ◯ | Present Invention |
| 34 | 34 | Retardation 1 | 5 | 30 | Presence | — | Δ | X | ◯ | Δ | X | Comparative Invention |
| 35 | 35 | Retardation 1 | 5 | 31 | Presence | — | ◯ | Δ | ◯ | ◯ | ◯ | Present Invention |
| 36 | 36 | Retardation 1 | 5 | 32 | Presence | — | ⊚ | ⊚ | ◯ | ⊚ | ⊚ | Present Invention |
| 37 | 37 | Retardation 1 | 5 | 33 | Presence | — | ◯ | ⊚ | ◯ | ⊚ | ⊚ | Present Invention |
| 38 | 38 | Retardation 1 | 5 | 34 | Presence | — | ◯ | Δ | ◯ | ◯ | ◯ | Present Invention |
| 39 | 39 | Retardation 1 | 5 | 35 | Presence | — | Δ | Δ | ◯ | ◯ | Δ | Present Invention |
| 40 | 40 | Retardation 1 | 5 | 36 | Presence | — | Δ | X | ◯ | Δ | X | Comparative Invention |
| 41 | 41 | Retardation 1 | 5 | 37 | Presence | — | ◯ | Δ | ◯ | ◯ | ◯ | Present Invention |
| 42 | 42 | Retardation 1 | 5 | 38 | Presence | — | Δ | X | ◯ | Δ | X | Comparative Invention |
| 43 | 43 | Retardation 1 | 5 | 1B | Presence | LR | ⊚ | ⊚ | ◯ | ⊚ | ⊚ | Present Invention |
| 44 | 44 | Retardation 1 | 5 | 1A | Presence | AL | ⊚ | ⊚ | ◯ | ⊚ | ⊚ | Present Invention |
| 45 | 45 | Retardation 2 | 5 | 1 | Presence | — | ⊚ | ⊚ | ◯ | ⊚ | ⊚ | Present Invention |
| 46 | 46 | Retardation 3 | 5 | 1 | Presence | — | ⊚ | ◯ | ◯ | ⊚ | ◯ | Present Invention |
| 47 | 47 | Retardation 4 | 5 | 1 | Presence | — | ⊚ | ◯ | ◯ | ⊚ | ◯ | Present Invention |

*4: Flatness (curling property) when the polarization plate is prepared under a low humidity environment. A series
*5: Flatness (curling property) when the polarization plate is prepared under a hign humidity environment. B series

As is clearly shown by the results described in Table 4 and Table 5, the polarizing plate having a constitution defined by the present invention is excellent in flatness, even when it is prepared under a low humidity environment or a high humidity environment because a water swelling ratio of the protective film is controlled to have a specific condition and generation of curling is controlled. By using an organic electroluminescent display device provided with such polarizing plate, it can obtain an organic electroluminescent display device excellent in resistance to display unevenness.

### INDUSTRIAL APPLICABILITY

An organic electroluminescent display device of the present invention is provided with a thin film polarizing plate excellent in curling resistance and flatness when it is produced under a low humid condition or a high humid condition. It has a high resistance to display unevenness and it is suitably used for a variety of light sources for flat-panel illumination devices, light sources for optical fibers, backlights for liquid crystal displays, backlights for liquid crystal projectors, and various light sources for other display devices.

### DESCRIPTION OF SYMBOLS

1: Substrate
2: TFT
3: Metal electrode
4: ITO
5: Hole transport layer
6: Light emitting layer
7: Buffer layer
8: Cathode
9: ITO
10: Insulating layer
11: Adhesive layer C
12: Sealing glass
13: Adhesive layer
14: Retardation film
15A and 15B: UV curable adhesive layer
16: Polarizer
17: Protective film
18: Hard coat layer
D: Organic electroluminescent display device
E: Organic EL element unit
F: Polarizing plate
100: non-stretched film
102-1: Right side film catching position
102-2: Left side film catching position
103-1: Path of the right side film holder
103-2: Path of the left side film holder
104: Tenter
105-1: Right side film releasing position
105-2: Left side film releasing position
106: Obliquely stretched film
107-1: Film conveying direction
107-2: Film winding direction
108-1: Guide roller at the entrance of tenter
108-2: Guide roller at the exit of tenter
109: Film stretching direction
DR1: Film feeding direction
DR2: Film winding direction
θi: Feeding angle (angle formed between Film feeding direction and Film winding direction)
CR and CL: Holder
Wo: Film width before stretching
W: Film width after stretching
110: Film feeding apparatus
111: Transport direction changing apparatus
112: Winding apparatus
201: Winding core
201a: Edge of winding core
203: Packaging material
204: Packing tape
205: String or rubber band
210: Package form of roll laminate body of protective film (cellulose acetate film)
301: Dissolving tank
303, 306, 312, and 315: Filtering apparatus
304 and 305: Stock tank
305 and 314: Liquid transfer pump
308 and 316: Conducting pipe
310: Preparation tank of UV absorber
320: Joining tube
321: Mixer
330: Pressure die
331: Metal belt
332: Web
333: Peeling off position
334: Tenter stretching apparatus
335: Drying apparatus
341: Preparation tank
342: Stock tank
343: Pump
344: Filtering apparatus

1. An organic electroluminescent display device comprising an organic electroluminescent element unit having thereon a polarizing plate,
wherein the polarizing plate has a structure of: a retardation film, a polarizer, a protective film and a hard coat layer, which are laminated in that order from a surface side of the organic electroluminescent element unit; and
the protective film has properties of:
(1) containing cellulose acetate which has an average degree of acetyl group substitution in the range of 2.60 to 2.95 as a main component;
(2) having a water swelling ratio in the range of 0.2 to 1.0% after immersing in pure water at 23° C. for one hour; and
(3) having a thickness in the range of 10 to 50 μm.

2. The organic electroluminescent display device described in claim 1,
wherein the retardation film is a film containing polycarbonate or cycloolefin as a main component.

3. The organic electroluminescent display device described in claim 1,
wherein the thickness of the protective film is in the range of 15 to 35 μm.

4. The organic electroluminescent display device described in claim 1,
wherein a thickness of the polarizer is in the range of 2 to 15 μm.

5. The organic electroluminescent display device described in claim 1,
wherein a variation coefficient of the water swelling ratio of the protective film is 0.5% or less when the water swelling ratio is measured at ten different points of a width direction of the protective film.

6. The organic electroluminescent display device described in claim 1,
wherein at least one surface of the protective film and the polarizer is bonded with a UV curable adhesive.

7. The organic electroluminescent display device described in claim 1,
wherein at least one surface of the retardation film and the polarizer is bonded with a UV curable adhesive.

8. The organic electroluminescent display device described in claim 1,
wherein the protective film contains a sugar ester.

9. The organic electroluminescent display device described in claim 8,
wherein an average degree of esterification of the sugar ester is in the range of 5.0 to 7.5.

10. The organic electroluminescent display device described in claim 1,
wherein the protective film contains a polyhydric alcohol ester represented by Formula (1) described below,
B₁-G-B₂ Formula (1)
wherein, B₁ and B₂ each independently represent an aliphatic or aromatic mono carboxylic acid residue, G represents an alkylene glycol residue having a straight or branched structure of 2 to 12 carbon atoms.

11. The organic electroluminescent display device described in claim 10,
wherein B₁ and B₂ in the polyhydric alcohol ester represented by Formula (1) each represent an aliphatic mono carboxylic acid residue having 1 to 10 carbon atoms.

12. A method for producing an organic electroluminescent display device comprising an organic electroluminescent element unit having thereon a polarizing plate,
the method comprising a step of:
producing the polarizing plate by sequentially laminating a retardation film, a polarizer, a protective film and a hard coat layer, in that order, from a surface side of the organic electroluminescent element unit,
wherein the protective film has properties of:
(1) containing cellulose acetate which has an average degree of acetyl group substitution in the range of 2.60 to 2.95 as a main component;
(2) having a water swelling ratio adjusted in the range of 0.2 to 1.0%; and
(3) having a thickness adjusted in the range of 10 to 35 μm.

13. The method for producing an organic electroluminescent display device described in claim 12,
wherein the retardation film is a film containing polycarbonate or cycloolefin as a main component.

14. The method for producing an organic electroluminescent display device described in claim 12,
wherein the protective film is prepared by subjecting the protective film to a stretching treatment at first in a longitudinal direction (MD direction), then, in a transversal direction (TD direction) so as to achieve a stretching of 1.3 to 1.7 times in an area ratio compared to an area of the protective film before stretching.

15. The method for producing an organic electroluminescent display device described in claim 12,
wherein, after making the protective film, a laminated roll body is prepared by laminating in a roll state;
a surface of the laminated roll body is subjected to an aging treatment by covering with a moisture-proof sheet and keeping at 50° C. or more for 3 days or more; then,
the hard coat layer is formed thereon.

16. The method for producing an organic electroluminescent display device described in claim 15,
wherein a surface treatment is carried out to the hard coat layer after forming the hard coat layer.

17. The method for producing an organic electroluminescent display device described in claim 12,
wherein the polarizing plate is prepared by bonding at least one surface of the protective film and the polarizer with a UV curable adhesive.

18. The method for producing an organic electroluminescent display device described in claim 12,
wherein the polarizing plate is prepared by bonding at least one surface of the retardation film and the polarizer with a UV curable adhesive.
